(19) United States
(12) Patent Application Publication
(10) Pub. No.: US 2026/0035288 A1
(43) Pub. Date: Feb. 5, 2026

(54) GLASS

(71) Applicant: AGC Inc., Tokyo (JP)

(72) Inventors: Rikiya KADO, Tokyo (JP); Hirofumi TOKUNAGA, Tokyo (JP)

(73) Assignee: AGC Inc., Tokyo (JP)

(21) Appl. No.: 19/355,333

(22) Filed: Oct. 10, 2025

Related U.S. Application Data
(63) Continuation of application No. PCT/JP2024/015078, filed on Apr. 16, 2024.

(30) Foreign Application Priority Data
Apr. 17, 2023 (JP) 2023-067481

(51) Int. Cl. C03C 3/095; C03C 3/093; H01L 23/15

(52) U.S. Cl. CPC C03C 3/095; C03C 3/093; H01L 23/15

(57) ABSTRACT

A glass which satisfies formulas (1) and (2), where a liquid phase temperature is denoted by T_{L} (° C.), a Young's modulus calculated based on the composition is denoted by E (GPa), and a linear thermal expansion coefficient is denoted by α (ppm/° C.),

$$13.1 \times E + 9 - {T}_{L} \geq 0 \qquad ( 1 )$$

$$1923 - 156 \times α - {T}_{L} \geq 0. \qquad ( 2 )$$

### CROSS-REFERENCE TO RELATED APPLICATION(S)

This application is a continuation of International Application No. PCT/JP2024/015078, filed on Apr. 16, 2024 which claims the benefit of priority of the prior Japanese Patent Application No. 2023-067481, the entire contents of which are incorporated herein by reference.

### BACKGROUND OF THE INVENTION

### 1. Field of the Invention

The present invention relates to a glass.

### 2. Description of the Related Art

Glass may be used as a member for supporting a semiconductor device during the manufacturing process of the semiconductor device. For example, JP 2021-20840 A describes a supporting glass substrate having a high Young's modulus in order to minimize deflection. In addition, the thermal expansion coefficient may be lowered in order to minimize the deflection due to the temperature change.

However, a glass having a low thermal expansion coefficient and a high Young's modulus for minimizing deflection is likely to be crystallized and may be difficult to manufacture. Therefore, a glass with high manufacturability is demanded.

### SUMMARY OF THE INVENTION

It is an object of the present invention to at least partially solve the problems in the conventional technology.

A glass of the present disclosure satisfies Formulae (1) and (2) in a case where a liquid phase temperature is denoted by T_{L} (° C.), a Young's modulus is denoted by E (GPa), and a linear thermal expansion coefficient is denoted by α (ppm/° C.).

$$13.1 \times E + 9 - {T}_{L} \geq 0 \qquad ( 1 )$$

$$1923 - 156 \times α - {T}_{L} \geq 0. \qquad ( 2 )$$

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a schematic diagram of a glass according to the present embodiment.

FIG. 2 is a schematic diagram for explaining deflection evaluation.

### DETAILED DESCRIPTION OF THE PREFERRED EMBODIMENTS

Hereinafter, suitable embodiments of the present invention will be described in detail with reference to the accompanying drawings. The present invention is not limited to the embodiments, and in a case where a plurality of embodiments is provided, the present invention includes a combination of the embodiments. The numerical value includes a range of rounding. The numerical range represented by “to” means a numerical range including numerical values before and after “to” as a lower limit value and an upper limit value, and in a case where “to” is used in the following description, the same meaning is given.

### Glass

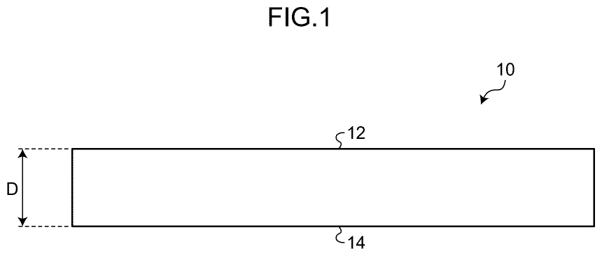

FIG. 1 is a schematic diagram of a glass according to the present embodiment. As illustrated in FIG. 1, a glass 10 according to the present embodiment is used as a glass substrate for manufacturing a semiconductor package, and more specifically, is a supporting glass substrate for manufacturing FOWLP or the like. However, the use of the glass 10 is not limited to the manufacturing FOWLP or the like, and may be optional, and the glass 10 may be a glass substrate used for supporting a member or may be used for purposes other than supporting the member. FOWLP or the like include a fan out wafer level package (FOWLP) and a fan out panel level package (FOPLP).

### Liquid Phase Temperature

The liquid phase temperature of the glass 10 is denoted by T_{L} (° C.), the Young's modulus of the glass 10 is denoted by E (GPa), and the linear thermal expansion coefficient of the glass 10 is denoted by α (ppm/° C.). In this case, the liquid phase temperature T_{L} of the glass 10 preferably satisfies the following Formulae (1) and (2). When Formulae (1) and (2) are satisfied, the liquid phase temperature can be kept relatively low, and the manufacturing can be facilitated while deflection is minimized.

$$13.1 \times E + 9 - {T}_{L} \geq 0 \qquad ( 1 )$$

$$1923 - 156 \times α - {T}_{L} \geq 0 \qquad ( 2 )$$

The liquid phase temperature T_{L} can be evaluated by placing glass particles that pass through a sieve with a mesh width of 4.0 mm and do not pass through a sieve with a mesh width of 2.3 mm on a platinum dish, and then holding the glass particles in an electric furnace set at a predetermined temperature for one hour to measure the temperature at which crystals are precipitated.

The left side (13.1×E+9−T_{L}) of Formula (1) is preferably 17 or more, more preferably 33 or more, more preferably 42 or more, more preferably 63 or more, more preferably 92 or more, and still more preferably 117 or more.

The left side (1923−156×α−T_{L}) of Formula (2) is preferably 12 or more, more preferably 22 or more, more preferably 42 or more, more preferably 62 or more, more preferably 72 or more, and still more preferably 102 or more.

The Young's modulus E can be measured by an ultrasonic pulse method defined in JIS R 1602:1995 “Testing methods for elastic modulus of fine ceramics”. The bulk density of a sample can be measured by the Archimedes method, and the longitudinal wave velocity and the transverse wave velocity are measured using an ultrasonic thickness meter 38DL PLUS manufactured by Olympus Corporation to determine a value of the Young's modulus.

On the other hand, the linear thermal expansion coefficient α is an average thermal expansion coefficient within a range of 50° C. to 200° C., and is a value measured in accordance with DIN-51045-1 as a standard for thermal expansion measurement. For example, the measurement may be performed within a range of 30° C. to 300° C. using a thermal expansion meter (DIL 402 Expedis Supreme) manufactured by NETZSCH Group as a measuring apparatus, and an average thermal expansion coefficient within a range of 50° C. to 200° C. in that measurement range may be used as the linear thermal expansion coefficient.

The liquid phase temperature T_{L} of the glass 10 is preferably 1300° C. or lower, more preferably 800° C. or higher and 1290° C. or lower, more preferably 825° C. or higher and 1280° C. or lower, more preferably 850° C. or higher and 1270° C. or lower, more preferably 875° C. or higher and 1260° C. or lower, more preferably 900° C. or higher and 1250° C. or lower, more preferably 925° C. or higher and 1240° C. or lower, more preferably 950° C. or higher and 1230° C. or lower, more preferably 975° C. or higher and 1220° C. or lower, more preferably 1000° C. or higher and 1210° C. or lower, and still more preferably 1200° C. or lower. By setting the liquid phase temperature within this range, the manufacturing can be facilitated.

### Young's Modulus

The Young's modulus E of the glass 10 is preferably 80 GPa or more, more preferably 85 GPa or more and 180 GPa or less, more preferably 88 GPa or more and 170 GPa or less, more preferably 90 GPa or more and 160 GPa or less, more preferably 93 GPa or more and 150 GPa or less, more preferably 95 GPa or more and 145 GPa or less, more preferably 97 GPa or more and 140 GPa or less, more preferably 98 GPa or more and 135 GPa or less, still more preferably 99 GPa or more and 130 GPa or less. By setting the Young's modulus within this range, deflection can be appropriately minimized, and cutting, grinding, and polishing processing can be facilitated.

### Linear Thermal Expansion Coefficient

The linear thermal expansion coefficient α of the glass 10 is preferably 4.5 ppm/° C. or less, more preferably 2.0 ppm/° C. or more and 4.3 ppm/° C. or less, more preferably 2.1 ppm/° C. or more and 4.1 ppm/° C. or less, more preferably 2.2 ppm/° C. or more and 4 ppm/° C. or less, more preferably 2.3 ppm/° C. or more and 3.9 ppm/° C. or less, more preferably 2.4 ppm/° C. or more and 3.8 ppm/° C. or less, more preferably 2.5 ppm/° C. or more and 3.75 ppm/° C. or less, more preferably 2.6 ppm/° C. or more and 3.7 ppm/° C. or less, more preferably 2.7 ppm/° C. or more and 3.65 ppm/° C. or less, and still more preferably 2.8 ppm/° C. or more and 3.6 ppm/° C. or less. By setting the linear thermal expansion coefficient within this range, deflection can be appropriately minimized.

The linear thermal expansion coefficient α of the glass 10 may be within the following range. The linear thermal expansion coefficient α of the glass 10 is preferably 5.0 ppm/° C. or less, more preferably 3.6 ppm/° C. or more and 4.9 ppm/° C. or less, more preferably 3.7 ppm/° C. or more and 4.8 ppm/° C. or less, more preferably 3.8 ppm/° C. or more and 4.7 ppm/° C. or less, more preferably 3.85 ppm/° C. or more and 4.65 ppm/° C. or less, more preferably 3.9 ppm/° C. or more and 4.6 ppm/° C. or less, more preferably 3.95 ppm/° C. or more and 4.55 ppm/° C. or less, more preferably 4 ppm/° C. or more and 4.5 ppm/° C. or less, more preferably 4.1 ppm/° C. or more and 4.45 ppm/° C. or less, and still more preferably 4.2 ppm/° C. or more and 4.4 ppm/° C. or less. By setting the linear thermal expansion coefficient within this range, deflection can be appropriately minimized.

### Young's Modulus Parameter

A Young's modulus parameter Y of the glass 10 calculated from a composition is preferably 0.8 or more, more preferably 0.85 or more and 1.8 or less, more preferably 0.88 or more and 1.7 or less, more preferably 0.9 or more and 1.6 or less, more preferably 0.93 or more and 1.5 or less, more preferably 0.95 or more and 1.45 or less, more preferably 0.97 or more and 1.4 or less, more preferably 0.98 or more and 1.35 or less, and still more preferably 0.99 or more and 1.3 or less. By setting the Young's modulus parameter within this range, deflection can be appropriately minimized.

The Young's modulus parameter Y is calculated from the following Formula (3).

$$Y = ( 123 - 0.54 [ {SiO}_{2} ] + 0.3 [ {Al}_{2} {O}_{3} ] - 1.15 [ {B}_{2} {O}_{3} ] + 0.21 [ MgO ] - 0.2 [ CaO ] - 0.1 [ SrO ] - 1.2 [ BaO ] + [ {Li}_{2} O ] - 2.8 [ {K}_{2} O ] + 0.05 [ ZnO ] + 1.46 [ {ZrO}_{2} ] - 0.05 [ {TiO}_{2} ] + 1.6 [ {Y}_{2} {O}_{3} ] + 1.35 [ {Gd}_{2} {O}_{3} ] + 1.37 [ {La}_{2} {O}_{3} ] + [ {Ta}_{2} {O}_{5} ] ) / 100 \qquad ( 3 )$$

The content of the oxide RₓO_{y} (R is an element constituting an oxide, and x and y are any integers) contained in the glass 10 is represented by [RₓO_{y}] in terms of mol % on an oxide basis. The content herein refers to the ratio of the content of the oxide RₓO_{y} to the total glass 10 in terms of mol % on an oxide basis. That is, for example, [SiO₂] in Formula (3) refers to the ratio of the content of SiO₂ to the total glass 10 in terms of mol % on an oxide basis.

In addition, the glass 10 may not contain all the oxides represented in Formula (3). In Formula (3), the content of the oxides not contained in the glass 10 is considered to be zero. In addition, the glass 10 may contain components other than the oxides represented in Formula (3).

### Liquid Phase Parameter

A liquid phase parameter L of the glass 10 calculated from the composition is preferably 10.5 or less, more preferably 6.4 or more and 10.4 or less, more preferably 7.2 or more and 10.3 or less, more preferably 7.6 or more and 10.2 or less, more preferably 7.7 or more and 10.1 or less, more preferably 7.8 or more and 10 or less, more preferably 7.9 or more and 9.9 or less, and still more preferably 8 or more and 9.8 or less. By setting the liquid phase parameter L within this range, the liquid phase temperature can be kept low, and the manufacturing can be facilitated.

The liquid phase parameter L is calculated from the following Formula (4).

$$L = ( - 642.5 + 20.6 [ {SiO}_{2} ] + 31.9 [ {Al}_{2} {O}_{3} ] + 2.85 [ {B}_{2} {O}_{3} ] + 11.24 [ MgO ] + 17.3 [ CaO ] + 1.7 [ SrO ] + 31.4 [ BaO ] - 6.86 [ {Li}_{2} O ] + 38 [ {K}_{2} O ] + 11.5 [ ZnO ] + 25.8 [ {ZrO}_{2} ] + 41 [ {TiO}_{2} ] + 12.3 [ {Y}_{2} {O}_{3} ] - 1.2 [ {Gd}_{2} {O}_{3} ] - 1.2 [ {La}_{2} {O}_{3} ] + 24.5 [ {Ta}_{2} {O}_{5} ] ) / 125 \qquad ( 4 )$$

The glass 10 may not contain all the oxides represented in Formula (4). In Formula (4), the content of the oxide not contained in the glass 10 is considered to be zero. In addition, the glass 10 may contain components other than the oxides represented in Formula (4).

### Thermal Expansion parameter

A thermal expansion parameter C of the glass 10 calculated from the composition is preferably 0.9 or less, more preferably 0.4 or more and 0.86 or less, more preferably 0.42 or more and 0.82 or less, more preferably 0.44 or more and 0.8 or less, more preferably 0.46 or more and 0.79 or less, more preferably 0.48 or more and 0.78 or less, more preferably 0.5 or more and 0.77 or less, more preferably 0.52 or more and 0.76 or less, more preferably 0.54 or more and 0.75 or less, and still more preferably 0.56 or more and 0.74 or less. By setting the thermal expansion parameter C within this range, the linear thermal expansion coefficient can be kept low, and deflection can be appropriately minimized.

In addition, the thermal expansion parameter C of the glass 10 may be within the following range. The thermal expansion parameter C of the glass 10 is preferably 1.0 or less, more preferably 0.72 or more and 0.98 or less, more preferably 0.74 or more and 0.96 or less, more preferably 0.76 or more and 0.94 or less, more preferably 0.77 or more and 0.93 or less, more preferably 0.78 or more and 0.92 or less, more preferably 0.79 or more and 0.91 or less, more preferably 0.8 or more and 0.9 or less, more preferably 0.82 or more and 0.89 or less, and still more preferably 0.84 or more and 0.88 or less.

The thermal expansion parameter C is calculated from the following Formula (5).

$$C = ( 14.098 - 0.1245 [ {SiO}_{2} ] - 0.131 [ {Al}_{2} {O}_{3} ] - 0.101 [ {B}_{2} {O}_{3} ] - 0.051 [ MgO ] + 0.013 [ CaO ] + 0.053 [ SrO ] + 0.018 [ BaO ] + 0.041 [ {Li}_{2} O ] + 0.395 [ {Na}_{2} O ] - 0.066 [ ZnO ] - 0.033 [ {ZrO}_{2} ] - 0.072 [ {TiO}_{2} ] + 0.035 [ {Y}_{2} {O}_{3} ] + 0.074 [ {Gd}_{2} {O}_{3} ] + 0.074 [ {La}_{2} {O}_{3} ] - 0.091 [ {Ta}_{2} {O}_{5} ] ) / 5 \qquad ( 5 )$$

The glass 10 may not contain all the oxides represented in Formula (5). In Formula (5), the content of the oxide not contained in the glass 10 is considered to be zero, and the same applies hereafter. In addition, the glass 10 may contain components other than the oxides represented in Formula (5).

### Composition of Glass

Next, a preferred composition of the glass 10 will be described. However, the glass 10 may have any composition in which the liquid phase temperature T_{L} satisfies the above-described range.

### SiO₂

The glass 10 preferably contains SiO₂ (the content of SiO₂ is higher than 0 mol %). SiO₂ is a component for reducing the linear thermal expansion coefficient and is a component for controlling the magnitude of the Young's modulus. In addition, in order to appropriately control an increase in the melting temperature and the liquid phase temperature, the content of SiO₂ is preferably 65% or less. In the glass 10, the content of SiO₂ is preferably 40% or more and 65% or less, preferably 44% or more and 64% or less, preferably 44% or more and 62% or less, preferably 46% or more and 60% or less, preferably 49% or more and 58% or less, preferably 50% or more and 57% or less, preferably 51% or more and 56% or less, preferably 52% or more and 55% or less, and more preferably 52.5% or more and 54% or less in terms of mol % on an oxide basis. When the content of SiO₂ is within this range, the manufacturing can be facilitated while deflection is minimized.

### Al₂O₃+Rare Earth Oxide

The glass 10 preferably contains at least one of Al₂O₃ or a rare earth oxide. The rare earth oxide herein may be one kind of rare earth oxide or a plurality of kinds of rare earth oxides. When Al₂O₃ and the rare earth oxide are contained, the Young's modulus is increased. In the glass 10, the total content (Al₂O₃+rare earth oxide) of Al₂O₃ and the rare earth oxide is preferably 0% or more and 20% or less, more preferably 5% or more and 18% or less, more preferably 9% or more and 17.5% or less, more preferably 10% or more and 17% or less, more preferably 10.5% or more and 16.5% or less, more preferably 11% or more and 16% or less, more preferably 11.5% or more and 15.5% or less, and more preferably 12% or more and 15% or less in terms of mol % on an oxide basis. When the total content of Al₂O₃ and the rare earth oxide is within this range, the liquid phase temperature can be lowered to facilitate the manufacturing.

The total content of Al₂O₃ and the rare earth oxide refers to the ratio of the total value of the content of Al₂O₃ and the content of the rare earth oxide to the total glass 10. In addition, the glass 10 is not limited to containing both Al₂O₃ and the rare earth oxide. The total content of Al₂O₃ and the rare earth oxide refers to, for example, the content of Al₂O₃ in a case where the rare earth oxide is not contained, and refers to the content of the rare earth oxide in a case where Al₂O₃ is not contained. When a plural of kinds of rare earth oxides is contained, the content of the rare earth oxides refers to the total content of these rare earth oxides.

Al₂O₃

Al₂O₃ has effects of increasing the Young's modulus to minimize deflection and inhibit phase separation of glass, but when the content of Al₂O₃ is less than 5%, these effects are less likely to be exhibited. In addition, by setting the content of Al₂O₃ to 20% or less, an increase in the liquid phase temperature can be controlled. Therefore, in the glass 10, the content of Al₂O₃ is preferably 5% or more and 20% or less, more preferably 78 or more and 19% or less, more preferably 8% or more and 18.5% or less, more preferably 9% or more and 18% or less, more preferably 9.5% or more and 17.5% or less, more preferably 10% or more and 17% or less, more preferably 10.5% or more and 16.5% or less, more preferably 11% or more and 16% or less, more preferably 11.5% or more and 15.5% or less, and more preferably 12% or more and 15% or less in terms of mol % on an oxide basis. When the content of Al₂O₃ is within this range, the manufacturing can be facilitated while deflection is minimized.

B₂O₃

B₂O₃ has effects of reducing devitrification caused by crystallization of glass to facilitate the manufacturing, and controlling Young's modulus. Therefore, the glass 10 may not contain B₂O₃ (the content of B₂O₃ is 0 mol %), but may contain B₂O₃. The content of B₂O₃ is preferably 0.01% or more and 15% or less, preferably 18 or more and 13% or less, preferably 3% or more and 12% or less, preferably 5% or more and 11% or less, preferably 6% or more and 10% or less, preferably 6.5% or more and 9.5% or less, and more preferably 7% or more and 9% or less in terms of mol % on an oxide basis. When the content of B₂O₃ is within this range, the manufacturing can be facilitated while deflection is minimized.

### MgO

Since MgO increases the Young's modulus without increasing the density, the deflection can be minimized by increasing the specific elastic modulus. In addition, there is also an effect of reducing the linear thermal expansion coefficient. By setting the content of MgO to 30% or less, the liquid phase temperature can be controlled to be low. Therefore, the glass 10 may not contain MgO (the content of MgO is 0 mol %), but may contain MgO. In the glass 10, the content of MgO is preferably 1% or more and 30% or less, more preferably 5% or more and 29.5% or less, more preferably 9% or more and 29% or less, more preferably 10% or more and 28.5% or less, more preferably 11% or more and 28% or less, more preferably 12% or more and 27.5% or less, more preferably 13% or more and 27% or less, more preferably 14% or more and 26.5% or less, more preferably 15% or more and 26% or less, more preferably 16% or more and 25.5% or less, more preferably 17% or more and 25% or less, more preferably 18% or more and 24.5% or less, more preferably 19% or more and 24% or less, more preferably 19.5% or more and 23.5% or less, and more preferably 20% or more and 23% or less in terms of mol % on an oxide basis. When the content of MgO is within this range, the manufacturing can be facilitated while deflection is minimized.

### CaO

CaO has a characteristic of increasing the specific elastic modulus next to MgO among the oxides of Group 2 elements and not excessively reducing the linear thermal expansion coefficient, and further has a characteristic less likely to increase the liquid phase temperature as compared with MgO. Therefore, the glass 10 may not contain CaO (the content of CaO is 0 mol %), but may contain CaO. By setting the content of CaO to 5% or less, an increase in the linear thermal expansion coefficient can be minimized, and the liquid phase temperature can be controlled to be low. In the glass 10, the content of Cao is preferably 0.01% or more and 5% or less, more preferably 0.1% or more and 3% or less, more preferably 0.15% or more and 2% or less, more preferably 0.2% or more and 1.3% or less, more preferably 0.25% or more and 1% or less, and more preferably 0.3% or more and 0.5% or less in terms of mol % on an oxide basis. When the content of CaO is within this range, the manufacturing can be facilitated while deflection is minimized.

### SrO

SrO has an effect of improving the solubility of glass and reducing the liquid phase temperature. Therefore, the glass 10 may not contain SrO (the content of SrO is 0 mol %), but may contain SrO. By setting the content of SrO to 5% or less, an increase in the linear thermal expansion coefficient can be minimized, and the liquid phase temperature can be controlled to be low. In the glass 10, the content of SrO is preferably 0.01% or more and 5% or less, more preferably 0.1% or more and 3% or less, more preferably 0.15% or more and 2% or less, more preferably 0.2% or more and 1.3% or less, more preferably 0.25% or more and 1% or less, and more preferably 0.3% or more and 0.5% or less in terms of mol % on an oxide basis. When the content of SrO is within this range, the manufacturing can be facilitated while deflection is minimized.

### BaO

BaO has an effect of improving the solubility of glass and reducing the liquid phase temperature. Therefore, the glass 10 may not contain BaO (the content of BaO is 0 mol %), but may contain BaO. By setting the content of BaO to 5% or less, an increase in the linear thermal expansion coefficient can be minimized, and the liquid phase temperature can be controlled to be low. In the glass 10, the content of BaO is preferably 0.01% or more and 5% or less, more preferably 0.1% or more and 3% or less, more preferably 0.15% or more and 2% or less, more preferably 0.2% or more and 1.3% or less, more preferably 0.25% or more and 1% or less, and more preferably 0.3% or more and 0.5% or less in terms of mol % on an oxide basis. When the content of BaO is within this range, the manufacturing can be facilitated while deflection is minimized.

### Li₂O

Among alkali metal oxides, Li₂O has an effect of improving solubility without reducing the linear thermal expansion coefficient. Therefore, the glass 10 may not contain Li₂O (the content of Li₂O is 0 mol %), but may contain Li₂O. By setting the content of Li₂O to 5% or less, the Young's modulus can be increased, and an increase in the linear thermal expansion coefficient can be minimized. In the glass 10, the content of Li₂O is preferably 0.01% or more and 5% or less, more preferably 0.1% or more and 4% or less, more preferably 0.15% or more and 3% or less, more preferably 0.2% or more and 2% or less, more preferably 0.25% or more and 1.5% or less, and more preferably 0.3% or more and 1% or less in terms of mol % on an oxide basis. When the content of Li₂O is within this range, the manufacturing can be facilitated while deflection is minimized.

### Na₂O

Among alkali metal oxides, Na₂O has effects of improving the solubility of glass and reducing the liquid phase temperature. Therefore, the glass 10 may not contain Na₂O (the content of Na₂O is 0 mol %), but may contain Na₂O. By setting the content of Na₂O to 5% or less, the Young's modulus can be increased, and an increase in the linear thermal expansion coefficient can be minimized. In the glass 10, the content of Na₂O is preferably 0.01% or more and 5% or less, more preferably 0.1% or more and 4% or less, more preferably 0.15% or more and 3% or less, more preferably 0.2% or more and 2% or less, more preferably 0.25% or more and 1.5% or less, and more preferably 0.3% or more and 1% or less in terms of mol % on an oxide basis. When the content of Na₂O is within this range, the manufacturing can be facilitated while deflection is minimized.

### K₂O

K₂O has an effect of improving the solubility of glass and reducing the liquid phase temperature. Therefore, the glass 10 may not contain K₂O (the content of K₂O is 0 mol %), but may contain K₂O. By setting the content of K₂O to 5% or less, the Young's modulus can be increased, and an increase in the linear thermal expansion coefficient can be minimized. In the glass 10, the content of K₂O is preferably 0.01% or more and 5% or less, more preferably 0.1% or more and 4% or less, more preferably 0.15% or more and 3% or less, more preferably 0.2% or more and 2% or less, more preferably 0.25% or more and 1.5% or less, and more preferably 0.3% or more and 1% or less in terms of mol % on an oxide basis. When the content of K₂O is within this range, the manufacturing can be facilitated while deflection is minimized.

### ZnO

ZnO has effects of improving the solubility of glass and increasing the Young's modulus. Therefore, the glass 10 may not contain ZnO (the content of ZnO is 0 mol %), but may contain ZnO. By setting the content of ZnO to 10% or less, an increase in the linear thermal expansion coefficient can be minimized, and the liquid phase temperature can be controlled. In the glass 10, the content of ZnO is preferably 0.01% or more and 10% or less, more preferably 0.1% or more and 8% or less, more preferably 0.2% or more and 7% or less, more preferably 0.4% or more and 6% or less, more preferably 0.6% or more and 5% or less, more preferably 0.8% or more and 4% or less, and more preferably 1% or more and 3% or less in terms of mol % on an oxide basis. When the content of ZnO is within this range, the manufacturing can be facilitated while deflection is minimized.

P₂O₅

P₂O₅ has effects of improving the solubility of glass and reducing the linear thermal expansion coefficient. Therefore, the glass 10 may not contain P₂O₅ (the content of P₂O₅ is 0 mol %), but may contain P₂O₅. By setting the content of P₂O₅ to 5% or less, the Young's modulus can be increased without deteriorating chemical resistance, and an increase in the linear thermal expansion coefficient can be minimized. In the glass 10, the content of P₂O₅ is preferably 0.01% or more and 5% or less, more preferably 0.1% or more and 4% or less, more preferably 0.15% or more and 3% or less, more preferably 0.2% or more and 2% or less, more preferably 0.25% or more and 1.5% or less, and more preferably 0.3% or more and 1% or less in terms of mol % on an oxide basis. When the content of P₂O₅ is within this range, the manufacturing can be facilitated while deflection is minimized.

ZrO₂

ZrO₂ can increase the Young's modulus without relatively reducing the linear thermal expansion coefficient. Therefore, the glass 10 may not contain ZrO₂ (the content of ZrO₂ is 0 mol %), but may contain ZrO₂. By setting the content of ZrO₂ to 10% or less, the liquid phase temperature can be controlled. In the glass 10, the content of ZrO₂ is preferably 0.01% or more and 10% or less, more preferably 0.2% or more and 7% or less, more preferably 0.5% or more and 4% or less, more preferably 0.7% or more and 4% or less, and more preferably 1% or more and 2% or less in terms of mol % on an oxide basis. When the content of ZrO₂ is within this range, the manufacturing can be facilitated while deflection is minimized.

### TiO₂

TiO₂ can increase the Young's modulus without relatively reducing the linear thermal expansion coefficient. Therefore, the glass 10 may not contain TiO₂ (the content of TiO₂ is 0 mol %), but may contain TiO₂. By setting the content of TiO₂ to 10% or less, the liquid phase temperature can be controlled. In the glass 10, the content of TiO₂ is preferably 0.01% or more and 10% or less, more preferably 0.2% or more and 7% or less, more preferably 0.5% or more and 4% or less, more preferably 0.7% or more and 4% or less, and more preferably 1% or more and 2% or less in terms of mol % on an oxide basis. When the content of TiO₂ is within this range, the manufacturing can be facilitated while deflection is minimized.

### Y₂O₃

Y₂O₃ has effects of improving the solubility of glass and increasing the Young's modulus. Therefore, the glass 10 may not contain Y₂O₃ (the content of Y₂O₃ is 0 mol %), but may contain Y₂O₃. By setting the content of Y₂O₃ to 7% or less, the linear thermal expansion coefficient can be controlled. In the glass 10, the content of Y₂O₃ is preferably 0.1% or more and 7% or less, more preferably 0.3% or more and 5% or less, more preferably 0.5% or more and 3% or less, more preferably 0.8% or more and 2.5% or less, and more preferably 1% or more and 2% or less in terms of mol % on an oxide basis. When the content of Y₂O₃ is within this range, the manufacturing can be facilitated while deflection is minimized.

### Gd₂O₃

Gd₂O₃ has effects of improving the solubility of glass and increasing the Young's modulus. Therefore, the glass 10 may not contain Gd₂O₃ (the content of Gd₂O₃ is 0 mol %), but may contain Gd₂O₃. By setting the content of Gd₂O₃ to 7% or less, the linear thermal expansion coefficient can be controlled. In the glass 10, the content of Gd₂O₃ is preferably 0.1% or more and 7% or less, more preferably 0.3% or more and 5% or less, more preferably 0.5% or more and 3% or less, more preferably 0.8% or more and 2.5% or less, and more preferably 1% or more and 2% or less in terms of molt on an oxide basis. When the content of Gd₂O₃ is within this range, the manufacturing can be facilitated while deflection is minimized.

### La₂O₃

La₂O₃ has effects of improving the solubility of glass and increasing the Young's modulus. Therefore, the glass 10 may not contain La₂O₃ (the content of La₂O₃ is 0 mol %), but may contain La₂O₃. By setting the content of La₂O₃ to 7% or less, the linear thermal expansion coefficient can be controlled. In the glass 10, the content of La₂O₃ is preferably 0.1% or more and 7% or less, more preferably 0.3% or more and 5% or less, more preferably 0.5% or more and 3% or less, more preferably 0.8% or more and 2.5% or less, and more preferably 1% or more and 2% or less in terms of mol % on an oxide basis. When the content of La₂O₃ is within this range, the manufacturing can be facilitated while deflection is minimized.

### WO₃

WO₃ has effects of improving the solubility of glass and increasing the Young's modulus. Therefore, the glass 10 may not contain WO₃ (the content of WO₃ is 0 mol %), but may contain WO₃. By setting the content of WO₃ to 7% or less, an increase in the linear thermal expansion coefficient can be minimized, and the liquid phase temperature can be controlled. In the glass 10, the content of WO₃ is preferably 0.1% or more and 7% or less, more preferably 0.3% or more and 5% or less, more preferably 0.5% or more and 3% or less, more preferably 0.8% or more and 2.5% or less, and more preferably 1% or more and 2% or less in terms of mol % on an oxide basis. When the content of WO₃ is within this range, the manufacturing can be facilitated while deflection is minimized.

### Ta₂O₅

Ta₂O₅ has effects of reducing the linear thermal expansion coefficient and increasing the Young's modulus. Therefore, the glass 10 may not contain Ta₂O₅ (the content of Ta₂O₅ is 0 mol %), but may contain Ta₂O₅. By setting the content of Ta₂O₅ to 10% or less, the liquid phase temperature can be controlled. In the glass 10, the content of Ta₂O₅ is preferably 0.1% or more and 10% or less, more preferably 0.5% or more and 5% or less, more preferably 1% or more and 4% or less, more preferably 1.5% or more and 3.5% or less, and more preferably 2% or more and 3% or less in terms of mol % on an oxide basis. When the content of Ta₂O₅ is within this range, the manufacturing can be facilitated while deflection is minimized.

### MnO

MnO has an effect of increasing the Young's modulus. However, MnO may increase the liquid phase temperature, and even a small amount of MnO causes the glass to be darkly colored from dark brown to black. Therefore, it is preferable that the glass 10 does not contain MnO. In the glass 10, the content of MnO is preferably 0.1% or less, more preferably 0.001% or more and 0.05% or less, and still more preferably 0.005% or more and 0.01% or less in terms of mol % on an oxide basis. When the content of MnO is within this range, a decrease in light transmittance can be minimized.

### PbO

PbO is an oxide having a high environmental load although having an effect of increasing the Young's modulus. Therefore, it is preferable that the glass 10 does not contain PbO. In the glass 10, the content of PbO is preferably 0.1% or less, more preferably 0.05% or less, and still more preferably 0.01% or less in terms of mol % on an oxide basis. When the content of PbO is within this range, the environmental load can be reduced.

### Fe₂O₃

The glass 10 preferably does not contain Fe₂O₃. In the glass 10, the content of Fe₂O₃ in the outer percentage is preferably 0.1% or less, more preferably 0.001% or more and 0.05% or less, and still more preferably 0.005% or more and 0.01% or less in terms of mass % on an oxide basis. When the content of Fe₂O₃ is as low as described above, a reduction in light transmittance can be minimized.

The content of Fe₂O₃ in the outer percentage refers to the ratio of the mass of Fe₂O₃ contained in the glass 10 to the total value of the mass of all the components of the glass 10 excluding Fe₂O₃ in terms of an oxide basis.

### Y₂O₃+Gd₂O₃+La₂O₃+Nd₂O₃+Ta₂O₅+Nb₂O₅

In the glass 10, the total content of Y₂O₃, Gd₂O₃, La₂O₃, Nd₂O₃, Ta₂O₅, and Nb₂O₅ (Y₂O₃+Gd₂O₃+La₂O₃+Nd₂O₃+Ta₂O₅+Nb₂O₅) is preferably 0.5% or more, more preferably 1% or more and 10% or less, and more preferably 2% or more and 5% or less in terms of mol % on an oxide basis. When the total content of these components is within this range, the manufacturing can be facilitated while deflection is minimized.

The glass 10 may not include all of the above-described components, and may include only some of the components. In addition, the glass 10 may contain none of the above-described components. That is, for example, in a case where Y₂O₃ is not contained, (Y₂O₃) in (Y₂O₃+Gd₂O₃+Ta₂O₅+La₂O₃+Nd₂O₃+Nb₂O₅) is considered to be zero, and the same applies to a case where other components are not contained.

$$( {Al}_{2} {O}_{3} + MgO ) / ( {SiO}_{2} + {Al}_{2} {O}_{3} + {B}_{2} {O}_{3} + MgO )$$

In the glass 10, the ratio of the total content of Al₂O₃ and MgO to the total content of SiO₂, Al₂O₃, B₂O₃, and MgO ((Al₂O₃+MgO)/(SiO₂+Al₂O₃+B₂O₃+MgO)) is preferably 0.1 or more and 1 or less, more preferably 0.2 or more and 0.8 or less, more preferably 0.28 or more and 0.5 or less, more preferably 0.3 or more and 0.4 or less, and more preferably 0.32 or more and 0.38 or less in terms of mol % on an oxide basis. When the total content of these components is within this range, the Young's modulus can be increased to minimize deflection.

The glass 10 is not limited to containing all of SiO₂, Al₂O₃, B₂O₃, and MgO. That is, for example, when Al₂O₃ is not contained, (Al₂O₃) in (Al₂O₃+MgO) and (SiO₂+Al₂O₃+B₂O₃+MgO) is considered to be zero, and the same applies to a case where other components are not contained.

$$( MgO ) / ( \sum R O )$$

In the glass 10, the ratio ((MgO)/(ΣRO)) of the content of MgO to the total content (ΣRO) of the alkaline earth metal oxide is preferably 0.5 or more and 1 or less, more preferably 0.7 or more and 0.98 or less, more preferably 0.8 or more and 0.97 or less, and more preferably 0.83 or more and 0.96 or less in terms of mol % on an oxide basis. When the total content of these components is within this range, the linear thermal expansion coefficient can be reduced to minimize deflection.

The glass 10 is not limited to containing an alkaline earth metal oxide such as MgO. For example, in a case where MgO is not contained, MgO in (MgO/ΣRO) is considered to be zero, and in a case where an alkaline earth metal oxide other than MgO is not contained, the content of the alkaline earth metal oxide other than MgO in (MgO/ΣRO) is considered to be zero.

### Value of N

In the glass 10, the number N of oxides having a content of 0.5% or more among the oxides contained in the glass 10 is preferably 5 or more, more preferably 7 or more, more preferably 8 or more, more preferably 9 or more, and more preferably 10 or more. When the number N is as high as described above, the liquid phase temperature can be lowered to facilitate the manufacturing.

The glass 10 preferably does not contain a sintered body. That is, the glass 10 is preferably glass that is not a sintered body. Here, the sintered body refers to a member in which a plurality of particles are heated at a temperature lower than the melting point to bond the particles to one another. The porosity of the sintered body is high to some extent because the sintered body includes pores, but the porosity of the glass 10 is low because the glass 10 is not a sintered body, and the porosity is thus usually 0%. However, it is allowable to include an inevitable trace amount of pores. The porosity herein is a so-called true porosity, and refers to a value obtained by dividing a sum of volumes of pores (pore) communicating with the outside and pores (pore) not communicating with the outside by a total volume (apparent volume). The porosity can be measured according to, for example, JIS R 1634:1998 “Test methods for density and apparent porosity of fine ceramics”.

In addition, it is preferable that glass used for the glass 10 is usually amorphous glass, that is, amorphous solid. In addition, although this glass may be crystallized glass containing crystals on the surface or inside, amorphous glass is preferable from the viewpoint of density. Among the ceramics, those produced by a sintering method are preferably not used because of a low transmittance and a high density.

### Shape of Glass

Next, the shape of the glass 10 will be described. As illustrated in FIG. 1, the glass 10 is a plate-like glass substrate including a surface 12 serving as a principal surface on one side and a surface 14 serving as a principal surface opposite to the surface 12. The surface 14 may be, for example, parallel to the surface 12. Although the glass 10 may have a circular disk shape in plan view, that is, when viewed from a direction orthogonal to the surface 12, the shape is not limited to the disk shape, may be any shape, and may be a polygonal plate such as a rectangle. The shape also includes a shape in which a notch such as a notch or an orientation flat is provided on the outer periphery.

In addition, a thickness D of the glass 10, that is, the length between the surface 12 and the surface 14 is preferably 0.1 mm or more and 5.0 mm or less, more preferably 0.1 mm or more and 2.0 mm or less, and still more preferably 0.1 mm or more and 0.5 mm or more. By setting the thickness D to 0.1 mm or more, it is possible to prevent the glass 10 from being too thin and to minimize breakage due to deflection or impact. By setting the thickness D to 2.0 mm or less, it is possible to minimize an increase in weight, and by setting the thickness D to 0.5 mm or less, it is possible to further minimize an increase in weight suitably.

### Properties of Glass

Next, properties of the glass 10 other than those described above will be described.

### Glass Transition Temperature

The glass transition temperature of the glass 10 is preferably 600° C. or higher and 850° C. or lower, more preferably 650° C. or higher and 800° C. or lower, more preferably 700° C. or higher and 790° C. or lower, more preferably 705° C. or higher and 780° C. or lower, more preferably 710° C. or higher and 770° C. or lower, more preferably 715° C. or higher and 760° C. or lower, and still more preferably 720° C. or higher and 750° C. or lower. The glass transition temperature can be determined in accordance with the method defined in JIS R3103-3:2001 “Viscosity and viscometric fixed temperature of glass—Part 3: Determination of dilatometric transformation temperature”.

### Density

The density of the glass 10 is preferably 2.45 g/cm³ or more and 3.0 g/cm³ or less, more preferably 2.55 g/cm³ or more and 2.95 g/cm³ or less, more preferably 2.6 g/cm³ or more and 2.9 g/cm³ or less, more preferably 2.65 g/cm³ or more and 2.85 g/cm³ or less, and still more preferably 2.7 g/cm³ or more and 2.8 g/cm³ or less.

### Liquid Phase Viscosity

A liquid phase viscosity log η_{L} (dPa·s) of the glass 10 is preferably 2 or more and 7 or less, more preferably 2.2 or more and 6.5 or less, more preferably 2.4 or more and 6 or less, more preferably 2.6 or more and 5.5 or less, more preferably 2.8 or more and 5 or less, more preferably 2.9 or more and 4.5 or less, and more preferably 3 or more and 4 or less. The liquid phase viscosity refers to a viscosity of the glass 10 at the liquid phase temperature. Since the liquid phase temperature is relatively high as described above, the manufacturing can be facilitated. In a case where the liquid phase temperature is too high, it is difficult to mold glass. The liquid phase viscosity can be determined by measuring a temperature-viscosity curve by an inner cylinder rotation method or the like and calculating the viscosity at the liquid phase temperature.

### Fracture Toughness Value

A fracture toughness value K_{IC} of the glass 10 is preferably 0.5 MPa·m^{0.5} or more and 2 MPa·m^{0.5} or less, more preferably 0.7 MPa·m^{0.5} or more and 1.5 MPa·m^{0.5} or less, more preferably 0.8 MPa·m^{0.5} or more and 1.4 MPa·m^{0.5} or less, and still more preferably 0.9 MPa·m^{0.5} or more and 1.3 MPa·m^{0.5} or less. When the fracture toughness value K_{IC} is within this range, breakage of the glass 10 can be minimized. When the fracture toughness value K_{IC} is too high, it is difficult to cut and grind glass. The fracture toughness value K_{IC} can be measured using a pre-crack introduction fracture test method (Single-Edge-Precracked-Beam (SEPB) method) as defined in, for example, JIS R1607:2015 “Testing methods for fracture toughness of fine ceramics at room temperature”.

### Light Transmittance

The internal transmittance of the glass 10 having a thickness D of 0.7 mm with respect to light (ultraviolet ray) at a wavelength of 308 nm is preferably 30% or more, more preferably 35% or more, still more preferably 40% or more, still more preferably 45% or more, still more preferably 50% or more, still more preferably 55% or more, and still more preferably 60% or more. When the transmittance with respect to the light at a wavelength of 308 nm is within this range, ultraviolet rays can be appropriately transmitted.

The internal transmittance of the glass 10 having a thickness D of 0.7 mm with respect to light (infrared ray) at a wavelength of 1064 nm is preferably 80% or more, more preferably 85% or more, and more preferably 90% or more. When the transmittance with respect to the light at a wavelength of 1064 nm is within this range, infrared rays can be appropriately transmitted.

The transmittance can be measured by measuring a spectral transmittance curve with a spectrophotometer or the like.

### Melting Temperature T₂, Working Temperature T₃, Molding Temperature T₄

A melting temperature T₂ of the glass 10 is preferably 1000° C. or higher and 1550° C. or lower, more preferably 1100° C. or higher and 1500° C. or lower, more preferably 1150° C. or higher and 1450° C. or lower, and more preferably 1200° C. or higher and 1400° C. or lower. The melting temperature T₂ refers to a temperature at which a viscosity η is 10² dPa·s. When the melting temperature T₂ is relatively low as described above, melting can be facilitated.

The working temperature T₃ of the glass 10 is preferably 1000° C. or higher and 1400° C. or lower, more preferably 1050° C. or higher and 1350° C. or lower, and more preferably 1100° C. or higher and 1300° C. or lower. The working temperature T₃ refers to a temperature at which a viscosity η is 10³ dPa·s. When the working temperature T₃ is relatively low as described above, molding can be facilitated.

The molding temperature T₄ of the glass 10 is preferably 900° C. or higher and 1250° C. or lower, more preferably 950° C. or higher and 1200° C. or lower, and more preferably 1000° C. or higher and 1150° C. or lower. The molding temperature T₄ refers to a temperature at which a viscosity η is 10⁴ dPa·s. When the molding temperature T₄ is relatively low as described above, molding can be facilitated.

The melting temperature T₂, the working temperature T₃, and the molding temperature T₄ can be measured by an inner cylinder rotation method or the like.

### Method for Manufacturing Glass

The glass 10 may be manufactured by any method, and is manufactured, for example, by the following method. First, a raw material such as silica sand or soda ash, which is a raw material of the compound contained in the glass 10, is heated at a predetermined temperature (for example, 1500° C. to 1600° C.) to be melted. Then, after the melted raw material (glass) is clarified, a molding process of molding the raw material into a plate shape is executed. The molded glass is one that falls within the composition range of the glass 10 described above on an oxide basis. Then, a slow cooling process is performed on the glass molded in the molding process to manufacture the glass 10.

The method for manufacturing the glass 10 is not limited to the above, and any methods may be adopted. For example, the slow cooling process is not necessary. In addition, various methods can be adopted as the molding process in manufacturing the glass 10, and examples thereof include a melt casting method, a down draw method (for example, an overflow down draw method, a slot down method, a redrawing method, and the like), a float method, a roll-out method, and a press method.

Next, an example of a manufacturing process in a case where the glass 10 is used for manufacturing FOWLP will be described. In manufacturing FOWLP, a plurality of semiconductor chips are bonded to the glass 10, and the semiconductor chips are covered with an encapsulating material to form an element substrate. Then, the glass 10 and the element substrate are separated, and a surface of the element substrate opposite to a surface of the element substrate on which the semiconductor chips are disposed is bonded to, for example, another glass 10. Then, wiring, solder bumps, and the like are formed on the semiconductor chips, and the element substrate and the glass 10 are separated again. The element substrate is then cut into pieces for each semiconductor chip to obtain a semiconductor device.

### Effects

As described above, the glass 10 according to a first aspect of the present disclosure satisfies Formulae (1) and (2) described above. Since Formulae (1) and (2) are satisfied, the liquid phase temperature can be reduced, and the manufacturing can be facilitated. In addition, for example, a glass having a high Young's modulus and a low thermal expansion coefficient for minimizing deflection is particularly likely to be crystallized and may be difficult to manufacture. In contrast, in the present disclosure, since Formulae (1) and (2) are satisfied, an increase in the liquid phase temperature can be minimized, and the manufacturing can be facilitated.

A glass 10 according to a second aspect of the present disclosure is the glass 10 according to the first aspect, in which the glass 10 preferably contains, in terms of mol % on an oxide basis,
SiO₂: 40% to 65%,
B₂O₃: 0.01% to 15%,
Al₂O₃+a rare earth oxide: 0% to 20%, and
(Y₂O₃+Gd₂O₃+Ta₂O₅+La₂O₃+Nd₂O₃+Nb₂O₅): 0.5% or more. As a result, since the Young's modulus can be increased, the linear thermal expansion coefficient can be reduced, and the liquid phase temperature can be lowered, the manufacturing can be facilitated while deflection is minimized.

A glass 10 according to a third aspect of the present disclosure is the glass 10 according to the second aspect, in which the glass 10 preferably contains, in terms of mol % on an oxide basis,
SiO₂: 44% to 64%,
B₂O₃: 1% to 13%,
Al₂O₃: 5% to 20%, and
(Y₂O₃+Gd₂O₃+Ta₂O₅+La₂O₃+Nd₂O₃+Nb₂O₅): 1% or more and 10% or less. As a result, since the Young's modulus can be increased, the linear thermal expansion coefficient can be reduced, and the liquid phase temperature can be lowered, the manufacturing can be facilitated while deflection is minimized.

A glass 10 according to a fourth aspect of the present disclosure is the glass 10 according to any one of the first aspect to the third aspect, in which it is preferable that, in terms of mol % on an oxide basis,

$$0.1 \leq \{ ( {Al}_{2} {O}_{3} + MgO ) / ( {SiO}_{2} + {Al}_{2} {O}_{3} + {B}_{2} {O}_{3} + MgO ) \} \leq 1 ,$$

$$0.5 \leq ( MgO ) / ( \sum R O ) \leq 1 ,$$

and
0%≤Al₂O₃+a rare earth oxide≤20%. As a result, since the Young's modulus can be increased, the linear thermal expansion coefficient can be reduced, and the liquid phase temperature can be lowered, the manufacturing can be facilitated while deflection is minimized.

A glass 10 according to a fifth aspect of the present disclosure is the glass 10 according to any one of the first aspect to the fourth aspect, in which it is preferable that a Young's modulus parameter Y calculated by Formula (3) is 0.8 or more, a liquid phase parameter L calculated by Formula (4) is 10.5 or less, and a thermal expansion parameter C calculated by Formula (5) is 0.9 or less. As a result, since the Young's modulus can be increased, the linear thermal expansion coefficient can be reduced, and the liquid phase temperature can be lowered, the manufacturing can be facilitated while deflection is minimized.

A glass 10 according to a sixth aspect of the present disclosure is the glass 10 according to any one of the first aspect to the fifth aspect, in which it is preferable to use the glass 10 as a substrate. The glass 10 of the present disclosure is suitably used for a substrate.

A glass 10 according to a seventh aspect of the present disclosure is the glass 10 according to the sixth aspect, in which it is preferable that the glass is used for manufacturing at least one of a fan out wafer level package or a fan out panel level package. The glass 10 is suitably used for these applications.

### EXAMPLES

Next, examples will be described. Tables 1 to 41 are tables showing the properties of the glass of each example. The embodiments may be modified as long as the effects of the invention are obtained.

TABLE 1

| | Example | Example | Example | Example | Example | Example | Example | Example | Example |
|---|---|---|---|---|---|---|---|---|---|
| (mol %) | 1 | 2 | 3 | 4 | 5 | 6 | 7 | 8 | 9 |
| SiO₂ | 54 | 54 | 52 | 51 | 53.6 | 55 | 54 | 54 | 52 |
| Al₂O₃ | 12 | 12 | 14 | 12.5 | 12.5 | 15 | 12.2 | 14 | 14 |
| B₂O₃ | 7 | 7 | 8 | 9 | 8 | 8 | 7.2 | 9.1 | 8.6 |
| MgO | 23 | 21 | 21.5 | 22 | 21 | 15 | 23 | 19 | 21.5 |
| CaO | | 1 | 0.5 | 0.5 | 0.3 | 1 | 0.2 | 0.3 | 0.3 |
| SrO | | 1 | 0.5 | 0.5 | 0.3 | 1 | 0.2 | 0.3 | 0.3 |
| BaO | | 1 | 0.5 | 0.5 | 0.3 | 1 | 0.2 | 0.3 | 0.3 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1 | 1 | 1 | 1 | 1 | 1 | 1 | 1 | 1 |
| TiO₂ | 1 | 1 | 1 | 1 | 1 | 1 | 1 | 1 | 1 |
| Y₂O₃ | | 1 | 1 | 2 | 2 | 2 | | 1 | 1 |
| Gd₂O₃ | | | | | | | | | |
| La₂O₃ | | | | | | | | | |
| WO₃ | | | | | | | | | |
| Ta₂O₅ | 2 | 2 | | | | | 1 | | |
| Al₂O₃ + rare earth oxide | 12 | 13 | 15 | 14.5 | 14.5 | 17 | 12.2 | 15 | 15 |
| Y₂O₃ + Gd₂O₃ + La₂O₃ + Nd₂O₃ + Ta₂O₅ + Nb₂O₅ | 2 | 3 | 1 | 2 | 2 | 2 | 1 | 1 | 1 |
| (Al₂O₃ + MgO)/(SiO₂ + Al₂O₃ + B₂O₃ + MgO) | 0.36 | 0.35 | 0.37 | 0.37 | 0.35 | 0.32 | 0.37 | 0.34 | 0.37 |
| MgO/ΣRO | 1.00 | 0.88 | 0.93 | 0.94 | 0.96 | 0.83 | 0.97 | 0.95 | 0.96 |
| N | 7 | 11 | 10 | 10 | 7 | 10 | 7 | 7 | 7 |
| Young's modulus E (GPa) | 98 | 100 | 97 | 99 | 98 | 94 | 95 | 93 | 95 |
| Thermal expansion coefficient α(ppm/° C.) | 3.58 | 3.86 | 3.81 | 4.07 | 3.92 | 3.68 | 3.64 | 3.55 | 3.73 |
| Liquid phase temperature T_{L} (° C.) | 1245 | 1275 | 1225 | 1185 | 1215 | 1195 | 1245 | 1205 | 1230 |
| 13.1 · E+9 − T_{L} | 48 | 49 | 48 | 114 | 76 | 44 | 12 | 21 | 24 |
| 1923 − 156 · α − T_{L} | 120 | 46 | 103 | 103 | 97 | 154 | 111 | 165 | 112 |
| Young's modulus parameter Y | 0.98 | 0.97 | 0.97 | 0.97 | 0.97 | 0.95 | 0.96 | 0.94 | 0.96 |
| Liquid phase parameter L | 10.0 | 10.3 | 10.0 | 9.6 | 9.8 | 10.4 | 9.9 | 10.0 | 9.9 |
| Thermal expansion parameter C | 0.73 | 0.77 | 0.77 | 0.82 | 0.78 | 0.75 | 0.74 | 0.72 | 0.76 |
| Glass transition point (° C.) | 744 | 750 | 742 | 736 | 745 | 752 | 742 | 745 | 742 |
| Density (g/cm³) | 2.79 | 2.89 | 2.65 | 2.70 | 2.68 | 2.71 | 2.68 | 2.59 | 2.61 |
| Liquid phase viscosity log η_{L} (dPa · s) | 3.0 | 2.8 | 3.2 | 3.6 | 3.3 | 3.5 | 3.0 | 3.4 | 3.2 |
| K_{Ic} (MPa · m^{0.5}) | 0.8< | 0.8< | 0.8< | 0.8< | 0.8< | 0.8< | 0.95 | 0.96 | 0.8< |
| Transmittance (%) @308 nm, 0.7 mmt | 30≤ | 30≤ | 30≤ | 30≤ | 30≤ | 30≤ | 35.3 | 30.0 | 30≤ |
| Transmittance (%) @1064 nm, 0.7 mmt | 80≤ | 80≤ | 80≤ | 80≤ | 80≤ | 80≤ | 91.2 | 91.2 | 80≤ |
| T₂ (° C.) | <1450 | <1450 | <1450 | <1450 | <1450 | <1450 | 1409 | 1418 | <1450 |
| T₃ (° C.) | <1300 | <1300 | <1300 | <1300 | <1300 | <1300 | 1250 | 1257 | <1300 |
| T₄ (° C.) | <1200 | <1200 | <1200 | <1200 | <1200 | <1200 | 1141 | 1146 | <1200 |
| Deflection determination | ◯ | ◯ | ◯ | ◯ | ◯ | ◯ | ◯ | ◯ | ◯ |
| Deflection determination in high density process | ◯ | × | ◯ | x | × | ◯ | ◯ | ◯ | ◯ |
| Manufacturability determination | ⊚ | ◯ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 10 | 11 | 12 | 13 | 14 | 15 | 16 | 17 |
| SiO₂ | 52.1 | 52 | 54.8 | 53.4 | 50.6 | 51.6 | 51 | 52.5 |
| Al₂O₃ | 14 | 14 | 12.7 | 13.8 | 14 | 14 | 12.5 | 12.5 |
| B₂O₃ | 9 | 8 | 8.2 | 11.0 | 8 | 8 | 8.5 | 7.5 |
| MgO | 20 | 22.1 | 20.55 | 17.8 | 21.5 | 21.5 | 20.5 | 21.5 |
| CaO | 0.3 | 0.3 | 0.25 | 0.5 | 0.3 | 0.3 | 1 | 1 |
| SrO | 0.3 | 0.3 | 0.25 | 0.6 | 0.3 | 0.3 | 1 | 1 |
| BaO | 0.3 | 0.3 | 0.25 | | 0.3 | 0.3 | 0.5 | 0.5 |
| Li₂O | | | | | | | | |
| Na₂O | | | | | | | | |
| K₂O | | | | | | | | |
| ZnO | | | | | | | 2.5 | |
| P₂O₅ | | | | | | | | |
| ZrO₂ | 1 | 1 | 1 | 0.9 | 1 | 2 | 1 | 1 |
| TiO₂ | 1 | 1 | 1 | 0.5 | 3 | 1 | 1 | 1 |
| Y₂O₃ | 2 | 1 | 1 | 1.5 | 1 | 1 | 0.5 | 1.5 |
| Gd₂O₃ | | | | | | | | |
| La₂O₃ | | | | | | | | |
| WO₃ | | | | | | | | |
| Ta₂O₅ | | | | | | | | |
| Al₂O₃ + rare earth oxide | 16 | 15 | 13.7 | 15.3 | 15 | 15 | 13 | 14 |
| Y₂O₃ + Gd₂O₃ + La₂O₃ + Nd₂O₃ + Ta₂O₅ + Nb₂O₅ | 2 | 1 | 1 | 1.5 | 1 | 1 | 0.5 | 1.5 |
| (Al₂O₃ + MgO)/(SiO₂ + Al₂O₃ + B₂O₃ + MgO) | 0.36 | 0.38 | 0.35 | 0.33 | 0.38 | 0.37 | 0.36 | 0.36 |
| MgO/ΣRO | 0.96 | 0.96 | 0.96 | 0.94 | 0.96 | 0.96 | 0.89 | 0.90 |
| N | 7 | 7 | 7 | 7 | 7 | 7 | 11 | 10 |
| Young's modulus E (GPa) | 97 | 96 | 93 | 91 | 97 | 100 | 95 | 101 |
| Thermal expansion coefficient α(ppm/° C.) | 3.77 | 3.84 | 3.70 | 3.59 | 3.81 | 3.87 | 4.25 | 4.30 |
| Liquid phase temperature T_{L} (° C.) | 1215 | 1255 | 1215 | 1150 | 1225 | 1251 | 1215 | 1235 |
| 13.1 · E+9 − T_{L} | 65 | 16 | 16 | 51 | 48 | 62 | 36 | 101 |
| 1923 − 156 · α − T_{L} | 120 | 69 | 131 | 213 | 103 | 69 | 45 | 17 |
| Young's modulus parameter Y | 0.97 | 0.97 | 0.95 | 0.93 | 0.98 | 0.99 | 0.95 | 0.97 |
| Liquid phase parameter L | 9.9 | 9.9 | 9.9 | 9.6 | 10.3 | 10.0 | 9.6 | 9.8 |
| Thermal expansion parameter C | 0.77 | 0.76 | 0.74 | 0.73 | 0.77 | 0.77 | 0.81 | 0.82 |
| Glass transition point (° C.) | 745 | 743 | 744 | 735 | 742 | 746 | 719 | 737 |
| Density (g/cm³) | 2.68 | 2.63 | 2.60 | 2.58 | 2.65 | 2.71 | 2.69 | 2.84 |
| Liquid phase viscosity log η_{L} (dPa · s) | 3.3 | 3.0 | 3.3 | 3.9 | 3.2 | 3.0 | 3.3 | 3.1 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | ◯ | x | ◯ | ◯ | ◯ | x | x | x |
| Manufacturability determination | ⊚ | ⊚ | ⊚ | ⊚ | ⊚ | ⊚ | ⊚ | ⊚ |

TABLE 2

| | Example | Example | Example | Example | Example | Example | Example | Example | Example |
|---|---|---|---|---|---|---|---|---|---|
| (mol %) | 18 | 19 | 20 | 21 | 22 | 23 | 24 | 25 | 26 |
| SiO₂ | 51.4 | 51 | 51 | 51.2 | 49 | 50.8 | 54 | 54 | 54 |
| Al₂O₃ | 12.3 | 13 | 12 | 12.1 | 14 | 12.9 | 12 | 12 | 12 |
| B₂O₃ | 8 | 7 | 7 | 8.0 | 8.0 | 7.0 | 7 | 7 | 7 |
| MgO | 21 | 21 | 21 | 21.4 | 21.4 | 22.4 | 23 | 23 | 23 |
| CaO | 1.3 | 1 | 2 | 1.3 | 1.3 | 1.0 | | | |
| SrO | 1.3 | 1 | 1 | 1.3 | 1.3 | 1.0 | | | |
| BaO | 0.3 | 1 | 1 | 0.6 | 0.6 | 1.0 | | | |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1 | 1 | 1 | 1.0 | 1.0 | 1.0 | 0.5 | 1 | 1 |
| TiO₂ | 1 | 1 | 1 | 1.0 | 1.0 | 1.0 | 1.5 | 0.5 | 1.5 |
| Y₂O₃ | 2.4 | 3 | 3 | 2.0 | 2.0 | 2.0 | | | |
| Gd₂O₃ | | | | | | | | | |
| La₂O₃ | | | | | | | | | |
| WO₃ | | | | | | | | | |
| Ta₂O₅ | | | | | | | 2 | 2.5 | 1.5 |
| Al₂O₃ + rare earth oxide | 14.7 | 16 | 15 | 14.1 | 16.0 | 14.9 | 12 | 12 | 12 |
| Y₂O₃ + Gd₂O₃ + La₂O₃ + Nd₂O₃ + Ta₂O₅ + Nb₂O₅ | 2.4 | 3 | 3 | 2 | 2 | 2 | 2 | 2.5 | 1.5 |
| (Al₂O₃ + MgO)/(SiO₂ + Al₂O₃ + B₂O₃ + MgO) | 0.36 | 0.37 | 0.36 | 0.36 | 0.38 | 0.38 | 0.36 | 0.36 | 0.36 |
| MgO/ΣRO | 0.88 | 0.88 | 0.84 | 0.87 | 0.87 | 0.88 | 1.00 | 1.00 | 1.00 |
| N | 9 | 10 | 10 | 10 | 10 | 10 | 7 | 7 | 7 |
| Young's modulus E (GPa) | 99 | 100 | 100 | 97 | 100 | 98 | 98 | 99 | 99 |
| Thermal expansion coefficient α(ppm/° C.) | 4.22 | 4.36 | 4.47 | 4.21 | 4.25 | 4.30 | 3.60 | 3.61 | 3.65 |
| Liquid phase temperature T_{L} (° C.) | 1175 | 1195 | 1175 | 1185 | 1205 | 1205 | 1277 | 1273 | 1236 |
| 13.1 · E+9 − T_{L} | 132 | 124 | 140 | 92 | 107 | 89 | 21 | 36 | 64 |
| 1923 − 156 · α − T_{L} | 89 | 48 | 51 | 82 | 56 | 47 | 84 | 87 | 117 |
| Young's modulus parameter Y | 0.99 | 1.00 | 1.00 | 0.98 | 1.00 | 0.99 | 0.97 | 0.98 | 0.97 |
| Liquid phase parameter L | 9.6 | 9.9 | 9.7 | 9.6 | 9.7 | 9.8 | 10.0 | 9.9 | 10.0 |
| Thermal expansion parameter C | 0.86 | 0.87 | 0.90 | 0.86 | 0.86 | 0.86 | 0.72 | 0.73 | 0.73 |
| Glass transition point (° C.) | 734 | 744 | 739 | 732 | 733 | 739 | 732 | 745 | 732 |
| Density (g/cm³) | 2.76 | 2.82 | 2.82 | 2.74 | 2.76 | 2.75 | 2.79 | 2.85 | 2.74 |
| Liquid phase viscosity log η_{L} (dPa · s) | 3.7 | 3.2 | 3.3 | 3.2 | 3.0 | 3.4 | 2.8 | 2.8 | 3.1 |
| K_{Ic} (MPa · m^{0.5}) | 0.8< | 0.95 | 0.8< | 0.8< | 0.8< | 0.8< | 0.8< | 0.8< | 0.8< |
| Transmittance (%) @308 nm, 0.7 mmt | 30≤ | 33.8 | 30≤ | 30≤ | 30≤ | 30≤ | 30≤ | 30≤ | 30≤ |
| Transmittance (%) @1064 nm, 0.7 mmt | 80≤ | 90.6 | 80≤ | 80≤ | 80≤ | 80≤ | 80≤ | 80≤ | 80≤ |
| T₂ (° C.) | <1450 | 1359 | <1450 | <1450 | 1351 | <1450 | <1450 | <1450 | <1450 |
| T₃ (° C.) | <1300 | 1213 | <1300 | <1300 | 1204 | <1300 | <1300 | <1300 | <1300 |
| T₄ (° C.) | <1200 | 1113 | <1200 | <1200 | 1104 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | x | x | x | ◯ | ◯ | ◯ |
| Manufacturability determination | ⊚ | ⊚ | ⊚ | ⊚ | ⊚ | ⊚ | ◯ | ◯ | ◯ |

| | Example | Example | Example | Example | Example | Example | Example | Example |
|---|---|---|---|---|---|---|---|---|
| (mol %) | 27 | 28 | 29 | 30 | 31 | 32 | 33 | 34 |
| SiO₂ | 54 | 54 | 52.1 | 52.1 | 52.1 | 52.1 | 52.1 | 52.1 |
| Al₂O₃ | 12 | 12 | 14 | 14 | 14 | 14 | 14 | 14 |
| B₂O₃ | 7 | 7 | 9 | 9 | 9 | 9 | 9 | 9 |
| MgO | 23 | 23 | 20 | 20 | 20 | 20 | 20 | 20 |
| CaO | | | 0.2 | 0.2 | 0.2 | 0.2 | 0.2 | 0.2 |
| SrO | | | 0.2 | 0.2 | 0.2 | 0.2 | 0.2 | 0.2 |
| BaO | | | 0.5 | 0.5 | 0.5 | 0.5 | 0.5 | 0.5 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1.5 | 1.5 | 0.5 | 0.5 | 0.5 | 0.5 | 0.5 | 0.5 |
| TiO₂ | 0.5 | 1 | 0.5 | 0.5 | 0.5 | 0.5 | 0.5 | 0.5 |
| Y₂O₃ | | | 1 | 1 | 1 | 1.5 | 1.5 | 2 |
| Gd₂O₃ | | | | 1 | 2 | | 1.5 | |
| La₂O₃ | | | 2 | 1 | | 1.5 | | 1 |
| WO₃ | | | | | | | | |
| Ta₂O₅ | 2 | 1.5 | | | | | | |
| Al₂O₃ + rare earth oxide | 12 | 12 | 17 | 17 | 17 | 17 | 17 | 17 |
| Y₂O₃ + Gd₂O₃ + La₂O₃ + Nd₂O₃ + Ta₂O₅ + Nb₂O₅ | 2 | 1.5 | 3 | 3 | 3 | 3 | 3 | 3 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 1.00 | 1.00 | 0.96 | 0.96 | 0.96 | 0.96 | 0.96 | 0.96 |
| N | 7 | 7 | 9 | 10 | 9 | 9 | 9 | 9 |
| Young's modulus E (GPa) | 99 | 99 | 98 | 98 | 98 | 98 | 98 | 98 |
| Thermal expansion coefficient α(ppm/° C.) | 3.65 | 3.68 | 4.03 | 4.07 | 4.10 | 3.99 | 4.05 | 3.96 |
| Liquid phase temperature T_{L} (° C.) | 1267 | 1240 | 1269 | 1266 | 1266 | 1264 | 1263 | 1249 |
| 13.1 · E+9 − T_{L} | 45 | 68 | 28 | 30 | 29 | 32 | 33 | 47 |
| 1923 − 156 · α − T_{L} | 86 | 110 | 25 | 22 | 17 | 36 | 28 | 57 |
| Young's modulus parameter Y | 0.98 | 0.98 | 0.97 | 0.97 | 0.97 | 0.97 | 0.97 | 0.98 |
| Liquid phase parameter L | 9.9 | 10.0 | 9.5 | 9.5 | 9.5 | 9.6 | 9.6 | 9.6 |
| Thermal expansion parameter C | 0.73 | 0.73 | 0.80 | 0.80 | 0.80 | 0.80 | 0.80 | 0.79 |
| Glass transition point (° C.) | 744 | 734 | 740 | 733 | 733 | 740 | 733 | 740 |
| Density (g/cm³) | 2.80 | 2.75 | 2.84 | 2.85 | 2.86 | 2.82 | 2.83 | 2.80 |
| Liquid phase viscosity log η_{L} (dPa · s) | 2.9 | 3.1 | 2.9 | 2.9 | 2.9 | 2.9 | 2.9 | 3.0 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | ◯ | ◯ | x | x | x | x | x | x |
| Manufacturability determination | ◯ | ⊚ | ◯ | ◯ | ◯ | ◯ | ◯ | ⊚ |

TABLE 3

| | Example | Example | Example | Example | Example | Example | Example | Example | Example |
|---|---|---|---|---|---|---|---|---|---|
| (mol %) | 35 | 36 | 37 | 38 | 39 | 40 | 41 | 42 | 43 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.2 | 0.2 | 0.2 | 0.2 | 0.2 | 0.2 | 0.2 | 0.2 | 0.2 |
| SrO | 0.2 | 0.2 | 0.2 | 0.2 | 0.2 | 0.2 | 0.2 | 0.2 | 0.2 |
| BaO | 0.5 | 0.5 | 0.5 | 0.5 | 0.5 | 0.5 | 0.5 | 0.5 | 0.5 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 0.5 | 0.5 | 0.5 | 0.5 | 0.5 | 0.5 | 0.5 | 0.5 | 0.5 |
| TiO₂ | 0.5 | 1 | 1 | 1 | 1 | 1 | 1.5 | 1.5 | 1.5 |
| Y₂O₃ | 2 | 1 | 1 | 1.5 | 1.5 | 2.5 | 1 | 1 | 2 |
| Gd₂O₃ | 1 | | 1.5 | | 1 | | | 1 | |
| La₂O₃ | | 1.5 | | 1 | | | 1 | | |
| WO₃ | | | | | | | | | |
| Ta₂O₅ | | | | | | | | | |
| Al₂O₃ + rare earth oxide | 17 | 16.5 | 16.5 | 16.5 | 16.5 | 16.5 | 16 | 16 | 16 |
| Y₂O₃ + Gd₂O₃ + La₂O₃ + Nd₂O₃ + Ta₂O₅ + Nb₂O₅ | 3 | 2.5 | 2.5 | 2.5 | 2.5 | 2.5 | 2 | 2 | 2 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 9 | 9 | 9 | 9 | 9 | 8 | | 9 | 8 |
| Young's modulus E (GPa) | 98 | 98 | 98 | 98 | 98 | 98 | 98 | 98 | 98 |
| Thermal expansion coefficient α(ppm/° C.) | 3.99 | 3.95 | 4.01 | 3.91 | 3.95 | 3.84 | 3.87 | 3.91 | 3.79 |
| Liquid phase temperature T_{L} (° C.) | 1249 | 1258 | 1255 | 1251 | 1250 | 1233 | 1258 | 1255 | 1235 |
| 13.1 · E+9 − T_{L} | 47 | 34 | 36 | 41 | 42 | 59 | 29 | 32 | 53 |
| 1923 − 156 · α − T_{L} | 51 | 49 | 43 | 61 | 57 | 91 | 61 | 58 | 96 |
| Young's modulus parameter Y | 0.98 | 0.97 | 0.97 | 0.97 | 0.97 | 0.97 | 0.96 | 0.96 | 0.96 |
| Liquid phase parameter L | 9.6 | 9.7 | 9.7 | 9.7 | 9.7 | 9.9 | 9.9 | 9.9 | 10.0 |
| Thermal expansion parameter C | 0.79 | 0.79 | 0.79 | 0.78 | 0.78 | 0.77 | 0.77 | 0.77 | 0.76 |
| Glass transition point (° C.) | 733 | 733 | 726 | 733 | 726 | 733 | 730 | 725 | 730 |
| Density (g/cm³) | 2.81 | 2.79 | 2.81 | 2.77 | 2.78 | 2.73 | 2.75 | 2.75 | 2.71 |
| Liquid phase viscosity log η_{L} (dPa · s) | 3.0 | 2.9 | 3.0 | 3.0 | 3.0 | 3.1 | 2.9 | 3.0 | 3.1 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | x | x | x | x | x | ◯ |
| Manufacturability determination | ⊚ | ⊚ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 44 | 45 | 46 | 47 | 48 | 49 | 50 | 51 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.2 | 0.2 | 0.2 | 0.2 | 0.2 | 0.2 | 0.2 | 0.2 |
| SrO | 0.2 | 0.2 | 0.2 | 0.2 | 0.2 | 0.2 | 0.2 | 0.2 |
| BaO | 0.5 | 0.5 | 0.5 | 0.5 | 0.5 | 0.5 | 0.5 | 0.5 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1 | 1 | 1 | 1 | 1 | 1 | 1 | 1 |
| TiO₂ | 0.5 | 0.5 | 0.5 | 0.5 | 0.5 | 0.5 | 0.5 | 0.5 |
| Y₂O₃ | | | | | 1 | 1 | 1.5 | 1.5 |
| Gd₂O₃ | | 1 | 1.5 | 2.5 | | 1.5 | | 1 |
| La₂O₃ | 2.5 | 1.5 | 1 | | 1.5 | | 1 | |
| WO₃ | | | | | | | | |
| Ta₂O₅ | | | | | | | | |
| Al₂O₃ + rare earth oxide | 16.5 | 16.5 | 16.5 | 16.5 | 16.5 | 16.5 | 16.5 | 16.5 |
| Y₂O₃ + Gd₂O₃ + La₂O₃ + Nd₂O₃ + Ta₂O₅ + Nb₂O₅ | 2.5 | 2.5 | 2.5 | 2.5 | 2.5 | 2.5 | 2.5 | 2.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 8 | 9 | 9 | 8 | 9 | 9 | 9 | 9 |
| Young's modulus E (GPa) | 98 | 98 | 98 | 98 | 98 | 98 | 98 | 98 |
| Thermal expansion coefficient α(ppm/° C.) | 4.06 | 4.09 | 4.11 | 4.15 | 3.98 | 4.03 | 3.94 | 3.98 |
| Liquid phase temperature T_{L} (° C.) | 1256 | 1253 | 1252 | 1252 | 1235 | 1230 | 1235 | 1233 |
| 13.1 · E+9 − T_{L} | 42 | 45 | 45 | 46 | 64 | 67 | 64 | 66 |
| 1923 − 156 · α − T_{L} | 34 | 32 | 30 | 25 | 67 | 64 | 74 | 70 |
| Young's modulus parameter Y | 0.97 | 0.97 | 0.97 | 0.97 | 0.97 | 0.97 | 0.97 | 0.97 |
| Liquid phase parameter L | 9.5 | 9.5 | 9.5 | 9.5 | 9.6 | 9.6 | 9.7 | 9.7 |
| Thermal expansion parameter C | 0.80 | 0.80 | 0.80 | 0.80 | 0.79 | 0.79 | 0.79 | 0.79 |
| Glass transition point (° C.) | 740 | 733 | 733 | 733 | 740 | 733 | 740 | 733 |
| Density (g/cm³) | 2.84 | 2.85 | 2.85 | 2.86 | 2.80 | 2.81 | 2.78 | 2.79 |
| Liquid phase viscosity log η_{L} (dPa · s) | 3.0 | 3.0 | 3.0 | 3.0 | 3.1 | 3.2 | 3.1 | 3.1 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | x | x | x | x | x | x |
| Manufacturability determination | ⊚ | ⊚ | ⊚ | ⊚ | ⊚ | ⊚ | ⊚ | ⊚ |

TABLE 4

| | Example | Example | Example | Example | Example | Example | Example | Example | Example |
|---|---|---|---|---|---|---|---|---|---|
| (mol %) | 52 | 53 | 54 | 55 | 56 | 57 | 58 | 59 | 60 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.2 | 0.2 | 0.2 | 0.2 | 0.2 | 0.2 | 0.2 | 0.2 | 0.2 |
| SrO | 0.2 | 0.2 | 0.2 | 0.2 | 0.2 | 0.2 | 0.2 | 0.2 | 0.2 |
| BaO | 0.5 | 0.5 | 0.5 | 0.5 | 0.5 | 0.5 | 0.5 | 0.5 | 0.5 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1 | 1 | 1 | 1 | 1 | 1 | 1 | 1 | 1 |
| TiO₂ | 0.5 | 1 | 1 | 1 | 1 | 1 | 1 | 1.5 | 1.5 |
| Y₂O₃ | 2.5 | | | | 1 | 1 | 2 | | |
| Gd₂O₃ | | | 1 | 2 | | 1 | | | 1.5 |
| La₂O₃ | | 2 | 1 | | 1 | | | 1.5 | |
| WO₃ | | | | | | | | | |
| Ta₂O₅ | | | | | | | | | |
| Al₂O₃ + rare earth oxide | 16.5 | 16 | 16 | 16 | 16 | 16 | 16 | 15.5 | 15.5 |
| Y₂O₃ + Gd₂O₃ + La₂O₃ + Nd₂O₃ + Ta₂O₅ + Nb₂O₅ | 2.5 | 2 | 2 | 2 | 2 | 2 | 2 | 1.5 | 1.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 8 | 8 | 9 | 8 | 9 | 9 | 8 | 8 | 8 |
| Young's modulus E (GPa) | 98 | 98 | 98 | 98 | 98 | 98 | 98 | 98 | 98 |
| Thermal expansion coefficient α(ppm/° C.) | 3.86 | 3.98 | 4.01 | 4.05 | 3.90 | 3.93 | 3.82 | 3.89 | 3.95 |
| Liquid phase temperature T_{L} (° C.) | 1219 | 1234 | 1230 | 1230 | 1223 | 1218 | 1205 | 1228 | 1223 |
| 13.1 · E+9 − T_{L} | 80 | 59 | 63 | 63 | 71 | 75 | 89 | 61 | 66 |
| 1923 − 156 · α − T_{L} | 102 | 68 | 67 | 62 | 92 | 91 | 122 | 87 | 84 |
| Young's modulus parameter Y | 0.98 | 0.96 | 0.96 | 0.96 | 0.97 | 0.97 | 0.97 | 0.96 | 0.96 |
| Liquid phase parameter L | 9.8 | 9.7 | 9.7 | 9.7 | 9.8 | 9.8 | 9.9 | 9.9 | 9.9 |
| Thermal expansion parameter C | 0.78 | 0.78 | 0.78 | 0.78 | 0.77 | 0.77 | 0.77 | 0.77 | 0.77 |
| Glass transition point (° C.) | 740 | 732 | 725 | 726 | 732 | 725 | 732 | 730 | 724 |
| Density (g/cm³) | 2.74 | 2.79 | 2.80 | 2.81 | 2.75 | 2.76 | 2.72 | 2.75 | 2.76 |
| Liquid phase viscosity log η_{L} (dPa · s) | 3.3 | 3.1 | 3.2 | 3.2 | 3.2 | 3.3 | 3.4 | 3.2 | 3.2 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | x | x | x | ◯ | x | × |
| Manufacturability determination | ⊚ | ⊚ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 61 | 62 | 63 | 64 | 65 | 66 | 67 | 68 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.2 | 0.2 | 0.2 | 0.2 | 0.2 | 0.2 | 0.2 | 0.2 |
| SrO | 0.2 | 0.2 | 0.2 | 0.2 | 0.2 | 0.2 | 0.2 | 0.2 |
| BaO | 0.5 | 0.5 | 0.5 | 0.5 | 0.5 | 0.5 | 0.5 | 0.5 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1 | 1.5 | 1.5 | 1.5 | 1.5 | 1.5 | 1.5 | 1.5 |
| TiO₂ | 1.5 | 0.5 | 0.5 | 0.5 | 0.5 | 0.5 | 0.5 | 1 |
| Y₂O₃ | 1.5 | | | | 1 | 1 | 2 | |
| Gd₂O₃ | | | 1 | 2 | | 1 | | |
| La₂O₃ | | 2 | 1 | | 1 | | | 1.5 |
| WO₃ | | | | | | | | |
| Ta₂O₅ | | | | | | | | |
| Al₂O₃ + rare earth oxide | 15.5 | 16 | 16 | 16 | 16 | 16 | 16 | 15.5 |
| Y₂O₃ + Gd₂O₃ + La₂O₃ + Nd₂O₃ + Ta₂O₅ + Nb₂O₅ | 1.5 | 2 | 2 | 2 | 2 | 2 | 2 | 1.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 8 | 8 | 9 | 8 | 9 | 9 | 8 | 8 |
| Young's modulus E (GPa) | 98 | 99 | 99 | 99 | 99 | 99 | 99 | 98 |
| Thermal expansion coefficient α(ppm/° C.) | 3.78 | 4.00 | 4.04 | 4.07 | 3.92 | 3.96 | 3.85 | 3.92 |
| Liquid phase temperature T_{L} (° C.) | 1222 | 1255 | 1252 | 1251 | 1234 | 1230 | 1219 | 1234 |
| 13.1 · E+9 − T_{L} | 68 | 45 | 48 | 49 | 67 | 71 | 82 | 62 |
| 1923 − 156 · α − T_{L} | 111 | 43 | 42 | 37 | 77 | 76 | 104 | 77 |
| Young's modulus parameter Y | 0.96 | 0.97 | 0.97 | 0.97 | 0.97 | 0.97 | 0.98 | 0.96 |
| Liquid phase parameter L | 10.0 | 9.6 | 9.6 | 9.6 | 9.7 | 9.7 | 9.8 | 9.8 |
| Thermal expansion parameter C | 0.76 | 0.79 | 0.79 | 0.79 | 0.78 | 0.78 | 0.77 | 0.77 |
| Glass transition point (° C.) | 730 | 740 | 733 | 733 | 740 | 733 | 740 | 733 |
| Density (g/cm³) | 2.69 | 2.80 | 2.81 | 2.82 | 2.76 | 2.77 | 2.72 | 2.75 |
| Liquid phase viscosity log η_{L} (dPa · s) | 3.2 | 3.0 | 3.0 | 3.0 | 3.1 | 3.2 | 3.2 | 3.1 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | ◯ | x | x | x | x | x | x | x |
| Manufacturability determination | ⊚ | ⊚ | ⊚ | ⊚ | ⊚ | ⊚ | ⊚ | ⊚ |

TABLE 5

| | Example | Example | Example | Example | Example | Example | Example | Example | Example |
|---|---|---|---|---|---|---|---|---|---|
| (mol %) | 69 | 70 | 71 | 72 | 73 | 74 | 75 | 76 | 77 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 6 | 9 | 9 |
| MgO | 20 | 20 | 20 | 20 | 20 | 20 | 20 | 20 | 20 |
| CaO | 0.2 | 0.2 | 0.2 | 0.2 | 0.2 | 0.2 | 0.2 | 0.2 | 0.2 |
| SrO | 0.2 | 0.2 | 0.2 | 0.2 | 0.2 | 0.3 | 0.3 | 0.3 | 0.3 |
| BaO | 0.5 | 0.5 | 0.5 | 0.5 | 0.5 | 0.4 | 0.4 | 0.4 | 0.4 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1.5 | 1.5 | 1.5 | 1.5 | 1.5 | 0.5 | 0.5 | 0.5 | 0.5 |
| TiO₂ | 1 | 1 | 1.5 | 1.5 | 1.5 | 0.5 | 0.5 | 0.5 | 0.5 |
| Y₂O₃ | | 1.5 | | | 1 | 1 | 1 | 1 | 1.5 |
| Gd₂O₃ | 1.5 | | | 1 | | | 1 | 2 | |
| La₂O₃ | | | 1 | | | 2 | 1 | | 1.5 |
| WO₃ | | | | | | | | | |
| Ta₂O₅ | | | | | | | | | |
| Al₂O₃ + rare earth oxide | 15.5 | 15.5 | 15 | 15 | 15 | 17 | 17 | 17 | 17 |
| Y₂O₃ + Gd₂O₃ + La₂O₃ + Nd₂O₃ + Ta₂O₅ + Nb₂O₅ | 1.5 | 1.5 | 1 | 1 | 1 | 3 | 3 | 3 | 3 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 8 | 8 | 8 | 8 | 8 | 8 | 9 | 8 | 8 |
| Young's modulus E (GPa) | 98 | 98 | 98 | 98 | 98 | 98 | 98 | 98 | 98 |
| Thermal expansion coefficient α(ppm/° C.) | 3.97 | 3.80 | 3.84 | 3.88 | 3.76 | 4.03 | 4.07 | 4.10 | 3.99 |
| Liquid phase temperature T_{L} (° C.) | 1229 | 1221 | 1227 | 1223 | 1222 | 1264 | 1261 | 1261 | 1259 |
| 13.1 · E+9 − T_{L} | 66 | 75 | 64 | 68 | 70 | 33 | 35 | 35 | 37 |
| 1923 − 156 · α − T_{L} | 74 | 108 | 97 | 96 | 114 | 30 | 27 | 22 | 41 |
| Young's modulus parameter Y | 0.96 | 0.97 | 0.96 | 0.96 | 0.96 | 0.97 | 0.97 | 0.97 | 0.98 |
| Liquid phase parameter L | 9.8 | 10.0 | 10.0 | 10.0 | 10.1 | 9.5 | 9.5 | 9.5 | 9.6 |
| Thermal expansion parameter C | 0.77 | 0.76 | 0.76 | 0.76 | 0.75 | 0.80 | 0.80 | 0.80 | 0.80 |
| Glass transition point (° C.) | 726 | 733 | 730 | 725 | 730 | 739 | 733 | 733 | 739 |
| Density (g/cm³) | 2.77 | 2.70 | 2.71 | 2.72 | 2.67 | 2.84 | 2.85 | 2.86 | 2.82 |
| Liquid phase viscosity log η_{L} (dPa · s) | 3.2 | 3.2 | 3.2 | 3.2 | 3.2 | 2.9 | 2.9 | 2.9 | 2.9 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | ◯ | x | x | ◯ | x | x | x | x |
| Manufacturability determination | ⊚ | ⊚ | ⊚ | ⊚ | ⊚ | ◯ | ◯ | ◯ | ⊚ |

| | Example | Example | Example | Example | Example | Example | Example | Example |
|---|---|---|---|---|---|---|---|---|
| (mol %) | 78 | 79 | 80 | 81 | 82 | 83 | 84 | 85 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.2 | 0.2 | 0.2 | 0.2 | 0.2 | 0.2 | 0.2 | 0.2 |
| SrO | 0.3 | 0.3 | 0.3 | 0.3 | 0.3 | 0.3 | 0.3 | 0.3 |
| BaO | 0.4 | 0.4 | 0.4 | 0.4 | 0.4 | 0.4 | 0.4 | 0.4 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 0.5 | 0.5 | 0.5 | 0.5 | 0.5 | 0.5 | 0.5 | 0.5 |
| TiO₂ | 0.5 | 0.5 | 0.5 | 1 | 1 | 1 | 1 | 1 |
| Y₂O₃ | 1.5 | 2 | 2 | 1 | 1 | 1.5 | 1.5 | 2.5 |
| Gd₂O₃ | 1.5 | | 1 | | 1.5 | | 1 | |
| La₂O₃ | | 1 | | 1.5 | | 1 | | |
| WO₃ | | | | | | | | |
| Ta₂O₅ | | | | | | | | |
| Al₂O₃ + rare earth oxide | 17 | 17 | 17 | 16.5 | 16.5 | 16.5 | 16.5 | 16.5 |
| Y₂O₃ + Gd₂O₃ + La₂O₃ + Nd₂O₃ + Ta₂O₅ + Nb₂O₅ | 3 | 3 | 3 | 2.5 | 2.5 | 2.5 | 2.5 | 2.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 8 | 8 | 8 | 8 | 8 | 8 | 8 | 7 |
| Young's modulus E (GPa) | 98 | 98 | 98 | 98 | 98 | 98 | 98 | 98 |
| Thermal expansion coefficient α(ppm/° C.) | 4.05 | 3.96 | 3.99 | 3.95 | 4.01 | 3.91 | 3.95 | 3.84 |
| Liquid phase temperature T_{L} (° C.) | 1258 | 1243 | 1243 | 1253 | 1250 | 1247 | 1246 | 1227 |
| 13.1 · E+9 − T_{L} | 38 | 54 | 54 | 39 | 41 | 46 | 47 | 66 |
| 1923 − 156 · α − T_{L} | 33 | 63 | 58 | 53 | 48 | 65 | 61 | 97 |
| Young's modulus parameter Y | 0.97 | 0.98 | 0.98 | 0.97 | 0.97 | 0.97 | 0.97 | 0.97 |
| Liquid phase parameter L | 9.6 | 9.6 | 9.6 | 9.7 | 9.7 | 9.7 | 9.7 | 9.8 |
| Thermal expansion parameter C | 0.80 | 0.79 | 0.79 | 0.79 | 0.79 | 0.78 | 0.78 | 0.77 |
| Glass transition point (° C.) | 733 | 739 | 733 | 733 | 726 | 733 | 726 | 733 |
| Density (g/cm³) | 2.83 | 2.80 | 2.81 | 2.79 | 2.80 | 2.77 | 2.78 | 2.73 |
| Liquid phase viscosity log η_{L} (dPa · s) | 2.9 | 3.1 | 3.1 | 3.0 | 3.0 | 3.0 | 3.0 | 3.2 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | x | x | x | x | x | x |
| Manufacturability determination | ⊚ | ⊚ | ⊚ | ⊚ | ⊚ | ⊚ | ⊚ | ⊚ |

TABLE 6

| | Example | Example | Example | Example | Example | Example | Example | Example | Example |
|---|---|---|---|---|---|---|---|---|---|
| (mol %) | 86 | 87 | 88 | 89 | 90 | 91 | 92 | 93 | 94 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.2 | 0.2 | 0.2 | 0.2 | 0.2 | 0.2 | 0.2 | 0.2 | 0.2 |
| SrO | 0.3 | 0.3 | 0.3 | 0.3 | 0.3 | 0.3 | 0.3 | 0.3 | 0.3 |
| BaO | 0.4 | 0.4 | 0.4 | 0.4 | 0.4 | 0.4 | 0.4 | 0.4 | 0.4 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 0.5 | 0.5 | 0.5 | 0.5 | 0.5 | 0.5 | 1 | 1 | 1 |
| TiO₂ | 1.5 | 1.5 | 1.5 | 1.5 | 1.5 | 1.5 | 0.5 | 0.5 | 0.5 |
| Y₂O₃ | | | | 1 | 1 | 2 | | | |
| Gd₂O₃ | | 1 | 2 | | 1 | | | 1 | 1.5 |
| La₂O₃ | 2 | 1 | | 1 | | | 2.5 | 1.5 | 1 |
| WO₃ | | | | | | | | | |
| Ta₂O₅ | | | | | | | | | |
| Al₂O₃ + rare earth oxide | 16 | 16 | 16 | 16 | 16 | 16 | 16.5 | 16.5 | 16.5 |
| Y₂O₃ + Gd₂O₃ + La₂O₃ + Nd₂O₃ + Ta₂O₅ + Nb₂O₅ | 2 | 2 | 2 | 2 | 2 | 2 | 2.5 | 2.5 | 2.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 7 | 8 | 7 | 8 | 8 | 7 | 7 | 8 | 8 |
| Young's modulus E (GPa) | 98 | 98 | 98 | 98 | 98 | 98 | 98 | 98 | 98 |
| Thermal expansion coefficient α(ppm/° C.) | 3.95 | 3.99 | 4.02 | 3.87 | 3.91 | 3.79 | 4.06 | 4.09 | 4.11 |
| Liquid phase temperature T_{L} (° C.) | 1278 | 1275 | 1275 | 1253 | 1250 | 1228 | 1252 | 1249 | 1249 |
| 13.1 · E+9 − T_{L} | 9 | 12 | 11 | 35 | 38 | 60 | 46 | 49 | 49 |
| 1923 − 156 · α − T_{L} | 29 | 26 | 20 | 66 | 63 | 103 | 38 | 35 | 33 |
| Young's modulus parameter Y | 0.96 | 0.96 | 0.96 | 0.96 | 0.96 | 0.96 | 0.97 | 0.97 | 0.97 |
| Liquid phase parameter L | 9.7 | 9.7 | 9.7 | 9.8 | 9.8 | 9.9 | 9.5 | 9.5 | 9.5 |
| Thermal expansion parameter C | 0.78 | 0.78 | 0.78 | 0.77 | 0.77 | 0.76 | 0.80 | 0.80 | 0.80 |
| Glass transition point (° C.) | 731 | 725 | 726 | 731 | 725 | 731 | 739 | 733 | 733 |
| Density (g/cm³) | 2.78 | 2.79 | 2.80 | 2.74 | 2.75 | 2.70 | 2.84 | 2.85 | 2.85 |
| Liquid phase viscosity log η_{L} (dPa · s) | 2.8 | 2.8 | 2.8 | 3.0 | 3.0 | 3.2 | 3.0 | 3.0 | 3.0 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | x | x | ◯ | x | x | x |
| Manufacturability determination | ◯ | ◯ | ◯ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 95 | 96 | 97 | 98 | 99 | 100 | 101 | 102 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.2 | 0.2 | 0.2 | 0.2 | 0.2 | 0.2 | 0.2 | 0.2 |
| SrO | 0.3 | 0.3 | 0.3 | 0.3 | 0.3 | 0.3 | 0.3 | 0.3 |
| BaO | 0.4 | 0.4 | 0.4 | 0.4 | 0.4 | 0.4 | 0.4 | 0.4 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1 | 1 | 1 | 1 | 1 | 1 | 1 | 1 |
| TiO₂ | 0.5 | 0.5 | 0.5 | 0.5 | 0.5 | 0.5 | 1 | 1 |
| Y₂O₃ | | 1 | 1 | 1.5 | 1.5 | 2.5 | | |
| Gd₂O₃ | 2.5 | | 1.5 | | 1 | | | 1 |
| La₂O₃ | | 1.5 | | 1 | | | 2 | 1 |
| WO₃ | | | | | | | | |
| Ta₂O₅ | | | | | | | | |
| Al₂O₃ + rare earth oxide | 16.5 | 16.5 | 16.5 | 16.5 | 16.5 | 16.5 | 16 | 16 |
| Y₂O₃ + Gd₂O₃ + La₂O₃ + Nd₂O₃ + Ta₂O₅ + Nb₂O₅ | 2.5 | 2.5 | 2.5 | 2.5 | 2.5 | 2.5 | 2 | 2 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 7 | 8 | 8 | 8 | 8 | 7 | 7 | 8 |
| Young's modulus E (GPa) | 98 | 98 | 98 | 98 | 98 | 99 | 98 | 98 |
| Thermal expansion coefficient α(ppm/° C.) | 4.14 | 3.98 | 4.03 | 3.94 | 3.97 | 3.86 | 3.98 | 4.01 |
| Liquid phase temperature T_{L} (° C.) | 1248 | 1230 | 1226 | 1230 | 1228 | 1214 | 1231 | 1227 |
| 13.1 · E+9 − T_{L} | 50 | 69 | 72 | 69 | 71 | 86 | 63 | 67 |
| 1923 − 156 · α − T_{L} | 29 | 72 | 68 | 78 | 75 | 107 | 72 | 70 |
| Young's modulus parameter Y | 0.97 | 0.97 | 0.97 | 0.98 | 0.98 | 0.98 | 0.97 | 0.96 |
| Liquid phase parameter L | 9.5 | 9.6 | 9.6 | 9.7 | 9.7 | 9.8 | 9.7 | 9.7 |
| Thermal expansion parameter C | 0.80 | 0.79 | 0.79 | 0.79 | 0.79 | 0.78 | 0.78 | 0.78 |
| Glass transition point (° C.) | 733 | 739 | 733 | 739 | 733 | 739 | 733 | 726 |
| Density (g/cm³) | 2.86 | 2.80 | 2.81 | 2.78 | 2.79 | 2.74 | 2.79 | 2.80 |
| Liquid phase viscosity log η_{L} (dPa · s) | 3.0 | 3.2 | 3.2 | 3.2 | 3.2 | 3.3 | 3.2 | 3.2 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | x | x | x | x | x | x |
| Manufacturability determination | ⊚ | ⊚ | ⊚ | ⊚ | ⊚ | ⊚ | ⊚ | ⊚ |

TABLE 7

| | Example | Example | Example | Example | Example | Example | Example | Example | Example |
|---|---|---|---|---|---|---|---|---|---|
| (mol %) | 103 | 104 | 105 | 106 | 107 | 108 | 109 | 110 | 111 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.2 | 0.2 | 0.2 | 0.2 | 0.2 | 0.2 | 0.2 | 0.2 | 0.2 |
| SrO | 0.3 | 0.3 | 0.3 | 0.3 | 0.3 | 0.3 | 0.3 | 0.3 | 0.3 |
| BaO | 0.4 | 0.4 | 0.4 | 0.4 | 0.4 | 0.4 | 0.4 | 0.4 | 0.4 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1 | 1 | 1 | 1 | 1 | 1 | 1 | 1.5 | 1.5 |
| TiO₂ | 1 | 1 | 1 | 1 | 1.5 | 1.5 | 1.5 | 0.5 | 0.5 |
| Y₂O₃ | | 1 | 1 | 2 | | | 1.5 | | |
| Gd₂O₃ | 2 | | 1 | | | 1.5 | | | 1 |
| La₂O₃ | | 1 | | | 1.5 | | | 2 | 1 |
| WO₃ | | | | | | | | | |
| Ta₂O₅ | | | | | | | | | |
| Al₂O₃ + rare earth oxide | 16 | 16 | 16 | 16 | 15.5 | 15.5 | 15.5 | 16 | 16 |
| Y₂O₃ + Gd₂O₃ + La₂O₃ + Nd₂O₃ + Ta₂O₅ + Nb₂O₅ | 2 | 2 | 2 | 2 | 1.5 | 1.5 | 1.5 | 2 | 2 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 7 | 8 | 8 | 7 | 7 | 7 | 7 | 7 | 8 |
| Young's modulus E (GPa) | 98 | 98 | 98 | 98 | 98 | 98 | 98 | 99 | 99 |
| Thermal expansion coefficient α(ppm/° C.) | 4.05 | 3.90 | 3.93 | 3.82 | 3.89 | 3.95 | 3.78 | 4.00 | 4.04 |
| Liquid phase temperature T_{L} (° C.) | 1226 | 1219 | 1214 | 1201 | 1224 | 1219 | 1217 | 1253 | 1249 |
| 13.1 · E+9 − T_{L} | 67 | 76 | 80 | 94 | 66 | 71 | 73 | 48 | 51 |
| 1923 − 156 · α − T_{L} | 65 | 96 | 95 | 127 | 91 | 88 | 117 | 46 | 44 |
| Young's modulus parameter Y | 0.96 | 0.97 | 0.97 | 0.97 | 0.96 | 0.96 | 0.96 | 0.97 | 0.97 |
| Liquid phase parameter L | 9.7 | 9.8 | 9.8 | 9.9 | 9.8 | 9.8 | 10.0 | 9.6 | 9.6 |
| Thermal expansion parameter C | 0.78 | 0.78 | 0.78 | 0.77 | 0.77 | 0.77 | 0.76 | 0.79 | 0.79 |
| Glass transition point (° C.) | 726 | 733 | 726 | 733 | 730 | 725 | 730 | 740 | 733 |
| Density (g/cm³) | 2.81 | 2.75 | 2.76 | 2.71 | 2.74 | 2.76 | 2.69 | 2.80 | 2.81 |
| Liquid phase viscosity log η_{L} (dPa · s) | 3.2 | 3.3 | 3.3 | 3.4 | 3.2 | 3.3 | 3.3 | 3.0 | 3.0 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | ◯ | x | x | ◯ | x | x |
| Manufacturability determination | ⊚ | ⊚ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 112 | 113 | 114 | 115 | 116 | 117 | 118 | 119 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.2 | 0.2 | 0.2 | 0.2 | 0.2 | 0.2 | 0.2 | 0.2 |
| SrO | 0.3 | 0.3 | 0.3 | 0.3 | 0.3 | 0.3 | 0.3 | 0.3 |
| BaO | 0.4 | 0.4 | 0.4 | 0.4 | 0.4 | 0.4 | 0.4 | 0.4 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1.5 | 1.5 | 1.5 | 1.5 | 1.5 | 1.5 | 1.5 | 1.5 |
| TiO₂ | 0.5 | 0.5 | 0.5 | 0.5 | 1 | 1 | 1 | 1.5 |
| Y₂O₃ | | 1 | 1 | 2 | | | 1.5 | |
| Gd₂O₃ | 2 | | 1 | | | 1.5 | | |
| La₂O₃ | | 1 | | | 1.5 | | | 1 |
| WO₃ | | | | | | | | |
| Ta₂O₅ | | | | | | | | |
| Al₂O₃ + rare earth oxide | 16 | 16 | 16 | 16 | 15.5 | 15.5 | 15.5 | 15 |
| Y₂O₃ + Gd₂O₃ + La₂O₃ + Nd₂O₃ + Ta₂O₅ + Nb₂O₅ | 2 | 2 | 2 | 2 | 1.5 | 1.5 | 1.5 | 1 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 7 | 8 | 8 | 7 | 7 | 7 | 7 | 7 |
| Young's modulus E (GPa) | 99 | 99 | 99 | 99 | 98 | 98 | 98 | 98 |
| Thermal expansion coefficient α(ppm/° C.) | 4.07 | 3.92 | 3.96 | 3.84 | 3.92 | 3.97 | 3.80 | 3.84 |
| Liquid phase temperature T_{L} (° C.) | 1249 | 1231 | 1227 | 1216 | 1232 | 1227 | 1219 | 1225 |
| 13.1 · E+9 − T_{L} | 52 | 70 | 74 | 86 | 64 | 69 | 78 | 68 |
| 1923 − 156 · α − T_{L} | 39 | 80 | 79 | 108 | 79 | 76 | 111 | 99 |
| Young's modulus parameter Y | 0.97 | 0.98 | 0.97 | 0.98 | 0.97 | 0.97 | 0.97 | 0.96 |
| Liquid phase parameter L | 9.6 | 9.7 | 9.7 | 9.8 | 9.8 | 9.8 | 9.9 | 9.9 |
| Thermal expansion parameter C | 0.79 | 0.78 | 0.78 | 0.77 | 0.77 | 0.77 | 0.76 | 0.76 |
| Glass transition point (° C.) | 733 | 740 | 733 | 740 | 733 | 726 | 733 | 731 |
| Density (g/cm³) | 2.82 | 2.76 | 2.77 | 2.72 | 2.75 | 2.76 | 2.69 | 2.71 |
| Liquid phase viscosity log η_{L} (dPa · s) | 3.0 | 3.1 | 3.2 | 3.3 | 3.1 | 3.2 | 3.3 | 3.2 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | x | x | x | x | ◯ | x |
| Manufacturability determination | ⊚ | ⊚ | ⊚ | ⊚ | ⊚ | ⊚ | ⊚ | ⊚ |

TABLE 8

| | Example | Example | Example | Example | Example | Example | Example | Example | Example |
|---|---|---|---|---|---|---|---|---|---|
| (mol %) | 120 | 121 | 122 | 123 | 124 | 125 | 126 | 127 | 128 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.2 | 0.2 | 0.2 | 0.2 | 0.2 | 0.2 | 0.2 | 0.2 | 0.2 |
| SrO | 0.3 | 0.3 | 0.4 | 0.4 | 0.4 | 0.4 | 0.4 | 0.4 | 0.4 |
| BaO | 0.4 | 0.4 | 0.3 | 0.3 | 0.3 | 0.3 | 0.3 | 0.3 | 0.3 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1.5 | 1.5 | 0.5 | 0.5 | 0.5 | 0.5 | 0.5 | 0.5 | 0.5 |
| TiO₂ | 1.5 | 1.5 | 0.5 | 0.5 | 0.5 | 0.5 | 0.5 | 0.5 | 0.5 |
| Y₂O₃ | | 1 | 1 | 1 | 1 | 1.5 | 1.5 | 2 | 2 |
| Gd₂O₃ | 1 | | | 1 | 2 | | 1.5 | | 1 |
| La₂O₃ | | | 2 | 1 | | 1.5 | | 1 | |
| WO₃ | | | | | | | | | |
| Ta₂O₅ | | | | | | | | | |
| Al₂O₃ + rare earth oxide | 15 | 15 | 17 | 17 | 17 | 17 | 17 | 17 | 17 |
| Y₂O₃ + Gd₂O₃ + La₂O₃ + Nd₂O₃ + Ta₂O₅ + Nb₂O₅ | 1 | 1 | 3 | 3 | 3 | 3 | 3 | 3 | 3 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 7 | 7 | 8 | 9 | 8 | 8 | 8 | 8 | 8 |
| Young's modulus E (GPa) | 98 | 98 | 98 | 98 | 98 | 98 | 98 | 98 | 98 |
| Thermal expansion coefficient α(ppm/° C.) | 3.87 | 3.76 | 4.03 | 4.07 | 4.10 | 3.99 | 4.05 | 3.95 | 3.99 |
| Liquid phase temperature T_{L} (° C.) | 1220 | 1218 | 1264 | 1261 | 1261 | 1260 | 1258 | 1243 | 1243 |
| 13.1 · E+9 − T_{L} | 72 | 74 | 33 | 36 | 35 | 38 | 38 | 55 | 54 |
| 1923 − 156 · α − T_{L} | 98 | 118 | 30 | 27 | 22 | 40 | 33 | 63 | 58 |
| Young's modulus parameter Y | 0.96 | 0.96 | 0.98 | 0.98 | 0.97 | 0.98 | 0.98 | 0.98 | 0.98 |
| Liquid phase parameter L | 9.9 | 10.1 | 9.5 | 9.5 | 9.5 | 9.5 | 9.5 | 9.6 | 9.6 |
| Thermal expansion parameter C | 0.76 | 0.75 | 0.80 | 0.80 | 0.80 | 0.80 | 0.80 | 0.79 | 0.79 |
| Glass transition point (° C.) | 725 | 731 | 738 | 732 | 732 | 738 | 732 | 738 | 732 |
| Density (g/cm³) | 2.71 | 2.67 | 2.84 | 2.85 | 2.85 | 2.82 | 2.83 | 2.80 | 2.81 |
| Liquid phase viscosity log η_{L} (dPa · s) | 3.2 | 3.3 | 2.9 | 2.9 | 2.9 | 2.9 | 2.9 | 3.1 | 3.1 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80 | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | ◯ | x | x | x | x | x | x | x |
| Manufacturability determination | ⊚ | ⊚ | ◯ | ◯ | ◯ | ⊚ | ⊚ | ⊚ | ⊚ |

| | Example | Example | Example | Example | Example | Example | Example | Example |
|---|---|---|---|---|---|---|---|---|
| (mol %) | 129 | 130 | 131 | 132 | 133 | 134 | 135 | 136 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.2 | 0.2 | 0.2 | 0.2 | 0.2 | 0.2 | 0.2 | 0.2 |
| SrO | 0.4 | 0.4 | 0.4 | 0.4 | 0.4 | 0.4 | 0.4 | 0.4 |
| BaO | 0.3 | 0.3 | 0.3 | 0.3 | 0.3 | 0.3 | 0.3 | 0.3 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 0.5 | 0.5 | 0.5 | 0.5 | 0.5 | 0.5 | 0.5 | 0.5 |
| TiO₂ | 1 | 1 | 1 | 1 | 1 | 1.5 | 1.5 | 1.5 |
| Y₂O₃ | 1 | 1 | 1.5 | 1.5 | 2.5 | | | |
| Gd₂O₃ | | 1.5 | | 1 | | | 1 | 2 |
| La₂O₃ | 1.5 | | 1 | | | 2 | 1 | |
| WO₃ | | | | | | | | |
| Ta₂O₅ | | | | | | | | |
| Al₂O₃ + rare earth oxide | 16.5 | 16.5 | 16.5 | 16.5 | 16.5 | 16 | 16 | 16 |
| Y₂O₃ + Gd₂O₃ + La₂O₃ + Nd₂O₃ + Ta₂O₅ + Nb₂O₅ | 2.5 | 2.5 | 2.5 | 2.5 | 2.5 | 2 | 2 | 2 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 8 | 8 | 8 | 8 | 7 | 7 | 8 | 7 |
| Young's modulus E (GPa) | 98 | 98 | 98 | 98 | 98 | 98 | 98 | 98 |
| Thermal expansion coefficient α(ppm/° C.) | 3.95 | 4.01 | 3.91 | 3.95 | 3.84 | 3.95 | 3.98 | 4.02 |
| Liquid phase temperature T_{L} (° C.) | 1253 | 1250 | 1247 | 1246 | 1227 | 1278 | 1276 | 1276 |
| 13.1 · E+9 − T_{L} | 40 | 42 | 46 | 47 | 66 | 10 | 12 | 12 |
| 1923 − 156 · α − T_{L} | 53 | 48 | 65 | 61 | 97 | 29 | 26 | 20 |
| Young's modulus parameter Y | 0.97 | 0.97 | 0.97 | 0.97 | 0.97 | 0.96 | 0.96 | 0.96 |
| Liquid phase parameter L | 9.6 | 9.6 | 9.7 | 9.7 | 9.8 | 9.7 | 9.7 | 9.7 |
| Thermal expansion parameter C | 0.79 | 0.79 | 0.78 | 0.78 | 0.78 | 0.78 | 0.78 | 0.78 |
| Glass transition point (° C.) | 733 | 727 | 733 | 727 | 733 | 731 | 726 | 726 |
| Density (g/cm³) | 2.79 | 2.80 | 2.77 | 2.78 | 2.73 | 2.78 | 2.79 | 2.80 |
| Liquid phase viscosity log η_{L} (dPa · s) | 3.0 | 3.0 | 3.0 | 3.0 | 3.2 | 2.8 | 2.8 | 2.8 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80 | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | x | x | ◯ | x | x | x |
| Manufacturability determination | ⊚ | ⊚ | ⊚ | ⊚ | ⊚ | ◯ | ◯ | ◯ |

TABLE 9

| | Example | Example | Example | Example | Example | Example | Example | Example | Example |
|---|---|---|---|---|---|---|---|---|---|
| (mol %) | 137 | 138 | 139 | 140 | 141 | 142 | 143 | 144 | 145 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | | 9 | 9 | 9 | 9 | 9 | 9 | 9 | 9 |
| MgO | 20 | 20 | 20 | 20 | 20 | 20 | 20 | 20 | 20 |
| CaO | 0.2 | 0.2 | 0.2 | 0.2 | 0.2 | 0.2 | 0.2 | 0.2 | 0.2 |
| SrO | 0.4 | 0.4 | 0.4 | 0.4 | 0.4 | 0.4 | 0.4 | 0.4 | 0.4 |
| BaO | 0.3 | 0.3 | 0.3 | 0.3 | 0.3 | 0.3 | 0.3 | 0.3 | 0.3 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 0.5 | 0.5 | 0.5 | 1 | 1 | 1 | 1 | 1 | 1 |
| TiO₂ | 1.5 | 1.5 | 4.5 | 0.5 | 0.5 | 0.5 | 0.5 | 0.5 | 0.5 |
| Y₂O₃ | 1 | 1 | 2 | | | | | 1 | 1 |
| Gd₂O₃ | | 1 | | | 1 | 1.5 | 2.5 | | 1.5 |
| La₂O₃ | 1 | | | 2.5 | 1.5 | 1 | | 1.5 | |
| WO₃ | | | | | | | | | |
| Ta₂O₅ | | | | | | | | | |
| Al₂O₃ + rare earth oxide | 16 | 16 | 16 | 16.5 | 16.5 | 16.5 | 16.5 | 16.5 | 16.5 |
| Y₂O₃ + Gd₂O₃ + La₂O₃ + Nd₂O₃ + Ta₂O₅ + Nb₂O₅ | 2 | 2 | 2 | 2.5 | 2.5 | 2.5 | 2.5 | 2.5 | 2.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 8 | 8 | 7 | 7 | 8 | 8 | 7 | 8 | 8 |
| Young's modulus E (GPa) | 98 | 98 | 98 | 98 | 98 | 98 | 98 | 99 | 98 |
| Thermal expansion coefficient α(ppm/° C.) | 3.87 | 3.91 | 3.79 | 4.06 | 4.09 | 4.11 | 4.14 | 3.98 | 4.03 |
| Liquid phase temperature T_{L} (° C.) | 1253 | 1250 | 1228 | 1252 | 1249 | 1248 | 1248 | 1230 | 1226 |
| 13.1 · E+9 − T_{L} | 36 | 38 | 61 | 47 | 49 | 50 | 50 | 69 | 73 |
| 1923 − 156 · α − T_{L} | 66 | 63 | 103 | 38 | 36 | 34 | 29 | 72 | 68 |
| Young's modulus parameter Y | 0.96 | 0.96 | 0.96 | 0.97 | 0.97 | 0.97 | 0.97 | 0.98 | 0.98 |
| Liquid phase parameter L | 9.8 | 9.8 | 9.9 | 9.5 | 9.5 | 9.5 | 9.5 | 9.6 | 9.6 |
| Thermal expansion parameter C | 0.77 | 0.77 | 0.76 | 0.80 | 0.80 | 0.80 | 0.80 | 0.79 | 0.79 |
| Glass transition point (° C.) | 731 | 726 | 731 | 738 | 732 | 732 | 733 | 738 | 732 |
| Density (g/cm³) | 2.74 | 2.75 | 2.70 | 2.84 | 2.85 | 2.85 | 2.86 | 2.80 | 2.81 |
| Liquid phase viscosity log η_{L} (dPa · s) | 3.0 | 3.0 | 3.2 | 3.0 | 3.0 | 3.0 | 3.0 | 3.2 | 3.2 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | x | x | x | x | x | x |
| Manufacturability determination | ⊚ | ⊚ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 146 | 147 | 148 | 149 | 150 | 151 | 152 | 153 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.2 | 0.2 | 0.2 | 0.2 | 0.2 | 0.2 | 0.2 | 0.2 |
| SrO | 0.4 | 0.4 | 0.4 | 0.4 | 0.4 | 0.4 | 0.4 | 0.4 |
| BaO | 0.3 | 0.3 | 0.3 | 0.3 | 0.3 | 0.3 | 0.3 | 0.3 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1 | 1 | 1 | 1 | 1 | 1 | 1 | 1 |
| TiO₂ | 0.5 | 0.5 | 0.5 | 1 | 1 | 1 | 1 | 1 |
| Y₂O₃ | 1.5 | 1.5 | 2.5 | | | | 1 | 1 |
| Gd₂O₃ | | 1 | | | 1 | 2 | | 1 |
| La₂O₃ | 1 | | | 2 | 1 | | 1 | |
| WO₃ | | | | | | | | |
| Ta₂O₅ | | | | | | | | |
| Al₂O₃ + rare earth oxide | 16.5 | 16.5 | 16.5 | 16 | 16 | 16 | 16 | 16 |
| Y₂O₃ + Gd₂O₃ + La₂O₃ + Nd₂O₃ + Ta₂O₅ + Nb₂O₅ | 2.5 | 2.5 | 2.5 | 2 | 2 | 2 | 2 | 2 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 8 | 8 | 7 | 7 | 8 | 7 | 8 | 8 |
| Young's modulus E (GPa) | 99 | 98 | 99 | 98 | 98 | 98 | 98 | 98 |
| Thermal expansion coefficient α(ppm/° C.) | 3.94 | 3.97 | 3.86 | 3.97 | 4.01 | 4.05 | 3.90 | 3.93 |
| Liquid phase temperature T_{L} (° C.) | 1231 | 1228 | 1214 | 1231 | 1227 | 1226 | 1219 | 1214 |
| 13.1 · E+9 − T_{L} | 69 | 71 | 86 | 63 | 67 | 68 | 76 | 80 |
| 1923 − 156 · α − T_{L} | 78 | 75 | 107 | 72 | 70 | 66 | 96 | 95 |
| Young's modulus parameter Y | 0.98 | 0.98 | 0.98 | 0.97 | 0.97 | 0.97 | 0.97 | 0.97 |
| Liquid phase parameter L | 9.6 | 9.6 | 9.7 | 9.6 | 9.6 | 9.6 | 9.8 | 9.8 |
| Thermal expansion parameter C | 0.79 | 0.79 | 0.78 | 0.78 | 0.78 | 0.78 | 0.78 | 0.78 |
| Glass transition point (° C.) | 738 | 732 | 738 | 733 | 726 | 727 | 733 | 726 |
| Density (g/cm³) | 2.78 | 2.79 | 2.74 | 2.79 | 2.80 | 2.81 | 2.75 | 2.76 |
| Liquid phase viscosity log η_{L} (dPa · s) | 3.2 | 3.2 | 3.3 | 3.2 | 3.2 | 3.2 | 3.3 | 3.3 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | x | x | x | x | x | x |
| Manufacturability determination | ⊚ | ⊚ | ⊚ | ⊚ | ⊚ | ⊚ | ⊚ | ⊚ |

TABLE 10

| | Example | Example | Example | Example | Example | Example | Example | Example | Example |
|---|---|---|---|---|---|---|---|---|---|
| (mol %) | 154 | 155 | 156 | 157 | 158 | 159 | 160 | 161 | 162 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.2 | 0.2 | 0.2 | 0.2 | 0.2 | 0.2 | 0.2 | 0.2 | 0.2 |
| SrO | 0.4 | 0.4 | 0.4 | 0.4 | 0.4 | 0.4 | 0.4 | 0.4 | 0.4 |
| BaO | 0.3 | 0.3 | 0.3 | 0.3 | 0.3 | 0.3 | 0.3 | 0.3 | 0.3 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1 | 1 | 1 | 1 | 1.5 | 1.5 | 1.5 | 1.5 | 1.5 |
| TiO₂ | 1 | 1.5 | 1.5 | 1.5 | 0.5 | 0.5 | 0.5 | 0.5 | 0.5 |
| Y₂O₃ | 2 | | | 1.5 | | | | 1 | 1 |
| Gd₂O₃ | | | 1.5 | | | 1 | 2 | | 1 |
| La₂O₃ | | 1.5 | | | 2 | 1 | | 1 | |
| WO₃ | | | | | | | | | |
| Ta₂O₅ | | | | | | | | | |
| Al₂O₃ + rare earth oxide | 16 | 15.5 | 15.5 | 15.5 | 16 | 16 | 16 | 16 | 16 |
| Y₂O₃ + Gd₂O₃ + La₂O₃ + Nd₂O₃ + Ta₂O₅ + Nb₂O₅ | 2 | 1.5 | 1.5 | 1.5 | 2 | 2 | 2 | 2 | 2 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 7 | 7 | 7 | 7 | 7 | 8 | 7 | 8 | 8 |
| Young's modulus E (GPa) | 98 | 98 | 98 | 98 | 99 | 99 | 99 | 99 | 99 |
| Thermal expansion coefficient α(ppm/° C.) | 3.82 | 3.89 | 3.95 | 3.78 | 4.00 | 4.04 | 4.07 | 3.92 | 3.96 |
| Liquid phase temperature T_{L} (° C.) | 1201 | 1224 | 1219 | 1217 | 1253 | 1249 | 1249 | 1231 | 1227 |
| 13.1 · E+9 − T_{L} | 95 | 66 | 71 | 74 | 48 | 52 | 52 | 70 | 74 |
| 1923 − 156 · α − T_{L} | 127 | 91 | 88 | 116 | 46 | 44 | 39 | 80 | 79 |
| Young's modulus parameter Y | 0.97 | 0.96 | 0.96 | 0.96 | 0.97 | 0.97 | 0.97 | 0.98 | 0.98 |
| Liquid phase parameter L | 9.9 | 9.8 | 9.8 | 10.0 | 9.6 | 9.6 | 9.6 | 9.7 | 9.7 |
| Thermal expansion parameter C | 0.77 | 0.77 | 0.77 | 0.76 | 0.79 | 0.79 | 0.79 | 0.78 | 0.78 |
| Glass transition point (° C.) | 733 | 730 | 726 | 730 | 739 | 733 | 733 | 739 | 733 |
| Density (g/cm³) | 2.71 | 2.74 | 2.75 | 2.68 | 2.80 | 2.81 | 2.81 | 2.76 | 2.77 |
| Liquid phase viscosity log η_{L} (dPa · s) | 3.4 | 3.2 | 3.3 | 3.3 | 3.0 | 3.0 | 3.0 | 3.1 | 3.2 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | ◯ | x | x | ◯ | x | x | x | x | x |
| Manufacturability determination | ⊚ | ⊚ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 163 | 164 | 165 | 166 | 167 | 168 | 169 | 170 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.2 | 0.2 | 0.2 | 0.2 | 0.2 | 0.2 | 0.2 | 0.2 |
| SrO | 0.4 | 0.4 | 0.4 | 0.4 | 0.4 | 0.4 | 0.4 | 0.5 |
| BaO | 0.3 | 0.3 | 0.3 | 0.3 | 0.3 | 0.3 | 0.3 | 0.2 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1.5 | 1.5 | 1.5 | 1.5 | 1.5 | 1.5 | 1.5 | 0.5 |
| TiO₂ | 0.5 | 1 | 1 | 1 | 1.5 | 1.5 | 1.5 | 0.5 |
| Y₂O₃ | 2 | | | 1.5 | | | 1 | 1 |
| Gd₂O₃ | | | 1.5 | | | 1 | | |
| La₂O₃ | | 1.5 | | | 1 | | | 2 |
| WO₃ | | | | | | | | |
| Ta₂O₅ | | | | | | | | |
| Al₂O₃ + rare earth oxide | 16 | 15.5 | 15.5 | 15.5 | 15 | 15 | 15 | 17 |
| Y₂O₃ + Gd₂O₃ + La₂O₃ + Nd₂O₃ + Ta₂O₅ + Nb₂O₅ | 2 | 1.5 | 1.5 | 1.5 | 1 | 1 | 1 | 3 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 7 | 7 | 7 | 7 | 7 | 7 | 7 | 9 |
| Young's modulus E (GPa) | 99 | 98 | 98 | 98 | 98 | 98 | 98 | 98 |
| Thermal expansion coefficient α(ppm/° C.) | 3.84 | 3.92 | 3.97 | 3.80 | 3.84 | 3.87 | 3.76 | 4.03 |
| Liquid phase temperature T_{L} (° C.) | 1216 | 1232 | 1227 | 1219 | 1225 | 1220 | 1218 | 1267 |
| 13.1 · E+9 − T_{L} | 87 | 65 | 69 | 79 | 68 | 72 | 75 | 31 |
| 1923 − 156 · α − T_{L} | 108 | 79 | 76 | 111 | 99 | 98 | 118 | 27 |
| Young's modulus parameter Y | 0.98 | 0.97 | 0.97 | 0.97 | 0.96 | 0.96 | 0.96 | 0.98 |
| Liquid phase parameter L | 9.8 | 9.8 | 9.8 | 9.9 | 9.9 | 9.9 | 10.0 | 9.5 |
| Thermal expansion parameter C | 0.77 | 0.77 | 0.77 | 0.76 | 0.76 | 0.76 | 0.75 | 0.80 |
| Glass transition point (° C.) | 739 | 733 | 727 | 733 | 731 | 726 | 731 | 741 |
| Density (g/cm³) | 2.72 | 2.75 | 2.76 | 2.69 | 2.70 | 2.71 | 2.66 | 2.84 |
| Liquid phase viscosity log η_{L} (dPa · s) | 3.3 | 3.1 | 3.2 | 3.3 | 3.2 | 3.2 | 3.3 | 2.9 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | x | ◯ | x | x | ◯ | x |
| Manufacturability determination | ⊚ | ⊚ | ⊚ | ⊚ | ⊚ | ⊚ | ⊚ | ⊚ |

TABLE 11

| | Example | Example | Example | Example | Example | Example | Example | Example | Example |
|---|---|---|---|---|---|---|---|---|---|
| (mol %) | 171 | 172 | 173 | 174 | 175 | 176 | 177 | 178 | 179 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.2 | 0.2 | 0.2 | 0.2 | 0.2 | 0.2 | 0.2 | 0.2 | 0.2 |
| SrO | 0.5 | 0.5 | 0.5 | 0.5 | 0.5 | 0.5 | 0.5 | 0.5 | 0.5 |
| BaO | 0.2 | 0.2 | 0.2 | 0.2 | 0.2 | 0.2 | 0.2 | 0.2 | 0.2 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 0.5 | 0.5 | 0.5 | 0.5 | 0.5 | 0.5 | 0.5 | 0.5 | 0.5 |
| TiO₂ | 0.5 | 0.5 | 0.5 | 0.5 | 0.5 | 0.5 | 1 | 1 | 1 |
| Y₂O₃ | 1 | 1 | 1.5 | 1.5 | 2 | 2 | 1 | 1 | 1.5 |
| Gd₂O₃ | 1 | 2 | | 1.5 | | 1 | | 1.5 | |
| La₂O₃ | 1 | | 1.5 | | 1 | | 1.5 | | 1 |
| WO₃ | | | | | | | | | |
| Ta₂O₅ | | | | | | | | | |
| Al₂O₃ + rare earth oxide | 17 | 17 | 17 | 17 | 17 | 17 | 16.5 | 16.5 | 16.5 |
| Y₂O₃ + Gd₂O₃ + La₂O₃ + Nd₂O₃ + Ta₂O₅ + Nb₂O₅ | 3 | 3 | 3 | 3 | 3 | 3 | 2.5 | 2.5 | 2.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 10 | 9 | 9 | 9 | 9 | 9 | 9 | 9 | 9 |
| Young's modulus E (GPa) | 98 | 98 | 98 | 98 | 98 | 98 | 98 | 98 | 98 |
| Thermal expansion coefficient α(ppm/° C.) | 4.07 | 4.10 | 3.99 | 4.05 | 3.95 | 3.99 | 3.95 | 4.01 | 3.91 |
| Liquid phase temperature T_{L} (° C.) | 1265 | 1265 | 1263 | 1262 | 1248 | 1248 | 1257 | 1254 | 1250 |
| 13.1 · E+9 − T_{L} | 33 | 32 | 35 | 36 | 50 | 49 | 37 | 39 | 43 |
| 1923 − 156 · α − T_{L} | 24 | 18 | 37 | 30 | 58 | 52 | 50 | 44 | 62 |
| Young's modulus parameter Y | 0.98 | 0.98 | 0.98 | 0.98 | 0.98 | 0.98 | 0.97 | 0.97 | 0.97 |
| Liquid phase parameter L | 9.5 | 9.5 | 9.5 | 9.5 | 9.6 | 9.6 | 9.6 | 9.6 | 9.7 |
| Thermal expansion parameter C | 0.80 | 0.80 | 0.80 | 0.80 | 0.79 | 0.79 | 0.79 | 0.79 | 0.78 |
| Glass transition point (° C.) | 735 | 735 | 741 | 735 | 741 | 735 | 735 | 729 | 735 |
| Density (g/cm³) | 2.84 | 2.85 | 2.82 | 2.83 | 2.80 | 2.80 | 2.79 | 2.80 | 2.77 |
| Liquid phase viscosity log η_{L} (dPa · s) | 2.9 | 2.9 | 2.9 | 2.9 | 3.0 | 3.0 | 3.0 | 3.0 | 3.0 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | x | x | x | x | x | x |
| Manufacturability determination | ◯ | ◯ | ◯ | ◯ | ⊚ | ⊚ | ⊚ | ⊚ | ⊚ |

| | Example | Example | Example | Example | Example | Example | Example | Example |
|---|---|---|---|---|---|---|---|---|
| (mol %) | 180 | 181 | 182 | 183 | 184 | 185 | 186 | 187 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.2 | 0.2 | 0.2 | 0.2 | 0.2 | 0.2 | 0.2 | 0.2 |
| SrO | 0.5 | 0.5 | 0.5 | 0.5 | 0.5 | 0.5 | 0.5 | 0.5 |
| BaO | 0.2 | 0.2 | 0.2 | 0.2 | 0.2 | 0.2 | 0.2 | 0.2 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 0.5 | 0.5 | 0.5 | 0.5 | 0.5 | 0.5 | 0.5 | 1 |
| TiO₂ | 1 | 1 | 1.5 | 1.5 | 1.5 | 1.5 | 1.5 | 0.5 |
| Y₂O₃ | 1.5 | 2.5 | | | 1 | 1 | 2 | |
| Gd₂O₃ | 1 | | 1 | 2 | | 1 | | |
| La₂O₃ | | | 1 | | 1 | | | 2.5 |
| WO₃ | | | | | | | | |
| Ta₂O₅ | | | | | | | | |
| Al₂O₃ + rare earth oxide | 16.5 | 16.5 | 16 | 16 | 16 | 16 | 16 | 16.5 |
| Y₂O₃ + Gd₂O₃ + La₂O₃ + Nd₂O₃ + Ta₂O₅ + Nb₂O₅ | 2.5 | 2.5 | 2 | 2 | 2 | 2 | 2 | 2.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 9 | 8 | 9 | 8 | 9 | 9 | 8 | 8 |
| Young's modulus E (GPa) | 98 | 98 | 98 | 98 | 98 | 98 | 98 | 99 |
| Thermal expansion coefficient α(ppm/° C.) | 3.95 | 3.84 | 3.98 | 4.02 | 3.87 | 3.91 | 3.79 | 4.05 |
| Liquid phase temperature T_{L} (° C.) | 1249 | 1232 | 1279 | 1279 | 1256 | 1253 | 1233 | 1255 |
| 13.1 · E+9 − T_{L} | 44 | 62 | 9 | | 33 | 35 | 57 | 44 |
| 1923 − 156 · α − T_{L} | 58 | 93 | 22 | 17 | 63 | 60 | 99 | 35 |
| Young's modulus parameter Y | 0.97 | 0.97 | 0.96 | 0.96 | 0.96 | 0.96 | 0.96 | 0.97 |
| Liquid phase parameter L | 9.7 | 9.8 | 9.7 | 9.7 | 9.8 | 9.8 | 9.9 | 9.5 |
| Thermal expansion parameter C | 0.78 | 0.78 | 0.78 | 0.78 | 0.77 | 0.77 | 0.77 | 0.80 |
| Glass transition point (° C.) | 729 | 735 | 728 | 728 | 733 | 728 | 733 | 741 |
| Density (g/cm³) | 2.78 | 2.73 | 2.79 | 2.80 | 2.74 | 2.75 | 2.70 | 2.84 |
| Liquid phase viscosity log η_{L} (dPa · s) | 3.0 | 3.1 | 2.8 | 2.8 | 3.0 | 3.0 | 3.1 | 3.0 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | ◯ | x | x | x | x | ◯ | x |
| Manufacturability determination | ⊚ | ⊚ | ◯ | ◯ | ⊚ | ⊚ | ⊚ | ⊚ |

TABLE 12

| | Example | Example | Example | Example | Example | Example | Example | Example | Example |
|---|---|---|---|---|---|---|---|---|---|
| (mol %) | 188 | 189 | 190 | 191 | 192 | 193 | 194 | 195 | 196 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.2 | 0.2 | 0.2 | 0.2 | 0.2 | 0.2 | 0.2 | 0.2 | 0.2 |
| SrO | 0.5 | 0.5 | 0.5 | 0.5 | 0.5 | 0.5 | 0.5 | 0.5 | 0.5 |
| BaO | 0.2 | 0.2 | 0.2 | 0.2 | 0.2 | 0.2 | 0.2 | 0.2 | 0.2 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1 | 1 | 1 | 1 | 1 | 1 | 1 | 1 | 1 |
| TiO₂ | 0.5 | 0.5 | 0.5 | 0.5 | 0.5 | 0.5 | 0.5 | 0.5 | 1 |
| Y₂O₃ | | | | 1 | 1 | 1.5 | 1.5 | 2.5 | |
| Gd₂O₃ | 1 | 1.5 | 2.5 | | 1.5 | | 1 | | |
| La₂O₃ | 1.5 | 1 | | 1.5 | | 1 | | | 2 |
| WO₃ | | | | | | | | | |
| Ta₂O₅ | | | | | | | | | |
| Al₂O₃ + rare earth oxide | 16.5 | 16.5 | 16.5 | 16.5 | 16.5 | 16.5 | 16.5 | 16.5 | 16 |
| Y₂O₃ + Gd₂O₃ + La₂O₃ + Nd₂O₃ + Ta₂O₅ + Nb₂O₅ | 2.5 | 2.5 | 2.5 | 2.5 | 2.5 | 2.5 | 2.5 | 2.5 | 2 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 9 | 9 | 8 | 9 | 9 | 9 | 9 | 8 | 8 |
| Young's modulus E (GPa) | 98 | 98 | 98 | 99 | 99 | 99 | 99 | 99 | 98 |
| Thermal expansion coefficient α(ppm/° C.) | 4.09 | 4.11 | 4.14 | 3.98 | 4.03 | 3.94 | 3.97 | 3.86 | 3.97 |
| Liquid phase temperature T_{L} (° C.) | 1252 | 1251 | 1251 | 1233 | 1229 | 1233 | 1231 | 1218 | 1234 |
| 13.1 · E+9 − T_{L} | 47 | 48 | 48 | 67 | 70 | 67 | 69 | 83 | 61 |
| 1923 − 156 · α − T_{L} | 33 | 31 | 26 | 69 | 65 | 75 | 72 | 103 | 69 |
| Young's modulus parameter Y | 0.97 | 0.97 | 0.97 | 0.98 | 0.98 | 0.98 | 0.98 | 0.98 | 0.97 |
| Liquid phase parameter L | 9.5 | 9.5 | 9.5 | 9.6 | 9.6 | 9.6 | 9.6 | 9.7 | 9.6 |
| Thermal expansion parameter C | 0.80 | 0.80 | 0.80 | 0.79 | 0.79 | 0.79 | 0.79 | 0.78 | 0.78 |
| Glass transition point (° C.) | 735 | 735 | 735 | 741 | 735 | 741 | 735 | 741 | 735 |
| Density (g/cm³) | 2.84 | 2.85 | 2.86 | 2.80 | 2.81 | 2.78 | 2.79 | 2.74 | 2.79 |
| Liquid phase viscosity log η_{L} (dPa · s) | 3.0 | 3.0 | 3.0 | 3.1 | 3.2 | 3.1 | 3.1 | 3.3 | 3.1 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | x | x | x | x | x | x |
| Manufacturability determination | ⊚ | ⊚ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 197 | 198 | 199 | 200 | 201 | 202 | 203 | 204 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.2 | 0.2 | 0.2 | 0.2 | 0.2 | 0.2 | 0.2 | 0.2 |
| SrO | 0.5 | 0.5 | 0.5 | 0.5 | 0.5 | 0.5 | 0.5 | 0.5 |
| BaO | 0.2 | 0.2 | 0.2 | 0.2 | 0.2 | 0.2 | 0.2 | 0.2 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1 | 1 | 1 | 1 | 1 | 1 | 1 | 1 |
| TiO₂ | 1 | 1 | 1 | 1 | 1 | 1.5 | 1.5 | 1.5 |
| Y₂O₃ | | | 1 | 1 | 2 | | | 1.5 |
| Gd₂O₃ | 1 | 2 | | 1 | | | 1.5 | |
| La₂O₃ | 1 | | 1 | | | 1.5 | | |
| WO₃ | | | | | | | | |
| Ta₂O₅ | | | | | | | | |
| Al₂O₃ + rare earth oxide | 16 | 16 | 16 | 16 | 16 | 15.5 | 15.5 | 15.5 |
| Y₂O₃ + Gd₂O₃ + La₂O₃ + Nd₂O₃ + Ta₂O₅ + Nb₂O₅ | 2 | 2 | 2 | 2 | 2 | 1.5 | 1.5 | 1.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 9 | 8 | 9 | 9 | 8 | 8 | 8 | 8 |
| Young's modulus E (GPa) | 98 | 98 | 98 | 98 | 98 | 98 | 98 | 98 |
| Thermal expansion coefficient α(ppm/° C.) | 4.01 | 4.05 | 3.90 | 3.93 | 3.82 | 3.89 | 3.95 | 3.78 |
| Liquid phase temperature T_{L} (° C.) | 1230 | 1229 | 1222 | 1217 | 1204 | 1227 | 1222 | 1220 |
| 13.1 · E+9 − T_{L} | 65 | 65 | 74 | 78 | 92 | 63 | 68 | 71 |
| 1923 − 156 · α − T_{L} | 67 | 62 | 93 | 92 | 124 | 88 | 85 | 113 |
| Young's modulus parameter Y | 0.97 | 0.97 | 0.97 | 0.97 | 0.97 | 0.96 | 0.96 | 0.96 |
| Liquid phase parameter L | 9.6 | 9.6 | 9.7 | 9.7 | 9.8 | 9.8 | 9.8 | 10.0 |
| Thermal expansion parameter C | 0.78 | 0.78 | 0.78 | 0.78 | 0.77 | 0.77 | 0.77 | 0.76 |
| Glass transition point (° C.) | 728 | 729 | 735 | 728 | 735 | 733 | 728 | 733 |
| Density (g/cm³) | 2.80 | 2.80 | 2.75 | 2.76 | 2.71 | 2.74 | 2.75 | 2.68 |
| Liquid phase viscosity log η_{L} (dPa · s) | 3.2 | 3.2 | 3.2 | 3.3 | 3.4 | 3.2 | 3.2 | 3.2 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | x | x | ◯ | x | x | ◯ |
| Manufacturability determination | ⊚ | ⊚ | ⊚ | ⊚ | ⊚ | ⊚ | ⊚ | ⊚ |

TABLE 13

| | Example | Example | Example | Example | Example | Example | Example | Example | Example |
|---|---|---|---|---|---|---|---|---|---|
| (mol %) | 205 | 206 | 207 | 208 | 209 | 210 | 211 | 212 | 213 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.2 | 0.2 | 0.2 | 0.2 | 0.2 | 0.2 | 0.2 | 0.2 | 0.2 |
| SrO | 0.5 | 0.5 | 0.5 | 0.5 | 0.5 | 0.5 | 0.5 | 0.5 | 0.5 |
| BaO | 0.2 | 0.2 | 0.2 | 0.2 | 0.2 | 0.2 | 0.2 | 0.2 | 0.2 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1.5 | 1.5 | 1.5 | 1.5 | 1.5 | 1.5 | 1.5 | 1.5 | 1.5 |
| TiO₂ | 0.5 | 0.5 | 0.5 | 0.5 | 0.5 | 0.5 | 1 | 1 | 1 |
| Y₂O₃ | | | | 1 | 1 | 2 | | | 1.5 |
| Gd₂O₃ | | 1 | 2 | | 1 | | | 1.5 | |
| La₂O₃ | 2 | 1 | | 1 | | | 1.5 | | |
| WO₃ | | | | | | | | | |
| Ta₂O₅ | | | | | | | | | |
| Al₂O₃ + rare earth oxide | 16 | 16 | 16 | 16 | 16 | 16 | 15.5 | 15.5 | 15.5 |
| Y₂O₃ + Gd₂O₃ + La₂O₃ + Nd₂O₃ + Ta₂O₅ + Nb₂O₅ | 2 | 2 | 2 | 2 | 2 | 2 | 1.5 | 1.5 | 1.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 8 | 9 | 8 | 9 | 9 | 8 | 8 | 8 | 8 |
| Young's modulus E (GPa) | 99 | 99 | 99 | 99 | 99 | 99 | 98 | 98 | 98 |
| Thermal expansion coefficient α(ppm/° C.) | 4.00 | 4.04 | 4.07 | 3.92 | 3.96 | 3.84 | 3.92 | 3.97 | 3.80 |
| Liquid phase temperature T_{L} (° C.) | 1257 | 1253 | 1252 | 1235 | 1231 | 1221 | 1237 | 1232 | 1223 |
| 13.1 · E+9 − T_{L} | 45 | 48 | 49 | 67 | 71 | 82 | 61 | 65 | 75 |
| 1923 − 156 · α − T_{L} | 42 | 40 | 35 | 76 | 75 | 103 | 75 | 72 | 107 |
| Young's modulus parameter Y | 0.97 | 0.97 | 0.97 | 0.98 | 0.98 | 0.98 | 0.97 | 0.97 | 0.97 |
| Liquid phase parameter L | 9.6 | 9.6 | 9.6 | 9.7 | 9.7 | 9.8 | 9.7 | 9.7 | 9.9 |
| Thermal expansion parameter C | 0.79 | 0.79 | 0.79 | 0.78 | 0.78 | 0.77 | 0.77 | 0.77 | 0.76 |
| Glass transition point (° C.) | 741 | 735 | 735 | 741 | 735 | 741 | 735 | 729 | 735 |
| Density (g/cm³) | 2.80 | 2.81 | 2.81 | 2.76 | 2.77 | 2.72 | 2.75 | 2.76 | 2.69 |
| Liquid phase viscosity log η_{L} (dPa · s) | 2.9 | 3.0 | 3.0 | 3.1 | 3.2 | 3.2 | 3.1 | 3.1 | 3.2 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | x | x | x | x | x | ◯ |
| Manufacturability determination | ⊚ | ⊚ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 214 | 215 | 216 | 217 | 218 | 219 | 220 | 221 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.2 | 0.2 | 0.2 | 0.3 | 0.3 | 0.3 | 0.3 | 0.3 |
| SrO | 0.5 | 0.5 | 0.5 | 0.2 | 0.2 | 0.2 | 0.2 | 0.2 |
| BaO | 0.2 | 0.2 | 0.2 | 0.4 | 0.4 | 0.4 | 0.4 | 0.4 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1.5 | 1.5 | 1.5 | 0.5 | 0.5 | 0.5 | 0.5 | 0.5 |
| TiO₂ | 1.5 | 1.5 | 1.5 | 0.5 | 0.5 | 0.5 | 0.5 | 0.5 |
| Y₂O₃ | | | 1 | 1 | 1 | 1 | 1.5 | 1.5 |
| Gd₂O₃ | | 1 | | | 1 | 2 | | 1.5 |
| La₂O₃ | 1 | | | 2 | 1 | | 1.5 | |
| WO₃ | | | | | | | | |
| Ta₂O₅ | | | | | | | | |
| Al₂O₃ + rare earth oxide | 15 | 15 | 15 | 17 | 17 | 17 | 17 | 17 |
| Y₂O₃ + Gd₂O₃ + La₂O₃ + Nd₂O₃ + Ta₂O₅ + Nb₂O₅ | 1 | 1 | 1 | 3 | 3 | 3 | 3 | 3 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 8 | 8 | 8 | 8 | 9 | 8 | 8 | 8 |
| Young's modulus E (GPa) | 98 | 98 | 98 | 98 | 98 | 98 | 98 | 98 |
| Thermal expansion coefficient α(ppm/° C.) | 3.84 | 3.87 | 3.76 | 4.03 | 4.06 | 4.10 | 3.99 | 4.04 |
| Liquid phase temperature T_{L} (° C.) | 1229 | 1225 | 1222 | 1268 | 1266 | 1266 | 1264 | 1263 |
| 13.1 · E+9 − T_{L} | 64 | 68 | 71 | 29 | 31 | 31 | 33 | 34 |
| 1923 − 156 · α − T_{L} | 95 | 94 | 114 | 26 | 23 | 18 | 37 | 30 |
| Young's modulus parameter Y | 0.96 | 0.96 | 0.96 | 0.97 | 0.97 | 0.97 | 0.98 | 0.97 |
| Liquid phase parameter L | 9.9 | 9.9 | 10.0 | 9.5 | 9.5 | 9.5 | 9.6 | 9.6 |
| Thermal expansion parameter C | 0.76 | 0.76 | 0.75 | 0.80 | 0.80 | 0.80 | 0.80 | 0.80 |
| Glass transition point (° C.) | 733 | 728 | 733 | 741 | 734 | 734 | 741 | 734 |
| Density (g/cm³) | 2.70 | 2.71 | 2.66 | 2.84 | 2.85 | 2.85 | 2.82 | 2.83 |
| Liquid phase viscosity log η_{L} (dPa · s) | 3.2 | 3.2 | 3.2 | 2.9 | 2.9 | 2.9 | 2.9 | 2.9 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | ◯ | x | x | x | x | x |
| Manufacturability determination | ⊚ | ⊚ | ⊚ | ◯ | ◯ | ◯ | ◯ | ◯ |

TABLE 14

| | Example | Example | Example | Example | Example | Example | Example | Example | Example |
|---|---|---|---|---|---|---|---|---|---|
| (mol %) | 222 | 223 | 224 | 225 | 226 | 227 | 228 | 229 | 230 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.3 | 0.3 | 0.3 | 0.3 | 0.3 | 0.3 | 0.3 | 0.3 | 0.3 |
| SrO | 0.2 | 0.2 | 0.2 | 0.2 | 0.2 | 0.2 | 0.2 | 0.2 | 0.2 |
| BaO | 0.4 | 0.4 | 0.4 | 0.4 | 0.4 | 0.4 | 0.4 | 0.4 | 0.4 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 0.5 | 0.5 | 0.5 | 0.5 | 0.5 | 0.5 | 0.5 | 0.5 | 0.5 |
| TiO₂ | 0.5 | 0.5 | 1 | 1 | 1 | 1 | 1 | 1.5 | 1.5 |
| Y₂O₃ | 2 | 2 | 1 | 1 | 1.5 | 1.5 | 2.5 | | |
| Gd₂O₃ | | 1 | | 1.5 | | 1 | | 1 | 2 |
| La₂O₃ | 1 | | 1.5 | | 1 | | | 1 | |
| WO₃ | | | | | | | | | |
| Ta₂O₅ | | | | | | | | | |
| Al₂O₃ + rare earth oxide | 17 | 17 | 16.5 | 16.5 | 16.5 | 16.5 | 16.5 | 16 | 16 |
| Y₂O₃ + Gd₂O₃ + La₂O₃ + Nd₂O₃ + Ta₂O₅ + Nb₂O₅ | 3 | 3 | 2.5 | 2.5 | 2.5 | 2.5 | 2.5 | 2 | 2 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 8 | 8 | 8 | 8 | 8 | 8 | 7 | 8 | 7 |
| Young's modulus E (GPa) | 98 | 98 | 98 | 98 | 98 | 98 | 98 | 98 | 98 |
| Thermal expansion coefficient α(ppm/° C.) | 3.95 | 3.99 | 3.95 | 4.00 | 3.91 | 3.94 | 3.83 | 3.98 | 4.02 |
| Liquid phase temperature T_{L} (° C.) | 1249 | 1249 | 1257 | 1254 | 1251 | 1249 | 1233 | 1278 | 1278 |
| 13.1 · E+9 − T_{L} | 49 | 48 | 35 | 38 | 42 | 43 | 61 | 9 | 9 |
| 1923 − 156 · α − T_{L} | 58 | 53 | 50 | 44 | 62 | 58 | 93 | 24 | 18 |
| Young's modulus parameter Y | 0.98 | 0.98 | 0.97 | 0.97 | 0.97 | 0.97 | 0.97 | 0.96 | 0.96 |
| Liquid phase parameter L | 9.6 | 9.6 | 9.7 | 9.7 | 9.7 | 9.7 | 9.8 | 9.7 | 9.7 |
| Thermal expansion parameter C | 0.79 | 0.79 | 0.79 | 0.79 | 0.78 | 0.78 | 0.77 | 0.78 | 0.78 |
| Glass transition point (° C.) | 741 | 734 | 734 | 727 | 734 | 727 | 734 | 726 | 726 |
| Density (g/cm³) | 2.80 | 2.81 | 2.79 | 2.80 | 2.77 | 2.78 | 2.73 | 2.79 | 2.80 |
| Liquid phase viscosity log η_{L} (dPa · s) | 3.0 | 3.0 | 2.9 | 3.0 | 3.0 | 3.0 | 3.1 | 2.8 | 2.8 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | x | x | x | ◯ | x | x |
| Manufacturability determination | ⊚ | ⊚ | ⊚ | ⊚ | ⊚ | ⊚ | ⊚ | ◯ | ◯ |

| | Example | Example | Example | Example | Example | Example | Example | Example |
|---|---|---|---|---|---|---|---|---|
| (mol %) | 231 | 232 | 233 | 234 | 235 | 236 | 237 | 238 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.3 | 0.3 | 0.3 | 0.3 | 0.3 | 0.3 | 0.3 | 0.3 |
| SrO | 0.2 | 0.2 | 0.2 | 0.2 | 0.2 | 0.2 | 0.2 | 0.2 |
| BaO | 0.4 | 0.4 | 0.4 | 0.4 | 0.4 | 0.4 | 0.4 | 0.4 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 0.5 | 0.5 | 0.5 | 1 | 1 | 1 | 1 | 1 |
| TiO₂ | 1.5 | 1.5 | 1.5 | 0.5 | 0.5 | 0.5 | 0.5 | 0.5 |
| Y₂O₃ | 1 | 1 | 2 | | | | | 1 |
| Gd₂O₃ | | 1 | | | 1 | 1.5 | 2.5 | |
| La₂O₃ | 1 | | | 2.5 | 1.5 | 1 | | 1.5 |
| WO₃ | | | | | | | | |
| Ta₂O₅ | | | | | | | | |
| Al₂O₃ + rare earth oxide | 16 | 16 | 16 | 16.5 | 16.5 | 16.5 | 16.5 | 16.5 |
| Y₂O₃ + Gd₂O₃ + La₂O₃ + Nd₂O₃ + Ta₂O₅ + Nb₂O₅ | 2 | 2 | 2 | 2.5 | 2.5 | 2.5 | 2.5 | 2.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 8 | 8 | 7 | 7 | 8 | 8 | 7 | 8 |
| Young's modulus E (GPa) | 98 | 98 | 98 | 98 | 98 | 98 | 98 | 98 |
| Thermal expansion coefficient α(ppm/° C.) | 3.87 | 3.90 | 3.79 | 4.05 | 4.09 | 4.10 | 4.14 | 3.97 |
| Liquid phase temperature T_{L} (° C.) | 1258 | 1255 | 1234 | 1255 | 1251 | 1251 | 1250 | 1235 |
| 13.1 · E+9 − T_{L} | 30 | 33 | 54 | 44 | 47 | 48 | 48 | 64 |
| 1923 − 156 · α − T_{L} | 62 | 59 | 98 | 37 | 34 | 32 | 27 | 68 |
| Young's modulus parameter Y | 0.96 | 0.96 | 0.96 | 0.97 | 0.97 | 0.97 | 0.97 | 0.97 |
| Liquid phase parameter L | 9.9 | 9.9 | 10.0 | 9.5 | 9.5 | 9.5 | 9.5 | 9.6 |
| Thermal expansion parameter C | 0.77 | 0.77 | 0.76 | 0.80 | 0.80 | 0.80 | 0.80 | 0.79 |
| Glass transition point (° C.) | 731 | 726 | 731 | 741 | 734 | 734 | 734 | 741 |
| Density (g/cm³) | 2.74 | 2.75 | 2.70 | 2.84 | 2.85 | 2.85 | 2.86 | 2.80 |
| Liquid phase viscosity log η_{L} (dPa · s) | 2.9 | 3.0 | 3.1 | 3.0 | 3.0 | 3.0 | 3.0 | 3.1 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | ◯ | x | x | x | x | x |
| Manufacturability determination | ⊚ | ⊚ | ⊚ | ⊚ | ⊚ | ⊚ | ⊚ | ⊚ |

TABLE 15

| | Example | Example | Example | Example | Example | Example | Example | Example | Example |
|---|---|---|---|---|---|---|---|---|---|
| (mol %) | 239 | 240 | 241 | 242 | 243 | 244 | 245 | 246 | 247 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.3 | 0.3 | 0.3 | 0.3 | 0.3 | 0.3 | 0.3 | 0.3 | 0.3 |
| SrO | 0.2 | 0.2 | 0.2 | 0.2 | 0.2 | 0.2 | 0.2 | 0.2 | 0.2 |
| BaO | 0.4 | 0.4 | 0.4 | 0.4 | 0.4 | 0.4 | 0.4 | 0.4 | 0.4 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1 | 1 | 1 | 1 | 1 | 1 | 1 | 1 | 1 |
| TiO₂ | 0.5 | 0.5 | 0.5 | 0.5 | 1 | 1 | 1 | 1 | 1 |
| Y₂O₃ | 1 | 1.5 | 1.5 | 2.5 | | | | 1 | 1 |
| Gd₂O₃ | 1.5 | | 1 | | | 1 | 2 | | 1 |
| La₂O₃ | | 1 | | | 2 | 1 | | 1 | |
| WO₃ | | | | | | | | | |
| Ta₂O₅ | | | | | | | | | |
| Al₂O₃ + rare earth oxide | 16.5 | 16.5 | 16.5 | 16.5 | 16 | 16 | 16 | 16 | 16 |
| Y₂O₃ + Gd₂O₃ + La₂O₃ + Nd₂O₃ + Ta₂O₅ + Nb₂O₅ | 2.5 | 2.5 | 2.5 | 2.5 | 2 | 2 | 2 | 2 | 2 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 8 | 8 | 8 | 7 | 7 | 8 | 7 | 8 | 8 |
| Young's modulus E (GPa) | 98 | 99 | 98 | 99 | 98 | 98 | 98 | 98 | 98 |
| Thermal expansion coefficient α(ppm/° C.) | 4.03 | 3.93 | 3.97 | 3.86 | 3.97 | 4.01 | 4.04 | 3.89 | 3.93 |
| Liquid phase temperature T_{L} (° C.) | 1231 | 1235 | 1233 | 1219 | 1233 | 1229 | 1228 | 1223 | 1219 |
| 13.1 · E+9 − T_{L} | 68 | 64 | 66 | 81 | 62 | 65 | 66 | 72 | 76 |
| 1923 − 156 · α − T_{L} | 64 | 74 | 71 | 103 | 71 | 69 | 65 | 93 | 92 |
| Young's modulus parameter Y | 0.97 | 0.98 | 0.98 | 0.98 | 0.97 | 0.96 | 0.96 | 0.97 | 0.97 |
| Liquid phase parameter L | 9.6 | 9.7 | 9.7 | 9.8 | 9.7 | 9.7 | 9.7 | 9.8 | 9.8 |
| Thermal expansion parameter C | 0.79 | 0.79 | 0.79 | 0.78 | 0.78 | 0.78 | 0.78 | 0.77 | 0.77 |
| Glass transition point (° C.) | 734 | 741 | 734 | 741 | 733 | 726 | 726 | 733 | 726 |
| Density (g/cm³) | 2.81 | 2.78 | 2.79 | 2.74 | 2.79 | 2.80 | 2.81 | 2.75 | 2.76 |
| Liquid phase viscosity log η_{L} (dPa · s) | 3.2 | 3.1 | 3.1 | 3.3 | 3.1 | 3.2 | 3.2 | 3.2 | 3.3 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | x | x | x | x | x | x |
| Manufacturability determination | ⊚ | ⊚ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 248 | 249 | 250 | 251 | 252 | 253 | 254 | 255 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.3 | 0.3 | 0.3 | 0.3 | 0.3 | 0.3 | 0.3 | 0.3 |
| SrO | 0.2 | 0.2 | 0.2 | 0.2 | 0.2 | 0.2 | 0.2 | 0.2 |
| BaO | 0.4 | 0.4 | 0.4 | 0.4 | 0.4 | 0.4 | 0.4 | 0.4 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1 | 1 | 1 | 1 | 1.5 | 1.5 | 1.5 | 1.5 |
| TiO₂ | 1 | 1.5 | 1.5 | 1.5 | 0.5 | 0.5 | 0.5 | 0.5 |
| Y₂O₃ | 2 | | | 1.5 | | | | 1 |
| Gd₂O₃ | | | 1.5 | | | 1 | 2 | |
| La₂O₃ | | 1.5 | | | 2 | 1 | | 1 |
| WO₃ | | | | | | | | |
| Ta₂O₅ | | | | | | | | |
| Al₂O₃ + rare earth oxide | 16 | 15.5 | 15.5 | 15.5 | 16 | 16 | 16 | 16 |
| Y₂O₃ + Gd₂O₃ + La₂O₃ + Nd₂O₃ + Ta₂O₅ + Nb₂O₅ | 2 | 1.5 | 1.5 | 1.5 | 2 | 2 | 2 | 2 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 7 | 7 | 7 | 7 | 7 | 8 | 7 | 8 |
| Young's modulus E (GPa) | 98 | 98 | 98 | 98 | 99 | 99 | 99 | 99 |
| Thermal expansion coefficient α(ppm/° C.) | 3.81 | 3.89 | 3.94 | 3.77 | 4.00 | 4.03 | 4.07 | 3.92 |
| Liquid phase temperature T_{L} (° C.) | 1205 | 1227 | 1222 | 1222 | 1254 | 1250 | 1249 | 1234 |
| 13.1 · E+9 − T_{L} | 90 | 63 | 68 | 69 | 47 | 51 | 51 | 67 |
| 1923 − 156 · α − T_{L} | 123 | 89 | 86 | 112 | 46 | 44 | 39 | 77 |
| Young's modulus parameter Y | 0.97 | 0.96 | 0.96 | 0.96 | 0.97 | 0.97 | 0.97 | 0.97 |
| Liquid phase parameter L | 9.9 | 9.9 | 9.9 | 10.0 | 9.6 | 9.6 | 9.6 | 9.7 |
| Thermal expansion parameter C | 0.77 | 0.77 | 0.77 | 0.76 | 0.79 | 0.79 | 0.79 | 0.78 |
| Glass transition point (° C.) | 733 | 731 | 725 | 731 | 741 | 734 | 734 | 741 |
| Density (g/cm³) | 2.71 | 2.74 | 2.75 | 2.68 | 2.80 | 2.81 | 2.82 | 2.76 |
| Liquid phase viscosity log η_{L} (dPa · s) | 3.4 | 3.2 | 3.2 | 3.2 | 3.0 | 3.0 | 3.0 | 3.1 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | ◯ | x | x | ◯ | x | x | x | x |
| Manufacturability determination | ⊚ | ⊚ | ⊚ | ⊚ | ⊚ | ⊚ | ⊚ | ⊚ |

TABLE 16

| | Example | Example | Example | Example | Example | Example | Example | Example | Example |
|---|---|---|---|---|---|---|---|---|---|
| (mol %) | 256 | 257 | 258 | 259 | 260 | 261 | 262 | 263 | 264 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.3 | 0.3 | 0.3 | 0.3 | 0.3 | 0.3 | 0.3 | 0.3 | 0.3 |
| SrO | 0.2 | 0.2 | 0.2 | 0.2 | 0.2 | 0.2 | 0.2 | 0.2 | 0.3 |
| BaO | 0.4 | 0.4 | 0.4 | 0.4 | 0.4 | 0.4 | 0.4 | 0.4 | 0.3 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1.5 | 1.5 | 1.5 | 1.5 | 1.5 | 1.5 | 1.5 | 1.5 | 0.5 |
| TiO₂ | 0.5 | 0.5 | 1 | 1 | 1 | 1.5 | 1.5 | 1.5 | 0.5 |
| Y₂O₃ | 1 | 2 | | | 1.5 | | | 1 | 1 |
| Gd₂O₃ | 1 | | | 1.5 | | | 1 | | |
| La₂O₃ | | | 1.5 | | | 1 | | | 2 |
| WO₃ | | | | | | | | | |
| Ta₂O₅ | | | | | | | | | |
| Al₂O₃ + rare earth oxide | 16 | 16 | 15.5 | 15.5 | 15.5 | 15 | 15 | 15 | 17 |
| Y₂O₃ + Gd₂O₃ + La₂O₃ + Nd₂O₃ + Ta₂O₅ + Nb₂O₅ | 2 | 2 | 1.5 | 1.5 | 1.5 | 1 | 1 | 1 | 3 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 8 | 7 | 7 | 7 | 7 | 7 | 7 | 7 | 8 |
| Young's modulus E (GPa) | 99 | 99 | 98 | 98 | 98 | 98 | 98 | 98 | 98 |
| Thermal expansion coefficient α(ppm/° C.) | 3.95 | 3.84 | 3.92 | 3.97 | 3.80 | 3.83 | 3.87 | 3.76 | 4.03 |
| Liquid phase temperature T_{L} (° C.) | 1230 | 1219 | 1233 | 1228 | 1221 | 1226 | 1222 | 1222 | 1263 |
| 13.1 · E+9 − T_{L} | 71 | 83 | 64 | 69 | 76 | 66 | 71 | 71 | 34 |
| 1923 − 156 · α − T_{L} | 76 | 105 | 80 | 76 | 109 | 99 | 98 | 115 | 31 |
| Young's modulus parameter Y | 0.97 | 0.98 | 0.97 | 0.97 | 0.97 | 0.96 | 0.96 | 0.96 | 0.98 |
| Liquid phase parameter L | 9.7 | 9.8 | 9.8 | 9.8 | 10.0 | 10.0 | 10.0 | 10.1 | 9.5 |
| Thermal expansion parameter C | 0.78 | 0.77 | 0.77 | 0.77 | 0.76 | 0.76 | 0.76 | 0.75 | 0.80 |
| Glass transition point (° C.) | 734 | 741 | 734 | 727 | 734 | 731 | 726 | 731 | 739 |
| Density (g/cm³) | 2.77 | 2.72 | 2.75 | 2.76 | 2.69 | 2.70 | 2.71 | 2.66 | 2.84 |
| Liquid phase viscosity log η_{L} (dPa · s) | 3.2 | 3.3 | 3.1 | 3.2 | 3.2 | 3.2 | 3.2 | 3.2 | 2.9 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | x | ◯ | ◯ | x | ◯ | x |
| Manufacturability determination | ⊚ | ⊚ | ⊚ | ⊚ | ⊚ | ⊚ | ⊚ | ⊚ | ◯ |

| | Example | Example | Example | Example | Example | Example | Example | Example |
|---|---|---|---|---|---|---|---|---|
| (mol %) | 265 | 266 | 267 | 268 | 269 | 270 | 271 | 272 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.3 | 0.3 | 0.3 | 0.3 | 0.3 | 0.3 | 0.3 | 0.3 |
| SrO | 0.3 | 0.3 | 0.3 | 0.3 | 0.3 | 0.3 | 0.3 | 0.3 |
| BaO | 0.3 | 0.3 | 0.3 | 0.3 | 0.3 | 0.3 | 0.3 | 0.3 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 0.5 | 0.5 | 0.5 | 0.5 | 0.5 | 0.5 | 0.5 | 0.5 |
| TiO₂ | 0.5 | 0.5 | 0.5 | 0.5 | 0.5 | 0.5 | 1 | 1 |
| Y₂O₃ | 1 | 1 | 1.5 | 1.5 | 2 | 2 | | |
| Gd₂O₃ | 1 | 2 | | 1.5 | | 1 | 1 | 1.5 |
| La₂O₃ | 1 | | 1.5 | | 1 | | 1.5 | 1 |
| WO₃ | | | | | | | | |
| Ta₂O₅ | | | | | | | | |
| Al₂O₃ + rare earth oxide | 17 | 17 | 17 | 17 | 17 | 17 | 16.5 | 16.5 |
| Y₂O₃ + Gd₂O₃ + La₂O₃ + Nd₂O₃ + Ta₂O₅ + Nb₂O₅ | 3 | 3 | 3 | 3 | 3 | 3 | 2.5 | 2.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 9 | 8 | 8 | 8 | 8 | 8 | 8 | 8 |
| Young's modulus E (GPa) | 98 | 98 | 98 | 98 | 98 | 98 | 98 | 98 |
| Thermal expansion coefficient α(ppm/° C.) | 4.06 | 4.10 | 3.99 | 4.04 | 3.95 | 3.99 | 4.06 | 4.08 |
| Liquid phase temperature T_{L} (° C.) | 1261 | 1261 | 1259 | 1258 | 1242 | 1242 | 1279 | 1279 |
| 13.1 · E+9 − T_{L} | 36 | 36 | 39 | 39 | 55 | 55 | 13 | 13 |
| 1923 − 156 · α − T_{L} | 28 | 23 | 42 | 35 | 64 | 59 | 11 | 8 |
| Young's modulus parameter Y | 0.97 | 0.97 | 0.98 | 0.98 | 0.98 | 0.98 | 0.97 | 0.97 |
| Liquid phase parameter L | 9.5 | 9.5 | 9.5 | 9.5 | 9.6 | 9.6 | 9.6 | 9.6 |
| Thermal expansion parameter C | 0.80 | 0.80 | 0.80 | 0.80 | 0.79 | 0.79 | 0.79 | 0.79 |
| Glass transition point (° C.) | 733 | 733 | 739 | 733 | 739 | 733 | 727 | 727 |
| Density (g/cm³) | 2.84 | 2.85 | 2.82 | 2.83 | 2.80 | 2.81 | 2.84 | 2.84 |
| Liquid phase viscosity log η_{L} (dPa · s) | 2.9 | 2.9 | 2.9 | 2.9 | 3.1 | 3.1 | 2.8 | 2.8 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | x | x | x | x | x | x |
| Manufacturability determination | ◯ | ◯ | ⊚ | ⊚ | ⊚ | ⊚ | ◯ | ◯ |

TABLE 17

| | Example | Example | Example | Example | Example | Example | Example | Example | Example |
|---|---|---|---|---|---|---|---|---|---|
| (mol %) | 273 | 274 | 275 | 276 | 277 | 278 | 279 | 280 | 281 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.3 | 0.3 | 0.3 | 0.3 | 0.3 | 0.3 | 0.3 | 0.3 | 0.3 |
| SrO | 0.3 | 0.3 | 0.3 | 0.3 | 0.3 | 0.3 | 0.3 | 0.3 | 0.3 |
| BaO | 0.3 | 0.3 | 0.3 | 0.3 | 0.3 | 0.3 | 0.3 | 0.3 | 0.3 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 0.5 | 0.5 | 0.5 | 0.5 | 0.5 | 0.5 | 0.5 | 0.5 | 0.5 |
| TiO₂ | 1 | 1 | 1 | 1 | 1 | 1 | 1.5 | 1.5 | 1.5 |
| Y₂O₃ | | 1 | 1 | 1.5 | 1.5 | 2.5 | | | |
| Gd₂O₃ | 2.5 | | 1.5 | | 1 | | | 1 | 2 |
| La₂O₃ | | 1.5 | | 1 | | | 2 | 1 | |
| WO₃ | | | | | | | | | |
| Ta₂O₅ | | | | | | | | | |
| Al₂O₃ + rare earth oxide | 16.5 | 16.5 | 16.5 | 16.5 | 16.5 | 16.5 | 16 | 16 | 16 |
| Y₂O₃ + Gd₂O₃ + La₂O₃ + Nd₂O₃ + Ta₂O₅ + Nb₂O₅ | 2.5 | 2.5 | 2.5 | 2.5 | 2.5 | 2.5 | 2 | 2 | 2 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 7 | 8 | 8 | 8 | 8 | 7 | 7 | 8 | 7 |
| Young's modulus E (GPa) | 98 | 98 | 98 | 98 | 98 | 98 | 98 | 98 | 98 |
| Thermal expansion coefficient α(ppm/° C.) | 4.11 | 3.95 | 4.00 | 3.91 | 3.94 | 3.83 | 3.94 | 3.98 | 4.02 |
| Liquid phase temperature T_{L} (° C.) | 1279 | 1253 | 1250 | 1247 | 1245 | 1227 | 1276 | 1273 | 1273 |
| 13.1 · E+9 − T_{L} | 13 | 40 | 43 | 47 | 48 | 67 | 12 | 15 | 14 |
| 1923 − 156 · α − T_{L} | 2 | 54 | 49 | 67 | 63 | 99 | 31 | 29 | 23 |
| Young's modulus parameter Y | 0.97 | 0.97 | 0.97 | 0.97 | 0.97 | 0.97 | 0.96 | 0.96 | 0.96 |
| Liquid phase parameter L | 9.6 | 9.7 | 9.7 | 9.7 | 9.7 | 9.8 | 9.7 | 9.7 | 9.7 |
| Thermal expansion parameter C | 0.79 | 0.79 | 0.79 | 0.78 | 0.78 | 0.77 | 0.78 | 0.78 | 0.78 |
| Glass transition point (° C.) | 727 | 733 | 727 | 733 | 727 | 733 | 731 | 726 | 726 |
| Density (g/cm³) | 2.85 | 2.79 | 2.80 | 2.77 | 2.78 | 2.73 | 2.78 | 2.79 | 2.80 |
| Liquid phase viscosity log η_{L} (dPa · s) | 2.8 | 3.0 | 3.0 | 3.0 | 3.0 | 3.2 | 2.8 | 2.8 | 2.8 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | x | x | ◯ | x | x | x |
| Manufacturability determination | ⊚ | ⊚ | ⊚ | ⊚ | ⊚ | ⊚ | ◯ | ◯ | ◯ |

| | Example | Example | Example | Example | Example | Example | Example | Example |
|---|---|---|---|---|---|---|---|---|
| (mol %) | 282 | 283 | 284 | 285 | 286 | 287 | 288 | 289 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.3 | 0.3 | 0.3 | 0.3 | 0.3 | 0.3 | 0.3 | 0.3 |
| SrO | 0.3 | 0.3 | 0.3 | 0.3 | 0.3 | 0.3 | 0.3 | 0.3 |
| BaO | 0.3 | 0.3 | 0.3 | 0.3 | 0.3 | 0.3 | 0.3 | 0.3 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 0.5 | 0.5 | 0.5 | 1 | 1 | 1 | 1 | 1 |
| TiO₂ | 1.5 | 1.5 | 1.5 | 0.5 | 0.5 | 0.5 | 0.5 | 0.5 |
| Y₂O₃ | 1 | 1 | 2 | | | | | 1 |
| Gd₂O₃ | | 1 | | | 1 | 1.5 | 2.5 | |
| La₂O₃ | 1 | | | 2.5 | 1.5 | 1 | | 1.5 |
| WO₃ | | | | | | | | |
| Ta₂O₅ | | | | | | | | |
| Al₂O₃ + rare earth oxide | 16 | 16 | 16 | 16.5 | 16.5 | 16.5 | 16.5 | 16.5 |
| Y₂O₃ + Gd₂O₃ + La₂O₃ + Nd₂O₃ + Ta₂O₅ + Nb₂O₅ | 2 | 2 | 2 | 2.5 | 2.5 | 2.5 | 2.5 | 2.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 8 | 8 | 7 | 7 | 8 | 8 | 7 | 8 |
| Young's modulus E (GPa) | 98 | 98 | 98 | 98 | 98 | 98 | 98 | 99 |
| Thermal expansion coefficient α(ppm/° C.) | 3.87 | 3.90 | 3.79 | 4.05 | 4.09 | 4.10 | 4.14 | 3.97 |
| Liquid phase temperature T_{L} (° C.) | 1253 | 1250 | 1227 | 1251 | 1248 | 1247 | 1246 | 1231 |
| 13.1 · E+9 − T_{L} | 36 | 39 | 62 | 48 | 51 | 52 | 52 | 69 |
| 1923 − 156 · α − T_{L} | 67 | 65 | 105 | 40 | 38 | 36 | 31 | 73 |
| Young's modulus parameter Y | 0.96 | 0.96 | 0.96 | 0.97 | 0.97 | 0.97 | 0.97 | 0.98 |
| Liquid phase parameter L | 9.8 | 9.8 | 9.9 | 9.5 | 9.5 | 9.5 | 9.5 | 9.6 |
| Thermal expansion parameter C | 0.77 | 0.77 | 0.76 | 0.80 | 0.80 | 0.80 | 0.80 | 0.79 |
| Glass transition point (° C.) | 731 | 726 | 731 | 739 | 733 | 733 | 733 | 739 |
| Density (g/cm³) | 2.74 | 2.75 | 2.70 | 2.84 | 2.84 | 2.85 | 2.86 | 2.80 |
| Liquid phase viscosity log η_{L} (dPa · s) | 3.0 | 3.0 | 3.2 | 3.0 | 3.0 | 3.0 | 3.0 | 3.2 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | ◯ | x | x | x | x | x |
| Manufacturability determination | ⊚ | ⊚ | ⊚ | ⊚ | ⊚ | ⊚ | ⊚ | ⊚ |

TABLE 18

| | Example | Example | Example | Example | Example | Example | Example | Example | Example |
|---|---|---|---|---|---|---|---|---|---|
| (mol %) | 290 | 291 | 292 | 293 | 294 | 295 | 296 | 297 | 298 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.3 | 0.3 | 0.3 | 0.3 | 0.3 | 0.3 | 0.3 | 0.3 | 0.3 |
| SrO | 0.3 | 0.3 | 0.3 | 0.3 | 0.3 | 0.3 | 0.3 | 0.3 | 0.3 |
| BaO | 0.3 | 0.3 | 0.3 | 0.3 | 0.3 | 0.3 | 0.3 | 0.3 | 0.3 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1 | 1 | 1 | 1 | 1 | 1 | 1 | 1 | 1 |
| TiO₂ | 0.5 | 0.5 | 0.5 | 0.5 | 1 | 1 | 1 | 1 | 1 |
| Y₂O₃ | 1 | 1.5 | 1.5 | 2.5 | | | | 1 | 1 |
| Gd₂O₃ | 1.5 | | 1 | | | 1 | 2 | | 1 |
| La₂O₃ | | 1 | | | 2 | 1 | | 1 | |
| WO₃ | | | | | | | | | |
| Ta₂O₅ | | | | | | | | | |
| Al₂O₃ + rare earth oxide | 16.5 | 16.5 | 16.5 | 16.5 | 16 | 16 | 16 | 16 | 16 |
| Y₂O₃ + Gd₂O₃ + La₂O₃ + Nd₂O₃ + Ta₂O₅ + Nb₂O₅ | 2.5 | 2.5 | 2.5 | 2.5 | 2 | 2 | 2 | 2 | 2 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 8 | 8 | 8 | 7 | 7 | 8 | 7 | 8 | 8 |
| Young's modulus E (GPa) | 98 | 99 | 99 | 99 | 98 | 98 | 98 | 98 | 98 |
| Thermal expansion coefficient α(ppm/° C.) | 4.03 | 3.93 | 3.97 | 3.86 | 3.97 | 4.01 | 4.04 | 3.89 | 3.93 |
| Liquid phase temperature T_{L} (° C.) | 1226 | 1231 | 1228 | 1214 | 1230 | 1226 | 1225 | 1219 | 1215 |
| 13.1 · E+9 − T_{L} | 73 | 69 | 71 | 87 | 65 | 69 | 69 | 76 | 80 |
| 1923 − 156 · α − T_{L} | 69 | 79 | 75 | 108 | 74 | 73 | 68 | 96 | 96 |
| Young's modulus parameter Y | 0.98 | 0.98 | 0.98 | 0.98 | 0.97 | 0.97 | 0.97 | 0.97 | 0.97 |
| Liquid phase parameter L | 9.6 | 9.7 | 9.7 | 9.8 | 9.7 | 9.7 | 9.7 | 9.8 | 9.8 |
| Thermal expansion parameter C | 0.79 | 0.79 | 0.79 | 0.78 | 0.78 | 0.78 | 0.78 | 0.78 | 0.78 |
| Glass transition point (° C.) | 733 | 739 | 733 | 739 | 733 | 726 | 726 | 733 | 726 |
| Density (g/cm³) | 2.81 | 2.78 | 2.79 | 2.74 | 2.79 | 2.80 | 2.80 | 2.75 | 2.76 |
| Liquid phase viscosity log η_{L} (dPa · s) | 3.2 | 3.2 | 3.2 | 3.3 | 3.2 | 3.2 | 3.2 | 3.2 | 3.3 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | x | x | x | x | x | x |
| Manufacturability determination | ⊚ | ⊚ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 299 | 300 | 301 | 302 | 303 | 304 | 305 | 306 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.3 | 0.3 | 0.3 | 0.3 | 0.3 | 0.3 | 0.3 | 0.3 |
| SrO | 0.3 | 0.3 | 0.3 | 0.3 | 0.3 | 0.3 | 0.3 | 0.3 |
| BaO | 0.3 | 0.3 | 0.3 | 0.3 | 0.3 | 0.3 | 0.3 | 0.3 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1 | 1 | 1 | 1.5 | 1.5 | 1.5 | 1.5 | 1.5 |
| TiO₂ | 1.5 | 1.5 | 1.5 | 0.5 | 0.5 | 0.5 | 0.5 | 0.5 |
| Y₂O₃ | | | 1.5 | | | | 1 | 1 |
| Gd₂O₃ | | 1.5 | | | 1 | 2 | | 1 |
| La₂O₃ | 1.5 | | | 2 | 1 | | 1 | |
| WO₃ | | | | | | | | |
| Ta₂O₅ | | | | | | | | |
| Al₂O₃ + rare earth oxide | 15.5 | 15.5 | 15.5 | 16 | 16 | 16 | 16 | 16 |
| Y₂O₃ + Gd₂O₃ + La₂O₃ + Nd₂O₃ + Ta₂O₅ + Nb₂O₅ | 1.5 | 1.5 | 1.5 | 2 | 2 | 2 | 2 | 2 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 7 | 7 | 7 | 7 | 8 | 7 | 8 | 8 |
| Young's modulus E (GPa) | 98 | 98 | 98 | 99 | 99 | 99 | 99 | 99 |
| Thermal expansion coefficient α(ppm/° C.) | 3.89 | 3.94 | 3.77 | 4.00 | 4.03 | 4.07 | 3.92 | 3.95 |
| Liquid phase temperature T_{L} (° C.) | 1223 | 1218 | 1217 | 1252 | 1248 | 1247 | 1232 | 1227 |
| 13.1 · E+9 − T_{L} | 68 | 73 | 74 | 50 | 53 | 54 | 70 | 75 |
| 1923 − 156 · α − T_{L} | 94 | 90 | 117 | 48 | 46 | 42 | 80 | 79 |
| Young's modulus parameter Y | 0.96 | 0.96 | 0.96 | 0.97 | 0.97 | 0.97 | 0.98 | 0.98 |
| Liquid phase parameter L | 9.8 | 9.8 | 10.0 | 9.6 | 9.6 | 9.6 | 9.7 | 9.7 |
| Thermal expansion parameter C | 0.77 | 0.77 | 0.76 | 0.79 | 0.79 | 0.79 | 0.78 | 0.78 |
| Glass transition point (° C.) | 730 | 725 | 730 | 740 | 733 | 733 | 740 | 733 |
| Density (g/cm³) | 2.74 | 2.75 | 2.68 | 2.80 | 2.81 | 2.81 | 2.76 | 2.77 |
| Liquid phase viscosity log η_{L} (dPa · s) | 3.2 | 3.3 | 3.3 | 3.0 | 3.0 | 3.0 | 3.1 | 3.2 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | ◯ | x | x | x | x | x |
| Manufacturability determination | ⊚ | ⊚ | ⊚ | ⊚ | ⊚ | ⊚ | ⊚ | ⊚ |

TABLE 19

| | Example | Example | Example | Example | Example | Example | Example | Example | Example |
|---|---|---|---|---|---|---|---|---|---|
| (mol %) | 307 | 308 | 309 | 310 | 311 | 312 | 313 | 314 | 315 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.3 | 0.3 | 0.3 | 0.3 | 0.3 | 0.3 | 0.3 | 0.3 | 0.3 |
| SrO | 0.3 | 0.3 | 0.3 | 0.3 | 0.3 | 0.3 | 0.3 | 0.4 | 0.4 |
| BaO | 0.3 | 0.3 | 0.3 | 0.3 | 0.3 | 0.3 | 0.3 | 0.2 | 0.2 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1.5 | 1.5 | 1.5 | 1.5 | 1.5 | 1.5 | 1.5 | 0.5 | 0.5 |
| TiO₂ | 0.5 | 1 | 1 | 1 | 1.5 | 1.5 | 1.5 | 0.5 | 0.5 |
| Y₂O₃ | 2 | | | 1.5 | | | 1 | 1 | 1 |
| Gd₂O₃ | | | 1.5 | | | 1 | | | 1 |
| La₂O₃ | | 1.5 | | | 1 | | | 2 | 1 |
| WO₃ | | | | | | | | | |
| Ta₂O₅ | | | | | | | | | |
| Al₂O₃ + rare earth oxide | 16 | 15.5 | 15.5 | 15.5 | 15 | 15 | 15 | 17 | 17 |
| Y₂O₃ + Gd₂O₃ + La₂O₃ + Nd₂O₃ + Ta₂O₅ + Nb₂O₅ | 2 | 1.5 | 1.5 | 1.5 | 1 | 1 | 1 | 3 | 3 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 7 | 7 | 7 | 7 | 7 | 7 | 7 | 8 | 9 |
| Young's modulus E (GPa) | 99 | 98 | 98 | 98 | 98 | 98 | 98 | 98 | 98 |
| Thermal expansion coefficient α(ppm/° C.) | 3.84 | 3.91 | 3.97 | 3.80 | 3.83 | 3.87 | 3.76 | 4.03 | 4.06 |
| Liquid phase temperature T_{L} (° C.) | 1216 | 1231 | 1226 | 1219 | 1223 | 1219 | 1219 | 1266 | 1263 |
| 13.1 · E+9 − T_{L} | 87 | 66 | 71 | 79 | 70 | 74 | 75 | 32 | 34 |
| 1923 − 156 · α − T_{L} | 108 | 81 | 78 | 111 | 102 | 100 | 118 | 29 | 26 |
| Young's modulus parameter Y | 0.98 | 0.97 | 0.97 | 0.97 | 0.96 | 0.96 | 0.96 | 0.98 | 0.98 |
| Liquid phase parameter L | 9.8 | 9.8 | 9.8 | 9.9 | 9.9 | 9.9 | 10.0 | 9.5 | 9.5 |
| Thermal expansion parameter C | 0.77 | 0.77 | 0.77 | 0.76 | 0.76 | 0.76 | 0.75 | 0.80 | 0.80 |
| Glass transition point (° C.) | 740 | 734 | 727 | 734 | 731 | 725 | 731 | 741 | 736 |
| Density (g/cm³) | 2.72 | 2.75 | 2.76 | 2.69 | 2.70 | 2.71 | 2.66 | 2.83 | 2.84 |
| Liquid phase viscosity log η_{L} (dPa · s) | 3.3 | 3.2 | 3.2 | 3.3 | 3.2 | 3.3 | 3.3 | 2.9 | 2.9 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | ◯ | ◯ | x | ◯ | x | x |
| Manufacturability determination | ⊚ | ⊚ | ⊚ | ⊚ | ⊚ | ⊚ | ⊚ | ◯ | ◯ |

| | Example | Example | Example | Example | Example | Example | Example | Example |
|---|---|---|---|---|---|---|---|---|
| (mol %) | 316 | 317 | 318 | 319 | 320 | 321 | 322 | 323 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.3 | 0.3 | 0.3 | 0.3 | 0.3 | 0.3 | 0.3 | 0.3 |
| SrO | 0.4 | 0.4 | 0.4 | 0.4 | 0.4 | 0.4 | 0.4 | 0.4 |
| BaO | 0.2 | 0.2 | 0.2 | 0.2 | 0.2 | 0.2 | 0.2 | 0.2 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 0.5 | 0.5 | 0.5 | 0.5 | 0.5 | 0.5 | 0.5 | 0.5 |
| TiO₂ | 0.5 | 0.5 | 0.5 | 0.5 | 0.5 | 1 | 1 | 1 |
| Y₂O₃ | 1 | 1.5 | 1.5 | 2 | 2 | 1 | 1 | 1.5 |
| Gd₂O₃ | 2 | | 1.5 | | 1 | | 1.5 | |
| La₂O₃ | | 1.5 | | 1 | | 1.5 | | 1 |
| WO₃ | | | | | | | | |
| Ta₂O₅ | | | | | | | | |
| Al₂O₃ + rare earth oxide | 17 | 17 | 17 | 17 | 17 | 16.5 | 16.5 | 16.5 |
| Y₂O₃ + Gd₂O₃ + La₂O₃ + Nd₂O₃ + Ta₂O₅ + Nb₂O₅ | 3 | 3 | 3 | 3 | 3 | 2.5 | 2.5 | 2.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 8 | 8 | 8 | 8 | 8 | 8 | 8 | 8 |
| Young's modulus E (GPa) | 98 | 98 | 98 | 98 | 98 | 98 | 98 | 98 |
| Thermal expansion coefficient α(ppm/° C.) | 4.10 | 3.99 | 4.04 | 3.95 | 3.99 | 3.95 | 4.00 | 3.91 |
| Liquid phase temperature T_{L} (° C.) | 1263 | 1262 | 1260 | 1247 | 1247 | 1255 | 1253 | 1249 |
| 13.1 · E+9 − T_{L} | 34 | 36 | 37 | 51 | 50 | 38 | 41 | 45 |
| 1923 − 156 · α − T_{L} | 20 | 39 | 32 | 59 | 54 | 52 | 46 | 64 |
| Young's modulus parameter Y | 0.98 | 0.98 | 0.98 | 0.98 | 0.98 | 0.97 | 0.97 | 0.97 |
| Liquid phase parameter L | 9.5 | 9.5 | 9.5 | 9.6 | 9.6 | 9.6 | 9.6 | 9.7 |
| Thermal expansion parameter C | 0.80 | 0.80 | 0.80 | 0.79 | 0.79 | 0.79 | 0.79 | 0.78 |
| Glass transition point (° C.) | 736 | 741 | 736 | 741 | 736 | 736 | 730 | 736 |
| Density (g/cm³) | 2.85 | 2.81 | 2.83 | 2.80 | 2.80 | 2.79 | 2.80 | 2.77 |
| Liquid phase viscosity log η_{L} (dPa · s) | 2.9 | 2.9 | 2.9 | 3.0 | 3.0 | 3.0 | 3.0 | 3.0 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | x | x | x | x | x | x |
| Manufacturability determination | ◯ | ◯ | ◯ | ⊚ | ⊚ | ⊚ | ⊚ | ⊚ |

TABLE 20

| | Example | Example | Example | Example | Example | Example | Example | Example | Example |
|---|---|---|---|---|---|---|---|---|---|
| (mol %) | 324 | 325 | 326 | 327 | 328 | 329 | 330 | 331 | 332 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.3 | 0.3 | 0.3 | 0.3 | 0.3 | 0.3 | 0.3 | 0.3 | 0.3 |
| SrO | 0.4 | 0.4 | 0.4 | 0.4 | 0.4 | 0.4 | 0.4 | 0.4 | 0.4 |
| BaO | 0.2 | 0.2 | 0.2 | 0.2 | 0.2 | 0.2 | 0.2 | 0.2 | 0.2 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 0.5 | 0.5 | 0.5 | 0.5 | 0.5 | 0.5 | 0.5 | 0.5 | 1 |
| TiO₂ | 1 | 1 | 1.5 | 1.5 | 1.5 | 1.5 | 1.5 | 1.5 | 0.5 |
| Y₂O₃ | 1.5 | 2.5 | | | | 1 | 1 | 2 | |
| Gd₂O₃ | 1 | | | 1 | 2 | | 1 | | |
| La₂O₃ | | | 2 | 1 | | 1 | | | 2.5 |
| WO₃ | | | | | | | | | |
| Ta₂O₅ | | | | | | | | | |
| Al₂O₃ + rare earth oxide | 16.5 | 16.5 | 16 | 16 | 16 | 16 | 16 | 16 | 16.5 |
| Y₂O₃ + Gd₂O₃ + La₂O₃ + Nd₂O₃ + Ta₂O₅ + Nb₂O₅ | 2.5 | 2.5 | 2 | 2 | 2 | 2 | 2 | 2 | 2.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 8 | 7 | 7 | 8 | 7 | 8 | 8 | 7 | 7 |
| Young's modulus E (GPa) | 98 | 98 | 98 | 98 | 98 | 98 | 98 | 98 | 99 |
| Thermal expansion coefficient α(ppm/° C.) | 3.94 | 3.83 | 3.94 | 3.98 | 4.02 | 3.87 | 3.90 | 3.79 | 4.05 |
| Liquid phase temperature T_{L} (° C.) | 1248 | 1231 | 1279 | 1276 | 1276 | 1255 | 1252 | 1232 | 1253 |
| 13.1 · E+9 − T_{L} | 46 | 63 | 10 | 12 | 12 | 34 | 37 | 58 | 47 |
| 1923 − 156 · α − T_{L} | 60 | 94 | 29 | 26 | 20 | 65 | 62 | 100 | 38 |
| Young's modulus parameter Y | 0.97 | 0.97 | 0.96 | 0.96 | 0.96 | 0.96 | 0.96 | 0.96 | 0.97 |
| Liquid phase parameter L | 9.7 | 9.8 | 9.7 | 9.7 | 9.7 | 9.8 | 9.8 | 9.9 | 9.5 |
| Thermal expansion parameter C | 0.78 | 0.78 | 0.78 | 0.78 | 0.78 | 0.77 | 0.77 | 0.76 | 0.80 |
| Glass transition point (° C.) | 730 | 736 | 733 | 729 | 729 | 733 | 729 | 733 | 741 |
| Density (g/cm³) | 2.78 | 2.73 | 2.78 | 2.79 | 2.79 | 2.74 | 2.75 | 2.70 | 2.83 |
| Liquid phase viscosity log η_{L} (dPa · s) | 3.0 | 3.2 | 2.8 | 2.8 | 2.8 | 3.0 | 3.0 | 3.1 | 3.0 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | ◯ | x | x | x | x | x | ◯ | x |
| Manufacturability determination | ⊚ | ⊚ | ◯ | ◯ | ◯ | ⊚ | ⊚ | ⊚ | ⊚ |

| | Example | Example | Example | Example | Example | Example | Example | Example |
|---|---|---|---|---|---|---|---|---|
| (mol %) | 333 | 334 | 335 | 336 | 337 | 338 | 339 | 340 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.3 | 0.3 | 0.3 | 0.3 | 0.3 | 0.3 | 0.3 | 0.3 |
| SrO | 0.4 | 0.4 | 0.4 | 0.4 | 0.4 | 0.4 | 0.4 | 0.4 |
| BaO | 0.2 | 0.2 | 0.2 | 0.2 | 0.2 | 0.2 | 0.2 | 0.2 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1 | 1 | 1 | 1 | 1 | 1 | 1 | 1 |
| TiO₂ | 0.5 | 0.5 | 0.5 | 0.5 | 0.5 | 0.5 | 0.5 | 0.5 |
| Y₂O₃ | | | | 1 | 1 | 1.5 | 1.5 | 2.5 |
| Gd₂O₃ | 1 | 1.5 | 2.5 | | 1.5 | | 1 | |
| La₂O₃ | 1.5 | 1 | | 1.5 | | 1 | | |
| WO₃ | | | | | | | | |
| Ta₂O₅ | | | | | | | | |
| Al₂O₃ + rare earth oxide | 16.5 | 16.5 | 16.5 | 16.5 | 16.5 | 16.5 | 16.5 | 16.5 |
| Y₂O₃ + Gd₂O₃ + La₂O₃ + Nd₂O₃ + Ta₂O₅ + Nb₂O₅ | 2.5 | 2.5 | 2.5 | 2.5 | 2.5 | 2.5 | 2.5 | 2.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 8 | 8 | 7 | 8 | 8 | 8 | 8 | 7 |
| Young's modulus E (GPa) | 99 | 98 | 98 | 99 | 99 | 99 | 99 | 99 |
| Thermal expansion coefficient α(ppm/° C.) | 4.09 | 4.10 | 4.14 | 3.97 | 4.03 | 3.93 | 3.97 | 3.86 |
| Liquid phase temperature T_{L} (° C.) | 1250 | 1249 | 1248 | 1233 | 1228 | 1233 | 1231 | 1218 |
| 13.1 · E+9 − T_{L} | 49 | 50 | 50 | 67 | 71 | 67 | 69 | 83 |
| 1923 − 156 · α − T_{L} | 36 | 34 | 29 | 70 | 67 | 76 | 73 | 104 |
| Young's modulus parameter Y | 0.97 | 0.97 | 0.97 | 0.98 | 0.98 | 0.98 | 0.98 | 0.98 |
| Liquid phase parameter L | 9.5 | 9.5 | 9.5 | 9.6 | 9.6 | 9.6 | 9.6 | 9.7 |
| Thermal expansion parameter C | 0.80 | 0.80 | 0.80 | 0.79 | 0.79 | 0.79 | 0.79 | 0.78 |
| Glass transition point (° C.) | 736 | 736 | 736 | 741 | 736 | 741 | 736 | 741 |
| Density (g/cm³) | 2.84 | 2.85 | 2.85 | 2.80 | 2.81 | 2.78 | 2.78 | 2.74 |
| Liquid phase viscosity log η_{L} (dPa · s) | 3.0 | 3.0 | 3.0 | 3.1 | 3.2 | 3.1 | 3.2 | 3.3 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | x | x | x | x | x | x |
| Manufacturability determination | ⊚ | ⊚ | ⊚ | ⊚ | ⊚ | ⊚ | ⊚ | ⊚ |

TABLE 21

| | Example | Example | Example | Example | Example | Example | Example | Example | Example |
|---|---|---|---|---|---|---|---|---|---|
| (mol %) | 341 | 342 | 343 | 344 | 345 | 346 | 347 | 348 | 349 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.3 | 0.3 | 0.3 | 0.3 | 0.3 | 0.3 | 0.3 | 0.3 | 0.3 |
| SrO | 0.4 | 0.4 | 0.4 | 0.4 | 0.4 | 0.4 | 0.4 | 0.4 | 0.4 |
| BaO | 0.2 | 0.2 | 0.2 | 0.2 | 0.2 | 0.2 | 0.2 | 0.2 | 0.2 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1 | 1 | 1 | 1 | 1 | 1 | 1 | 1 | 1 |
| TiO₂ | 1 | 1 | 1 | 1 | 1 | 1 | 1.5 | 1.5 | 1.5 |
| Y₂O₃ | | | | 1 | 1 | 2 | | | 1.5 |
| Gd₂O₃ | | 1 | 2 | | 1 | | | 1.5 | |
| La₂O₃ | 2 | 1 | | 1 | | | 1.5 | | |
| WO₃ | | | | | | | | | |
| Ta₂O₅ | | | | | | | | | |
| Al₂O₃ + rare earth oxide | 16 | 16 | 16 | 16 | 16 | 16 | 15.5 | 15.5 | 15.5 |
| Y₂O₃ + Gd₂O₃ + La₂O₃ + Nd₂O₃ + Ta₂O₅ + Nb₂O₅ | 2 | 2 | 2 | 2 | 2 | 2 | 1.5 | 1.5 | 1.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 7 | 8 | 7 | 8 | 8 | 7 | 7 | 7 | 7 |
| Young's modulus E (GPa) | 98 | 98 | 98 | 98 | 98 | 98 | 98 | 98 | 98 |
| Thermal expansion coefficient α(ppm/° C.) | 3.97 | 4.01 | 4.04 | 3.89 | 3.93 | 3.81 | 3.89 | 3.94 | 3.77 |
| Liquid phase temperature T_{L} (° C.) | 1232 | 1228 | 1227 | 1221 | 1217 | 1204 | 1225 | 1220 | 1220 |
| 13.1 · E+9 − T_{L} | 63 | 67 | 68 | 74 | 79 | 93 | 66 | 70 | 72 |
| 1923 − 156 · α − T_{L} | 72 | 70 | 65 | 94 | 94 | 124 | 91 | 88 | 115 |
| Young's modulus parameter Y | 0.97 | 0.97 | 0.97 | 0.97 | 0.97 | 0.97 | 0.96 | 0.96 | 0.96 |
| Liquid phase parameter L | 9.6 | 9.6 | 9.6 | 9.7 | 9.7 | 9.9 | 9.8 | 9.8 | 10.0 |
| Thermal expansion parameter C | 0.78 | 0.78 | 0.78 | 0.78 | 0.78 | 0.77 | 0.77 | 0.77 | 0.76 |
| Glass transition point (° C.) | 736 | 729 | 730 | 736 | 729 | 736 | 733 | 728 | 733 |
| Density (g/cm³) | 2.79 | 2.80 | 2.80 | 2.75 | 2.76 | 2.71 | 2.74 | 2.75 | 2.68 |
| Liquid phase viscosity log η_{L} (dPa · s) | 3.1 | 3.2 | 3.2 | 3.2 | 3.3 | 3.4 | 3.2 | 3.2 | 3.2 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | x | x | ◯ | x | x | ◯ |
| Manufacturability determination | ⊚ | ⊚ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 350 | 351 | 352 | 353 | 354 | 355 | 356 | 357 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.3 | 0.3 | 0.3 | 0.3 | 0.3 | 0.3 | 0.3 | 0.3 |
| SrO | 0.4 | 0.4 | 0.4 | 0.4 | 0.4 | 0.4 | 0.4 | 0.4 |
| BaO | 0.2 | 0.2 | 0.2 | 0.2 | 0.2 | 0.2 | 0.2 | 0.2 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1.5 | 1.5 | 1.5 | 1.5 | 1.5 | 1.5 | 1.5 | 1.5 |
| TiO₂ | 0.5 | 0.5 | 0.5 | 0.5 | 0.5 | 0.5 | 1 | 1 |
| Y₂O₃ | | | | 1 | 1 | 2 | | |
| Gd₂O₃ | | 1 | 2 | | 1 | | | 1.5 |
| La₂O₃ | 2 | 1 | | 1 | | | 1.5 | |
| WO₃ | | | | | | | | |
| Ta₂O₅ | | | | | | | | |
| Al₂O₃ + rare earth oxide | 16 | 16 | 16 | 16 | 16 | 16 | 15.5 | 15.5 |
| Y₂O₃ + Gd₂O₃ + La₂O₃ + Nd₂O₃ + Ta₂O₅ + Nb₂O₅ | 2 | 2 | 2 | 2 | 2 | 2 | 1.5 | 1.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 7 | 8 | 7 | 8 | 8 | 7 | 7 | 7 |
| Young's modulus E (GPa) | 99 | 99 | 99 | 99 | 99 | 99 | 98 | 98 |
| Thermal expansion coefficient α(ppm/° C.) | 4.00 | 4.03 | 4.07 | 3.92 | 3.95 | 3.84 | 3.91 | 3.97 |
| Liquid phase temperature T_{L} (° C.) | 1255 | 1251 | 1250 | 1235 | 1230 | 1221 | 1234 | 1229 |
| 13.1 · E+9 − T_{L} | 47 | 51 | 51 | 68 | 72 | 82 | 63 | 68 |
| 1923 − 156 · α − T_{L} | 45 | 43 | 38 | 77 | 76 | 104 | 78 | 75 |
| Young's modulus parameter Y | 0.97 | 0.97 | 0.97 | 0.98 | 0.98 | 0.98 | 0.97 | 0.97 |
| Liquid phase parameter L | 9.6 | 9.6 | 9.6 | 9.7 | 9.7 | 9.8 | 9.7 | 9.7 |
| Thermal expansion parameter C | 0.79 | 0.79 | 0.79 | 0.78 | 0.78 | 0.77 | 0.77 | 0.77 |
| Glass transition point (° C.) | 742 | 736 | 736 | 742 | 736 | 742 | 736 | 730 |
| Density (g/cm³) | 2.80 | 2.80 | 2.81 | 2.76 | 2.76 | 2.72 | 2.75 | 2.76 |
| Liquid phase viscosity log η_{L} (dPa · s) | 3.0 | 3.0 | 3.0 | 3.1 | 3.2 | 3.2 | 3.1 | 3.2 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | x | x | x | x | x | x |
| Manufacturability determination | ⊚ | ⊚ | ⊚ | ⊚ | ⊚ | ⊚ | ⊚ | ⊚ |

TABLE 22

| | Example | Example | Example | Example | Example | Example | Example | Example | Example |
|---|---|---|---|---|---|---|---|---|---|
| (mol %) | 358 | 359 | 360 | 361 | 362 | 363 | 364 | 365 | 366 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.3 | 0.3 | 0.3 | 0.3 | 0.4 | 0.4 | 0.4 | 0.4 | 0.4 |
| SrO | 0.4 | 0.4 | 0.4 | 0.4 | 0.2 | 0.2 | 0.2 | 0.2 | 0.2 |
| BaO | 0.2 | 0.2 | 0.2 | 0.2 | 0.3 | 0.3 | 0.3 | 0.3 | 0.3 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1.5 | 1.5 | 1.5 | 1.5 | 0.5 | 0.5 | 0.5 | 0.5 | 0.5 |
| TiO₂ | 1 | 1.5 | 1.5 | 1.5 | 0.5 | 0.5 | 0.5 | 0.5 | 0.5 |
| Y₂O₃ | 1.5 | | | 1 | 1 | 1 | 1 | 1.5 | 1.5 |
| Gd₂O₃ | | | 1 | | | 1 | 2 | | 1.5 |
| La₂O₃ | | 1 | | | 2 | 1 | | 1.5 | |
| WO₃ | | | | | | | | | |
| Ta₂O₅ | | | | | | | | | |
| Al₂O₃ + rare earth oxide | 15.5 | 15 | 15 | 15 | 17 | 17 | 17 | 17 | 17 |
| Y₂O₃ + Gd₂O₃ + La₂O₃ + Nd₂O₃ + Ta₂O₅ + Nb₂O₅ | 1.5 | 1 | 1 | 1 | 3 | 3 | 3 | 3 | 3 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 7 | 7 | 7 | 7 | 8 | 9 | 8 | 8 | 8 |
| Young's modulus E (GPa) | 98 | 98 | 98 | 98 | 98 | 98 | 98 | 98 | 98 |
| Thermal expansion coefficient α(ppm/° C.) | 3.80 | 3.83 | 3.87 | 3.76 | 4.02 | 4.06 | 4.09 | 3.98 | 4.04 |
| Liquid phase temperature T_{L} (° C.) | 1222 | 1227 | 1222 | 1222 | 1268 | 1266 | 1266 | 1264 | 1263 |
| 13.1 · E+9 − T_{L} | 76 | 67 | 71 | 72 | 29 | 32 | 31 | 34 | 34 |
| 1923 − 156 · α − T_{L} | 108 | 98 | 97 | 115 | 27 | 24 | 19 | 37 | 30 |
| Young's modulus parameter Y | 0.97 | 0.96 | 0.96 | 0.96 | 0.98 | 0.97 | 0.97 | 0.98 | 0.98 |
| Liquid phase parameter L | 9.9 | 9.9 | 9.9 | 10.0 | 9.5 | 9.5 | 9.5 | 9.6 | 9.6 |
| Thermal expansion parameter C | 0.76 | 0.76 | 0.76 | 0.75 | 0.80 | 0.80 | 0.80 | 0.80 | 0.80 |
| Glass transition point (° C.) | 736 | 733 | 729 | 733 | 741 | 734 | 734 | 741 | 734 |
| Density (g/cm³) | 2.69 | 2.70 | 2.71 | 2.66 | 2.84 | 2.84 | 2.85 | 2.82 | 2.83 |
| Liquid phase viscosity log η_{L} (dPa · s) | 3.2 | 3.2 | 3.2 | 3.2 | 2.9 | 2.9 | 2.9 | 2.9 | 2.9 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | ◯ | ◯ | x | O | x | x | x | x | x |
| Manufacturability determination | O | | 6 | | ◯ | ◯ | ◯ | ◯ | ◯ |

| | Example | Example | Example | Example | Example | Example | Example | Example |
|---|---|---|---|---|---|---|---|---|
| (mol %) | 367 | 368 | 369 | 370 | 371 | 372 | 373 | 374 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.4 | 0.4 | 0.4 | 0.4 | 0.4 | 0.4 | 0.4 | 0.4 |
| SrO | 0.2 | 0.2 | 0.2 | 0.2 | 0.2 | 0.2 | 0.2 | 0.2 |
| BaO | 0.3 | 0.3 | 0.3 | 0.3 | 0.3 | 0.3 | 0.3 | 0.3 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 0.5 | 0.5 | 0.5 | 0.5 | 0.5 | 0.5 | 0.5 | 0.5 |
| TiO₂ | 0.5 | 0.5 | 1 | 1 | 1 | 1 | 1 | 1.5 |
| Y₂O₃ | 2 | 2 | 1 | 1 | 1.5 | 1.5 | 2.5 | |
| Gd₂O₃ | | 1 | | 1.5 | | 1 | | 1 |
| La₂O₃ | 1 | | 1.5 | | 1 | | | 1 |
| WO₃ | | | | | | | | |
| Ta₂O₅ | | | | | | | | |
| Al₂O₃ + rare earth oxide | 17 | 17 | 16.5 | 16.5 | 16.5 | 16.5 | 16.5 | 16 |
| Y₂O₃ + Gd₂O₃ + La₂O₃ + Nd₂O₃ + Ta₂O₅ + Nb₂O₅ | 3 | 3 | 2.5 | 2.5 | 2.5 | 2.5 | 2.5 | 2 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 8 | 8 | 8 | 8 | 8 | 8 | 7 | 8 |
| Young's modulus E (GPa) | 98 | 98 | 98 | 98 | 98 | 98 | 98 | 98 |
| Thermal expansion coefficient α(ppm/° C.) | 3.95 | 3.98 | 3.94 | 4.00 | 3.90 | 3.94 | 3.83 | 3.98 |
| Liquid phase temperature T_{L} (° C.) | 1249 | 1249 | 1257 | 1254 | 1251 | 1250 | 1232 | 1278 |
| 13.1 · E+9 − T_{L} | 49 | 49 | 36 | 38 | 43 | 44 | 61 | 10 |
| 1923 − 156 · α − T_{L} | 59 | 53 | 51 | 45 | 63 | 59 | 94 | 24 |
| Young's modulus parameter Y | 0.98 | 0.98 | 0.97 | 0.97 | 0.97 | 0.97 | 0.97 | 0.96 |
| Liquid phase parameter L | 9.6 | 9.6 | 9.7 | 9.7 | 9.7 | 9.7 | 9.8 | 9.7 |
| Thermal expansion parameter C | 0.79 | 0.79 | 0.79 | 0.79 | 0.78 | 0.78 | 0.77 | 0.78 |
| Glass transition point (° C.) | 741 | 734 | 734 | 727 | 734 | 727 | 734 | 726 |
| Density (g/cm³) | 2.80 | 2.80 | 2.79 | 2.80 | 2.77 | 2.78 | 2.73 | 2.79 |
| Liquid phase viscosity log η_{L} (dPa · s) | 3.0 | 3.0 | 2.9 | 3.0 | 3.0 | 3.0 | 3.1 | 2.8 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | x | x | x | x | ◯ | x |
| Manufacturability determination | ⊚ | ⊚ | ⊚ | ⊚ | ⊚ | ⊚ | ⊚ | ⊚ |

TABLE 23

| | Example | Example | Example | Example | Example | Example | Example | Example | Example |
|---|---|---|---|---|---|---|---|---|---|
| (mol %) | 375 | 376 | 377 | 378 | 379 | 380 | 381 | 382 | 383 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.4 | 0.4 | 0.4 | 0.4 | 0.4 | 0.4 | 0.4 | 0.4 | 0.4 |
| SrO | 0.2 | 0.2 | 0.2 | 0.2 | 0.2 | 0.2 | 0.2 | 0.2 | 0.2 |
| BaO | 0.3 | 0.3 | 0.3 | 0.3 | 0.3 | 0.3 | 0.3 | 0.3 | 0.3 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 0.5 | 0.5 | 0.5 | 0.5 | 1 | 1 | 1 | 1 | 1 |
| TiO₂ | 1.5 | 1.5 | 1.5 | 1.5 | 0.5 | 0.5 | 0.5 | 0.5 | 0.5 |
| Y₂O₃ | | 1 | 1 | 2 | | | | | 1 |
| Gd₂O₃ | 2 | | 1 | | | 1 | 1.5 | 2.5 | |
| La₂O₃ | | 1 | | | 2.5 | 1.5 | 1 | | 1.5 |
| WO₃ | | | | | | | | | |
| Ta₂O₅ | | | | | | | | | |
| Al₂O₃ + rare earth oxide | 16 | 16 | 16 | 16 | 16.5 | 16.5 | 16.5 | 16.5 | 16.5 |
| Y₂O₃ + Gd₂O₃ + La₂O₃ + Nd₂O₃ + Ta₂O₅ + Nb₂O₅ | 2 | 2 | 2 | 2 | 2.5 | 2.5 | 2.5 | 2.5 | 2.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 7 | 8 | 8 | 7 | 7 | 8 | 8 | 7 | 8 |
| Young's modulus E (GPa) | 98 | 98 | 98 | 98 | 99 | 98 | 98 | 98 | 99 |
| Thermal expansion coefficient α(ppm/° C.) | 4.01 | 3.86 | 3.90 | 3.78 | 4.05 | 4.08 | 4.10 | 4.14 | 3.97 |
| Liquid phase temperature T_{L} (° C.) | 1278 | 1258 | 1255 | 1234 | 1254 | 1251 | 1250 | 1250 | 1235 |
| 13.1 · E+9 − T_{L} | 9 | 31 | 34 | 55 | 45 | 48 | 49 | 49 | 65 |
| 1923 − 156 · α − T_{L} | 19 | 63 | 60 | 99 | 38 | 35 | 33 | 28 | 69 |
| Young's modulus parameter Y | 0.96 | 0.96 | 0.96 | 0.96 | 0.97 | 0.97 | 0.97 | 0.97 | 0.98 |
| Liquid phase parameter L | 9.7 | 9.8 | 9.8 | 9.9 | 9.5 | 9.5 | 9.5 | 9.5 | 9.6 |
| Thermal expansion parameter C | 0.78 | 0.77 | 0.77 | 0.76 | 0.80 | 0.80 | 0.80 | 0.80 | 0.79 |
| Glass transition point (° C.) | 726 | 731 | 726 | 731 | 741 | 734 | 734 | 734 | 741 |
| Density (g/cm³) | 2.79 | 2.74 | 2.75 | 2.70 | 2.84 | 2.84 | 2.85 | 2.86 | 2.80 |
| Liquid phase viscosity log η_{L} (dPa · s) | 2.8 | 2.9 | 3.0 | 3.1 | 3.0 | 3.0 | 3.0 | 3.0 | 3.1 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | ◯ | x | x | x | x | x |
| Manufacturability determination | ⊚ | ⊚ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 384 | 385 | 386 | 387 | 388 | 389 | 390 | 391 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.4 | 0.4 | 0.4 | 0.4 | 0.4 | 0.4 | 0.4 | 0.4 |
| SrO | 0.2 | 0.2 | 0.2 | 0.2 | 0.2 | 0.2 | 0.2 | 0.2 |
| BaO | 0.3 | 0.3 | 0.3 | 0.3 | 0.3 | 0.3 | 0.3 | 0.3 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1 | 1 | 1 | 1 | 1 | 1 | 1 | 1 |
| TiO₂ | 0.5 | 0.5 | 0.5 | 0.5 | 1 | 1 | 1 | 1 |
| Y₂O₃ | 1 | 1.5 | 1.5 | 2.5 | | | | 1 |
| Gd₂O₃ | 1.5 | | 1 | | | 1 | 2 | |
| La₂O₃ | | 1 | | | 2 | 1 | | 1 |
| WO₃ | | | | | | | | |
| Ta₂O₅ | | | | | | | | |
| Al₂O₃ + rare earth oxide | 16.5 | 16.5 | 16.5 | 16.5 | 16 | 16 | 16 | 16 |
| Y₂O₃ + Gd₂O₃ + La₂O₃ + Nd₂O₃ + Ta₂O₅ + Nb₂O₅ | 2.5 | 2.5 | 2.5 | 2.5 | 2 | 2 | 2 | 2 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 8 | 8 | 8 | 7 | 7 | 8 | 7 | 8 |
| Young's modulus E (GPa) | 99 | 99 | 99 | 99 | 98 | 98 | 98 | 98 |
| Thermal expansion coefficient α(ppm/° C.) | 4.02 | 3.93 | 3.96 | 3.85 | 3.97 | 4.00 | 4.04 | 3.89 |
| Liquid phase temperature T_{L} (° C.) | 1230 | 1235 | 1233 | 1218 | 1233 | 1229 | 1228 | 1223 |
| 13.1 · E+9 − T_{L} | 69 | 65 | 67 | 82 | 63 | 66 | 67 | 73 |
| 1923 − 156 · α − T_{L} | 65 | 75 | 72 | 104 | 72 | 70 | 66 | 94 |
| Young's modulus parameter Y | 0.98 | 0.98 | 0.98 | 0.98 | 0.97 | 0.97 | 0.97 | 0.97 |
| Liquid phase parameter L | 9.6 | 9.7 | 9.7 | 9.8 | 9.7 | 9.7 | 9.7 | 9.8 |
| Thermal expansion parameter C | 0.79 | 0.79 | 0.79 | 0.78 | 0.78 | 0.78 | 0.78 | 0.77 |
| Glass transition point (° C.) | 734 | 741 | 734 | 741 | 733 | 726 | 727 | 733 |
| Density (g/cm³) | 2.81 | 2.78 | 2.78 | 2.74 | 2.79 | 2.80 | 2.80 | 2.75 |
| Liquid phase viscosity log η_{L} (dPa · s) | 3.2 | 3.1 | 3.1 | 3.3 | 3.1 | 3.2 | 3.2 | 3.2 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | x | x | x | x | x | x |
| Manufacturability determination | ◯ | ⊚ | ⊚ | ⊚ | ⊚ | ⊚ | ⊚ | ⊚ |

TABLE 24

| | Example | Example | Example | Example | Example | Example | Example | Example | Example |
|---|---|---|---|---|---|---|---|---|---|
| (mol %) | 392 | 393 | 394 | 395 | 396 | 397 | 398 | 399 | 400 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.4 | 0.4 | 0.4 | 0.4 | 0.4 | 0.4 | 0.4 | 0.4 | 0.4 |
| SrO | 0.2 | 0.2 | 0.2 | 0.2 | 0.2 | 0.2 | 0.2 | 0.2 | 0.2 |
| BaO | 0.3 | 0.3 | 0.3 | 0.3 | 0.3 | 0.3 | 0.3 | 0.3 | 0.3 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1 | 1 | 1 | 1 | 1 | 1.5 | 1.5 | 1.5 | 1.5 |
| TiO₂ | 1 | 1 | 1.5 | 1.5 | 1.5 | 0.5 | 0.5 | 0.5 | 0.5 |
| Y₂O₃ | 1 | 2 | | | 1.5 | | | | 1 |
| Gd₂O₃ | 1 | | | 1.5 | | | 1 | 2 | |
| La₂O₃ | | | 1.5 | | | 2 | 1 | | 1 |
| WO₃ | | | | | | | | | |
| Ta₂O₅ | | | | | | | | | |
| Al₂O₃ + rare earth oxide | 16 | 16 | 15.5 | 15.5 | 15.5 | 16 | 16 | 16 | 16 |
| Y₂O₃ + Gd₂O₃ + La₂O₃ + Nd₂O₃ + Ta₂O₅ + Nb₂O₅ | 2 | 2 | 1.5 | 1.5 | 1.5 | 2 | 2 | 2 | 2 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 8 | 7 | 7 | 7 | 7 | 7 | 8 | 7 | 8 |
| Young's modulus E (GPa) | 98 | 98 | 98 | 98 | 98 | 99 | 99 | 99 | 99 |
| Thermal expansion coefficient α(ppm/° C.) | 3.92 | 3.81 | 3.88 | 3.94 | 3.77 | 3.99 | 4.03 | 4.06 | 3.91 |
| Liquid phase temperature T_{L} (° C.) | 1218 | 1205 | 1227 | 1222 | 1222 | 1254 | 1250 | 1249 | 1234 |
| 13.1 · E+9 − T_{L} | 77 | 91 | 64 | 68 | 69 | 48 | 52 | 52 | 68 |
| 1923 − 156 · α − T_{L} | 93 | 124 | 90 | 87 | 113 | 47 | 45 | 40 | 78 |
| Young's modulus parameter Y | 0.97 | 0.97 | 0.96 | 0.96 | 0.96 | 0.97 | 0.97 | 0.97 | 0.98 |
| Liquid phase parameter L | 9.8 | 9.9 | 9.8 | 9.8 | 10.0 | 9.6 | 9.6 | 9.6 | 9.7 |
| Thermal expansion parameter C | 0.77 | 0.77 | 0.77 | 0.77 | 0.76 | 0.79 | 0.79 | 0.79 | 0.78 |
| Glass transition point (° C.) | 726 | 733 | 731 | 725 | 731 | 741 | 734 | 734 | 741 |
| Density (g/cm³) | 2.76 | 2.71 | 2.74 | 2.75 | 2.68 | 2.80 | 2.80 | 2.81 | 2.76 |
| Liquid phase viscosity log η_{L} (dPa · s) | 3.3 | 3.4 | 3.2 | 3.2 | 3.2 | 3.0 | 3.0 | 3.0 | 3.1 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | ◯ | x | x | ◯ | x | x | x | x |
| Manufacturability determination | ⊚ | ⊚ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 401 | 402 | 403 | 404 | 405 | 406 | 407 | 408 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.4 | 0.4 | 0.4 | 0.4 | 0.4 | 0.4 | 0.4 | 0.4 |
| SrO | 0.2 | 0.2 | 0.2 | 0.2 | 0.2 | 0.2 | 0.2 | 0.2 |
| BaO | 0.3 | 0.3 | 0.3 | 0.3 | 0.3 | 0.3 | 0.3 | 0.3 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1.5 | 1.5 | 1.5 | 1.5 | 1.5 | 1.5 | 1.5 | 1.5 |
| TiO₂ | 0.5 | 0.5 | 1 | 1 | 1 | 1.5 | 1.5 | 1.5 |
| Y₂O₃ | 1 | 2 | | | 1.5 | | | 1 |
| Gd₂O₃ | 1 | | | 1.5 | | | 1 | |
| La₂O₃ | | | 1.5 | | | 1 | | |
| WO₃ | | | | | | | | |
| Ta₂O₅ | | | | | | | | |
| Al₂O₃ + rare earth oxide | 16 | 16 | 15.5 | 15.5 | 15.5 | 15 | 15 | 15 |
| Y₂O₃ + Gd₂O₃ + La₂O₃ + Nd₂O₃ + Ta₂O₅ + Nb₂O₅ | 2 | 2 | 1.5 | 1.5 | 1.5 | 1 | 1 | 1 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 8 | 7 | 7 | 7 | 7 | 7 | 7 | 7 |
| Young's modulus E (GPa) | 99 | 99 | 98 | 98 | 98 | 98 | 98 | 98 |
| Thermal expansion coefficient α(ppm/° C.) | 3.95 | 3.84 | 3.91 | 3.96 | 3.79 | 3.83 | 3.87 | 3.75 |
| Liquid phase temperature T_{L} (° C.) | 1230 | 1219 | 1232 | 1227 | 1221 | 1226 | 1222 | 1222 |
| 13.1 · E+9 − T_{L} | 72 | 84 | 65 | 70 | 77 | 67 | 71 | 72 |
| 1923 − 156 · α − T_{L} | 77 | 106 | 81 | 77 | 110 | 100 | 99 | 116 |
| Young's modulus parameter Y | 0.98 | 0.98 | 0.97 | 0.97 | 0.97 | 0.96 | 0.96 | 0.96 |
| Liquid phase parameter L | 9.7 | 9.8 | 9.8 | 9.8 | 9.9 | 9.9 | 9.9 | 10.1 |
| Thermal expansion parameter C | 0.78 | 0.77 | 0.77 | 0.77 | 0.76 | 0.76 | 0.76 | 0.75 |
| Glass transition point (° C.) | 734 | 741 | 734 | 727 | 734 | 731 | 726 | 731 |
| Density (g/cm³) | 2.77 | 2.72 | 2.75 | 2.76 | 2.69 | 2.70 | 2.71 | 2.66 |
| Liquid phase viscosity log η_{L} (dPa · s) | 3.2 | 3.3 | 3.1 | 3.2 | 3.2 | 3.2 | 3.2 | 3.2 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | ◯ | x | x | ◯ | ◯ | x | ◯ |
| Manufacturability determination | ⊚ | ⊚ | ⊚ | ⊚ | ⊚ | ⊚ | ⊚ | ⊚ |

TABLE 25

| | Example | Example | Example | Example | Example | Example | Example | Example | Example |
|---|---|---|---|---|---|---|---|---|---|
| (mol %) | 409 | 410 | 411 | 412 | 413 | 414 | 415 | 416 | 417 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 5 | 9 | 9 |
| MgO | 20 | 20 | 20 | 20 | 20 | 20 | 20 | 20 | 20 |
| CaO | 0.4 | 0.4 | 0.4 | 0.4 | 0.4 | 0.4 | 0.4 | 0.4 | 0.4 |
| SrO | 0.3 | 0.3 | 0.3 | 0.3 | 0.3 | 0.3 | 0.3 | 0.3 | 0.3 |
| BaO | 0.2 | 0.2 | 0.2 | 0.2 | 0.2 | 0.2 | 0.2 | 0.2 | 0.2 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 0.5 | 0.5 | 0.5 | 0.5 | 0.5 | 0.5 | 0.5 | 0.5 | 0.5 |
| TiO₂ | 0.5 | 0.5 | 0.5 | 0.5 | 0.5 | 0.5 | 0.5 | 1 | 1 |
| Y₂O₃ | 1 | 1 | 1 | 1.5 | 1.5 | 2 | 2 | 1 | 1 |
| Gd₂O₃ | | 1 | 2 | | 1.5 | | 1 | | 1.5 |
| La₂O₃ | 2 | 1 | | 1.5 | | 1 | | 1.5 | |
| WO₃ | | | | | | | | | |
| Ta₂O₅ | | | | | | | | | |
| Al₂O₃ + rare earth oxide | 17 | 17 | 17 | 17 | 17 | 17 | 17 | 16.5 | 16.5 |
| Y₂O₃ + Gd₂O₃ + La₂O₃ + Nd₂O₃ + Ta₂O₅ + Nb₂O₅ | 3 | 3 | 3 | 3 | 3 | 3 | 3 | 2.5 | 2.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 8 | 9 | 8 | 8 | 8 | 8 | 8 | 8 | 8 |
| Young's modulus E (GPa) | 98 | 98 | 98 | 98 | 98 | 98 | 98 | 98 | 98 |
| Thermal expansion coefficient α(ppm/° C.) | 4.02 | 4.06 | 4.09 | 3.98 | 4.04 | 3.95 | 3.98 | 3.94 | 4.00 |
| Liquid phase temperature T_{L} (° C.) | 1266 | 1263 | 1263 | 1262 | 1260 | 1247 | 1247 | 1255 | 1253 |
| 13.1 · E+9 − T_{L} | 32 | 34 | 34 | 37 | 37 | 51 | 51 | 38 | 41 |
| 1923 − 156 · α − T_{L} | 30 | 27 | 21 | 40 | 33 | 60 | 55 | 53 | 47 |
| Young's modulus parameter Y | 0.98 | 0.98 | 0.98 | 0.98 | 0.98 | 0.98 | 0.98 | 0.97 | 0.97 |
| Liquid phase parameter L | 9.5 | 9.5 | 9.5 | 9.5 | 9.5 | 9.6 | 9.6 | 9.6 | 9.6 |
| Thermal expansion parameter C | 0.80 | 0.80 | 0.80 | 0.80 | 0.80 | 0.79 | 0.79 | 0.79 | 0.79 |
| Glass transition point (° C.) | 743 | 736 | 736 | 743 | 736 | 743 | 736 | 736 | 730 |
| Density (g/cm³) | 2.83 | 2.84 | 2.85 | 2.81 | 2.83 | 2.79 | 2.80 | 2.79 | 2.80 |
| Liquid phase viscosity log η_{L} (dPa · s) | 2.9 | 2.9 | 2.9 | 2.9 | 2.9 | 3.0 | 3.0 | 3.0 | 3.0 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | x | x | x | x | x | x |
| Manufacturability determination | ◯ | ◯ | ◯ | ◯ | ◯ | ⊚ | ⊚ | ⊚ | ⊚ |

| | Example | Example | Example | Example | Example | Example | Example | Example |
|---|---|---|---|---|---|---|---|---|
| (mol %) | 418 | 419 | 420 | 421 | 422 | 423 | 424 | 425 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.4 | 0.4 | 0.4 | 0.4 | 0.4 | 0.4 | 0.4 | 0.4 |
| SrO | 0.3 | 0.3 | 0.3 | 0.3 | 0.3 | 0.3 | 0.3 | 0.3 |
| BaO | 0.2 | 0.2 | 0.2 | 0.2 | 0.2 | 0.2 | 0.2 | 0.2 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 0.5 | 0.5 | 0.5 | 0.5 | 0.5 | 0.5 | 0.5 | 0.5 |
| TiO₂ | 1 | 1 | 1 | 1.5 | 1.5 | 1.5 | 1.5 | 1.5 |
| Y₂O₃ | 1.5 | 1.5 | 2.5 | | | | 1 | 1 |
| Gd₂O₃ | | 1 | | | 1 | 2 | | 1 |
| La₂O₃ | 1 | | | 2 | 1 | | 1 | |
| WO₃ | | | | | | | | |
| Ta₂O₅ | | | | | | | | |
| Al₂O₃ + rare earth oxide | 16.5 | 16.5 | 16.5 | 16 | 16 | 16 | 16 | 16 |
| Y₂O₃ + Gd₂O₃ + La₂O₃ + Nd₂O₃ + Ta₂O₅ + Nb₂O₅ | 2.5 | 2.5 | 2.5 | 2 | 2 | 2 | 2 | 2 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 8 | 8 | 7 | 7 | 8 | 7 | 8 | 8 |
| Young's modulus E (GPa) | 98 | 98 | 98 | 98 | 98 | 98 | 98 | 98 |
| Thermal expansion coefficient α(ppm/° C.) | 3.90 | 3.94 | 3.83 | 3.94 | 3.98 | 4.01 | 3.86 | 3.90 |
| Liquid phase temperature T_{L} (° C.) | 1249 | 1248 | 1231 | 1279 | 1276 | 1276 | 1255 | 1252 |
| 13.1 · E+9 − T_{L} | 45 | 46 | 63 | 10 | 12 | 12 | 34 | 37 |
| 1923 − 156 · α − T_{L} | 65 | 61 | 95 | 29 | 27 | 21 | 65 | 63 |
| Young's modulus parameter Y | 0.97 | 0.97 | 0.97 | 0.96 | 0.96 | 0.96 | 0.96 | 0.96 |
| Liquid phase parameter L | 9.7 | 9.7 | 9.8 | 9.7 | 9.7 | 9.7 | 9.8 | 9.8 |
| Thermal expansion parameter C | 0.78 | 0.78 | 0.77 | 0.78 | 0.78 | 0.78 | 0.77 | 0.77 |
| Glass transition point (° C.) | 736 | 729 | 736 | 734 | 728 | 728 | 734 | 728 |
| Density (g/cm³) | 2.77 | 2.77 | 2.73 | 2.78 | 2.79 | 2.79 | 2.74 | 2.75 |
| Liquid phase viscosity log η_{L} (dPa · s) | 3.0 | 3.0 | 3.2 | 2.8 | 2.8 | 2.8 | 3.0 | 3.0 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | ◯ | x | x | x | x | x |
| Manufacturability determination | ⊚ | ⊚ | ⊚ | ◯ | ◯ | ◯ | ⊚ | ⊚ |

TABLE 26

| | Example | Example | Example | Example | Example | Example | Example | Example | Example |
|---|---|---|---|---|---|---|---|---|---|
| (mol %) | 426 | 427 | 428 | 429 | 430 | 431 | 432 | 433 | 434 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.4 | 0.4 | 0.4 | 0.4 | 0.4 | 0.4 | 0.4 | 0.4 | 0.4 |
| SrO | 0.3 | 0.3 | 0.3 | 0.3 | 0.3 | 0.3 | 0.3 | 0.3 | 0.3 |
| BaO | 0.2 | 0.2 | 0.2 | 0.2 | 0.2 | 0.2 | 0.2 | 0.2 | 0.2 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 0.5 | 1 | 1 | 1 | 1 | 1 | 1 | 1 | 1 |
| TiO₂ | 1.5 | 0.5 | 0.5 | 0.5 | 0.5 | 0.5 | 0.5 | 0.5 | 0.5 |
| Y₂O₃ | 2 | | | | | 1 | 1 | 1.5 | 1.5 |
| Gd₂O₃ | | | 1 | 1.5 | 2.5 | | 1.5 | | 1 |
| La₂O₃ | | 2.5 | 1.5 | 1 | | 1.5 | | 1 | |
| WO₃ | | | | | | | | | |
| Ta₂O₅ | | | | | | | | | |
| Al₂O₃ + rare earth oxide | 16 | 16.5 | 16.5 | 16.5 | 16.5 | 16.5 | 16.5 | 16.5 | 16.5 |
| Y₂O₃ + Gd₂O₃ + La₂O₃ + Nd₂O₃ + Ta₂O₅ + Nb₂O₅ | 2 | 2.5 | 2.5 | 2.5 | 2.5 | 2.5 | 2.5 | 2.5 | 2.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 7 | 7 | 8 | 8 | 7 | 8 | 8 | 8 | 8 |
| Young's modulus E (GPa) | 98 | 99 | 99 | 99 | 98 | 99 | 99 | 99 | 99 |
| Thermal expansion coefficient α(ppm/° C.) | 3.78 | 4.05 | 4.08 | 4.10 | 4.13 | 3.97 | 4.02 | 3.93 | 3.96 |
| Liquid phase temperature T_{L} (° C.) | 1232 | 1253 | 1250 | 1249 | 1248 | 1233 | 1228 | 1233 | 1230 |
| 13.1 · E+9 − T_{L} | 58 | 47 | 50 | 50 | 51 | 68 | 72 | 68 | 70 |
| 1923 − 156 · α − T_{L} | 101 | 39 | 37 | 35 | 30 | 72 | 68 | 78 | 74 |
| Young's modulus parameter Y | 0.96 | 0.97 | 0.97 | 0.97 | 0.97 | 0.98 | 0.98 | 0.98 | 0.98 |
| Liquid phase parameter L | 9.9 | 9.5 | 9.5 | 9.5 | 9.5 | 9.6 | 9.6 | 9.6 | 9.6 |
| Thermal expansion parameter C | 0.76 | 0.80 | 0.80 | 0.80 | 0.80 | 0.79 | 0.79 | 0.79 | 0.79 |
| Glass transition point (° C.) | 734 | 743 | 736 | 736 | 736 | 743 | 736 | 743 | 736 |
| Density (g/cm³) | 2.70 | 2.83 | 2.84 | 2.85 | 2.85 | 2.79 | 2.81 | 2.77 | 2.78 |
| Liquid phase viscosity log η_{L} (dPa · s) | 3.1 | 3.0 | 3.0 | 3.0 | 3.0 | 3.1 | 3.2 | 3.1 | 3.2 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | ◯ | x | x | x | x | x | x | x | x |
| Manufacturability determination | ⊚ | ⊚ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 435 | 436 | 437 | 438 | 439 | 440 | 441 | 442 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.4 | 0.4 | 0.4 | 0.4 | 0.4 | 0.4 | 0.4 | 0.4 |
| SrO | 0.3 | 0.3 | 0.3 | 0.3 | 0.3 | 0.3 | 0.3 | 0.3 |
| BaO | 0.2 | 0.2 | 0.2 | 0.2 | 0.2 | 0.2 | 0.2 | 0.2 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1 | 1 | 1 | 1 | 1 | 1 | 1 | 1 |
| TiO₂ | 0.5 | 1 | 1 | 1 | 1 | 1 | 1 | 1.5 |
| Y₂O₃ | 2.5 | | | | 1 | 1 | 2 | |
| Gd₂O₃ | | | 1 | 2 | | 1 | | |
| La₂O₃ | | 2 | 1 | | 1 | | | 1.5 |
| WO₃ | | | | | | | | |
| Ta₂O₅ | | | | | | | | |
| Al₂O₃ + rare earth oxide | 16.5 | 16 | 16 | 16 | 16 | 16 | 16 | 15.5 |
| Y₂O₃ + Gd₂O₃ + La₂O₃ + Nd₂O₃ + Ta₂O₅ + Nb₂O₅ | 2.5 | 2 | 2 | 2 | 2 | 2 | 2 | 1.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 7 | 7 | 8 | 7 | 8 | 8 | 7 | 7 |
| Young's modulus E (GPa) | 99 | 98 | 98 | 98 | 98 | 98 | 98 | 98 |
| Thermal expansion coefficient α(ppm/° C.) | 3.85 | 3.96 | 4.00 | 4.04 | 3.89 | 3.92 | 3.81 | 3.88 |
| Liquid phase temperature T_{L} (° C.) | 1217 | 1232 | 1228 | 1227 | 1221 | 1216 | 1203 | 1225 |
| 13.1 · E+9 − T_{L} | 84 | 64 | 68 | 68 | 75 | 79 | 93 | 66 |
| 1923 − 156 · α − T_{L} | 105 | 73 | 71 | 66 | 95 | 95 | 125 | 92 |
| Young's modulus parameter Y | 0.98 | 0.97 | 0.97 | 0.97 | 0.97 | 0.97 | 0.97 | 0.96 |
| Liquid phase parameter L | 9.7 | 9.6 | 9.6 | 9.6 | 9.8 | 9.8 | 9.9 | 9.8 |
| Thermal expansion parameter C | 0.78 | 0.78 | 0.78 | 0.78 | 0.78 | 0.78 | 0.77 | 0.77 |
| Glass transition point (° C.) | 743 | 736 | 729 | 729 | 736 | 729 | 736 | 733 |
| Density (g/cm³) | 2.74 | 2.79 | 2.79 | 2.80 | 2.75 | 2.75 | 2.71 | 2.74 |
| Liquid phase viscosity log η_{L} (dPa · s) | 3.3 | 3.1 | 3.2 | 3.2 | 3.2 | 3.3 | 3.4 | 3.2 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | x | x | x | x | ◯ | x |
| Manufacturability determination | ⊚ | ⊚ | ⊚ | ⊚ | ⊚ | ⊚ | ⊚ | ⊚ |

TABLE 27

| | Example | Example | Example | Example | Example | Example | Example | Example | Example |
|---|---|---|---|---|---|---|---|---|---|
| (mol %) | 443 | 444 | 445 | 446 | 447 | 448 | 449 | 450 | 451 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.4 | 0.4 | 0.4 | 0.4 | 0.4 | 0.4 | 0.4 | 0.4 | 0.4 |
| SrO | 0.3 | 0.3 | 0.3 | 0.3 | 0.3 | 0.3 | 0.3 | 0.3 | 0.3 |
| BaO | 0.2 | 0.2 | 0.2 | 0.2 | 0.2 | 0.2 | 0.2 | 0.2 | 0.2 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1 | 1 | 1.5 | 1.5 | 1.5 | 1.5 | 1.5 | 1.5 | 1.5 |
| TiO₂ | 1.5 | 1.5 | 0.5 | 0.5 | 0.5 | 0.5 | 0.5 | 0.5 | 1 |
| Y₂O₃ | | 1.5 | | | | 1 | 1 | 2 | |
| Gd₂O₃ | 1.5 | | | 1 | 2 | | 1 | | |
| La₂O₃ | | | 2 | 1 | | 1 | | | 1.5 |
| WO₃ | | | | | | | | | |
| Ta₂O₅ | | | | | | | | | |
| Al₂O₃ + rare earth oxide | 15.5 | 15.5 | 16 | 16 | 16 | 16 | 16 | 16 | 15.5 |
| Y₂O₃ + Gd₂O₃ + La₂O₃ + Nd₂O₃ + Ta₂O₅ + Nb₂O₅ | 1.5 | 1.5 | 2 | 2 | 2 | 2 | 2 | 2 | 1.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 7 | 7 | 7 | 8 | 7 | 8 | 8 | 7 | 7 |
| Young's modulus E (GPa) | 98 | 98 | 99 | 99 | 99 | 99 | 99 | 99 | 98 |
| Thermal expansion coefficient α(ppm/° C.) | 3.94 | 3.77 | 3.99 | 4.03 | 4.06 | 3.91 | 3.95 | 3.83 | 3.91 |
| Liquid phase temperature T_{L} (° C.) | 1220 | 1219 | 1255 | 1251 | 1250 | 1234 | 1230 | 1220 | 1234 |
| 13.1 · E+9 − T_{L} | 71 | 73 | 48 | 51 | 52 | 68 | 72 | 83 | 64 |
| 1923 − 156 · α − T_{L} | 89 | 116 | 46 | 44 | 39 | 78 | 77 | 105 | 79 |
| Young's modulus parameter Y | 0.96 | 0.96 | 0.97 | 0.97 | 0.97 | 0.98 | 0.98 | 0.98 | 0.97 |
| Liquid phase parameter L | 9.8 | 10.0 | 9.6 | 9.6 | 9.6 | 9.7 | 9.7 | 9.8 | 9.8 |
| Thermal expansion parameter C | 0.77 | 0.76 | 0.79 | 0.79 | 0.79 | 0.78 | 0.78 | 0.77 | 0.77 |
| Glass transition point (° C.) | 728 | 733 | 743 | 736 | 736 | 743 | 736 | 743 | 736 |
| Density (g/cm³) | 2.75 | 2.68 | 2.79 | 2.80 | 2.81 | 2.76 | 2.76 | 2.72 | 2.75 |
| Liquid phase viscosity log η_{L} (dPa · s) | 3.2 | 3.2 | 3.0 | 3.0 | 3.0 | 3.1 | 3.2 | 3.2 | 3.1 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | ◯ | x | x | x | x | x | ◯ | x |
| Manufacturability determination | ⊚ | ⊚ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 452 | 453 | 454 | 455 | 456 | 457 | 458 | 459 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.4 | 0.4 | 0.4 | 0.4 | 0.4 | 0.4 | 0.4 | 0.4 |
| SrO | 0.3 | 0.3 | 0.3 | 0.3 | 0.3 | 0.5 | 0.5 | 0.5 |
| BaO | 0.2 | 0.2 | 0.2 | 0.2 | 0.2 | 0.5 | 0.5 | 0.5 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1.5 | 1.5 | 1.5 | 1.5 | 1.5 | 0.5 | 0.5 | 0.5 |
| TiO₂ | 1 | 1 | 1.5 | 1.5 | 1.5 | 0.5 | 0.5 | 0.5 |
| Y₂O₃ | | 1.5 | | | 1 | 1 | 1 | 1.5 |
| Gd₂O₃ | 1.5 | | | 1 | | | 1.5 | |
| La₂O₃ | | | 1 | | | 1.5 | | 1 |
| WO₃ | | | | | | | | |
| Ta₂O₅ | | | | | | | | |
| Al₂O₃ + rare earth oxide | 15.5 | 15.5 | 15 | 15 | 15 | 16.5 | 16.5 | 16.5 |
| Y₂O₃ + Gd₂O₃ + La₂O₃ + Nd₂O₃ + Ta₂O₅ + Nb₂O₅ | 1.5 | 1.5 | 1 | 1 | 1 | 2.5 | 2.5 | 2.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.93 | 0.93 | 0.93 |
| N | 7 | 7 | 7 | 7 | 7 | 10 | 10 | 10 |
| Young's modulus E (GPa) | 98 | 98 | 98 | 98 | 98 | 98 | 98 | 98 |
| Thermal expansion coefficient α(ppm/° C.) | 3.96 | 3.79 | 3.83 | 3.86 | 3.75 | 4.01 | 4.06 | 3.97 |
| Liquid phase temperature T_{L} (° C.) | 1229 | 1222 | 1227 | 1222 | 1222 | 1263 | 1261 | 1259 |
| 13.1 · E+9 − T_{L} | 68 | 77 | 67 | 71 | 72 | 25 | 27 | 29 |
| 1923 − 156 · α − T_{L} | 76 | 109 | 99 | 98 | 116 | 34 | 29 | 45 |
| Young's modulus parameter Y | 0.97 | 0.97 | 0.96 | 0.96 | 0.96 | 0.97 | 0.97 | 0.97 |
| Liquid phase parameter L | 9.8 | 9.9 | 9.9 | 9.9 | 10.0 | 9.6 | 9.6 | 9.6 |
| Thermal expansion parameter C | 0.77 | 0.76 | 0.76 | 0.76 | 0.75 | 0.80 | 0.80 | 0.79 |
| Glass transition point (° C.) | 729 | 736 | 734 | 728 | 734 | 736 | 730 | 736 |
| Density (g/cm³) | 2.76 | 2.69 | 2.70 | 2.71 | 2.66 | 2.80 | 2.81 | 2.78 |
| Liquid phase viscosity log η_{L} (dPa · s) | 3.2 | 3.2 | 3.2 | 3.2 | 3.2 | 2.9 | 2.9 | 2.9 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | ◯ | ◯ | x | ◯ | x | x | x |
| Manufacturability determination | ⊚ | ⊚ | ⊚ | ⊚ | ⊚ | ◯ | ◯ | ⊚ |

TABLE 28

| | Example | Example | Example | Example | Example | Example | Example | Example | Example |
|---|---|---|---|---|---|---|---|---|---|
| (mol %) | 460 | 461 | 462 | 463 | 464 | 465 | 466 | 467 | 468 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.4 | 0.4 | 0.4 | 0.4 | 0.4 | 0.4 | 0.4 | 0.4 | 0.4 |
| SrO | 0.5 | 0.5 | 0.5 | 0.5 | 0.5 | 0.5 | 0.5 | 0.5 | 0.5 |
| BaO | 0.5 | 0.5 | 0.5 | 0.5 | 0.5 | 0.5 | 0.5 | 0.5 | 0.5 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 0.5 | 0.5 | 0.5 | 0.5 | 0.5 | 0.5 | 0.5 | 1 | 1 |
| TiO₂ | 0.5 | 0.5 | 1 | 1 | 1 | 1 | 1 | 0.5 | 0.5 |
| Y₂O₃ | 1.5 | 2.5 | | | 1 | 1 | 2 | | |
| Gd₂O₃ | 1 | | 1 | 2 | | 1 | | | 1 |
| La₂O₃ | | | 1 | | 1 | | | 2 | 1 |
| WO₃ | | | | | | | | | |
| Ta₂O₅ | | | | | | | | | |
| Al₂O₃ + rare earth oxide | 16.5 | 16.5 | 16 | 16 | 16 | 16 | 16 | 16 | 16 |
| Y₂O₃ + Gd₂O₃ + La₂O₃ + Nd₂O₃ + Ta₂O₅ + Nb₂O₅ | 2.5 | 2.5 | 2 | 2 | 2 | 2 | 2 | 2 | 2 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.93 | 0.93 | 0.93 | 0.93 | 0.93 | 0.93 | 0.93 | 0.93 | 0.93 |
| N | 10 | 9 | 10 | 9 | 10 | 10 | 9 | 9 | 10 |
| Young's modulus E (GPa) | 98 | 98 | 97 | 97 | 97 | 97 | 97 | 98 | 98 |
| Thermal expansion coefficient α(ppm/° C.) | 4.01 | 3.89 | 4.04 | 4.08 | 3.93 | 3.96 | 3.85 | 4.03 | 4.07 |
| Liquid phase temperature T_{L} (° C.) | 1258 | 1241 | 1279 | 1279 | 1253 | 1250 | 1228 | 1251 | 1247 |
| 13.1 · E+9 − T_{L} | 30 | 47 | 4 | 3 | 31 | 33 | 56 | 39 | 42 |
| 1923 − 156 · α − T_{L} | 40 | 74 | 13 | 8 | 57 | 55 | 95 | 43 | 41 |
| Young's modulus parameter Y | 0.97 | 0.97 | 0.96 | 0.96 | 0.96 | 0.96 | 0.96 | 0.96 | 0.96 |
| Liquid phase parameter L | 9.6 | 9.7 | 9.6 | 9.6 | 9.7 | 9.7 | 9.8 | 9.6 | 9.6 |
| Thermal expansion parameter C | 0.79 | 0.78 | 0.79 | 0.79 | 0.78 | 0.78 | 0.77 | 0.79 | 0.79 |
| Glass transition point (° C.) | 730 | 736 | 725 | 725 | 731 | 725 | 731 | 737 | 730 |
| Density (g/cm³) | 2.79 | 2.74 | 2.80 | 2.81 | 2.75 | 2.76 | 2.71 | 2.80 | 2.81 |
| Liquid phase viscosity log η_{L} (dPa · s) | 2.9 | 3.1 | 2.8 | 2.8 | 3.0 | 3.0 | 3.2 | 3.0 | 3.0 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | x | x | x | x | x | x |
| Manufacturability determination | ⊚ | ⊚ | ◯ | ◯ | ⊚ | ⊚ | ⊚ | ⊚ | ⊚ |

| | Example | Example | Example | Example | Example | Example | Example | Example |
|---|---|---|---|---|---|---|---|---|
| (mol %) | 469 | 470 | 471 | 472 | 473 | 474 | 475 | 476 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.4 | 0.4 | 0.4 | 0.4 | 0.4 | 0.4 | 0.4 | 0.4 |
| SrO | 0.5 | 0.5 | 0.5 | 0.5 | 0.5 | 0.5 | 0.5 | 0.5 |
| BaO | 0.5 | 0.5 | 0.5 | 0.5 | 0.5 | 0.5 | 0.5 | 0.5 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1 | 1 | 1 | 1 | 1 | 1 | 1 | 1.5 |
| TiO₂ | 0.5 | 0.5 | 0.5 | 0.5 | 1 | 1 | 1 | 0.5 |
| Y₂O₃ | | 1 | 1 | 2 | | | 1.5 | |
| Gd₂O₃ | 2 | | 1 | | | 1.5 | | |
| La₂O₃ | | 1 | | | 1.5 | | | 1.5 |
| WO₃ | | | | | | | | |
| Ta₂O₅ | | | | | | | | |
| Al₂O₃ + rare earth oxide | 16 | 16 | 16 | 16 | 15.5 | 15.5 | 15.5 | 15.5 |
| Y₂O₃ + Gd₂O₃ + La₂O₃ + Nd₂O₃ + Ta₂O₅ + Nb₂O₅ | 2 | 2 | 2 | 2 | 1.5 | 1.5 | 1.5 | 1.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.93 | 0.93 | 0.93 | 0.93 | 0.93 | 0.93 | 0.93 | 0.93 |
| N | 9 | 10 | 10 | 9 | 9 | 9 | 9 | 9 |
| Young's modulus E (GPa) | 98 | 98 | 98 | 98 | 97 | 97 | 97 | 98 |
| Thermal expansion coefficient α(ppm/° C.) | 4.10 | 3.95 | 3.99 | 3.88 | 3.95 | 4.00 | 3.83 | 3.98 |
| Liquid phase temperature T_{L} (° C.) | 1246 | 1230 | 1226 | 1214 | 1230 | 1225 | 1218 | 1252 |
| 13.1 · E+9 − T_{L} | 43 | 60 | 64 | 76 | 56 | 60 | 68 | 40 |
| 1923 − 156 · α − T_{L} | 37 | 76 | 75 | 104 | 77 | 73 | 107 | 51 |
| Young's modulus parameter Y | 0.96 | 0.97 | 0.97 | 0.97 | 0.96 | 0.96 | 0.96 | 0.96 |
| Liquid phase parameter L | 9.6 | 9.7 | 9.7 | 9.8 | 9.7 | 9.7 | 9.9 | 9.7 |
| Thermal expansion parameter C | 0.79 | 0.79 | 0.79 | 0.78 | 0.78 | 0.78 | 0.77 | 0.78 |
| Glass transition point (° C.) | 731 | 737 | 730 | 737 | 731 | 724 | 731 | 737 |
| Density (g/cm³) | 2.82 | 2.76 | 2.77 | 2.72 | 2.75 | 2.76 | 2.69 | 2.76 |
| Liquid phase viscosity log η_{L} (dPa · s) | 3.0 | 3.2 | 3.2 | 3.3 | 3.2 | 3.2 | 3.3 | 3.0 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | x | x | x | x | x | x |
| Manufacturability determination | ⊚ | ⊚ | ⊚ | ⊚ | ⊚ | ⊚ | ⊚ | ⊚ |

TABLE 29

| | Example | Example | Example | Example | Example | Example | Example | Example | Example |
|---|---|---|---|---|---|---|---|---|---|
| (mol %) | 477 | 478 | 479 | 480 | 481 | 482 | 483 | 484 | 485 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.4 | 0.4 | 0.4 | 0.4 | 0.4 | 0.5 | 0.5 | 0.5 | 0.5 |
| SrO | 0.5 | 0.5 | 0.5 | 0.5 | 0.5 | 0.2 | 0.2 | 0.2 | 0.2 |
| BaO | 0.5 | 0.5 | 0.5 | 0.5 | 0.5 | 0.2 | 0.2 | 0.2 | 0.2 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1.5 | 1.5 | 1.5 | 1.5 | 1.5 | 0.5 | 0.5 | 0.5 | 0.5 |
| TiO₂ | 0.5 | 0.5 | 1 | 1 | 1 | 0.5 | 0.5 | 0.5 | 0.5 |
| Y₂O₃ | | 1.5 | | | 1 | 1 | 1 | 1 | 1.5 |
| Gd₂O₃ | 1.5 | | | 1 | | | 1 | 2 | |
| La₂O₃ | | | 1 | | | 2 | 1 | | 1.5 |
| WO₃ | | | | | | | | | |
| Ta₂O₅ | | | | | | | | | |
| Al₂O₃ + rare earth oxide | 15.5 | 15.5 | 15 | 15 | 15 | 17 | 17 | 17 | 17 |
| Y₂O₃ + Gd₂O₃ + La₂O₃ + Nd₂O₃ + Ta₂O₅ + Nb₂O₅ | 1.5 | 1.5 | 1 | 1 | 1 | 3 | 3 | 3 | 3 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.93 | 0.93 | 0.93 | 0.93 | 0.93 | 0.96 | 0.96 | 0.96 | 0.96 |
| N | 9 | 9 | 9 | 9 | 9 | 9 | 10 | 9 | 9 |
| Young's modulus E (GPa) | 98 | 98 | 98 | 98 | 98 | 98 | 98 | 98 | 98 |
| Thermal expansion coefficient α(ppm/° C.) | 4.03 | 3.86 | 3.90 | 3.93 | 3.82 | 4.02 | 4.05 | 4.09 | 3.98 |
| Liquid phase temperature T_{L} (° C.) | 1247 | 1230 | 1230 | 1226 | 1218 | 1271 | 1268 | 1268 | 1267 |
| 13.1 · E+9 − T_{L} | 44 | 62 | 57 | 61 | 70 | 28 | 30 | 29 | 32 |
| 1923 − 156 · α − T_{L} | 47 | 91 | 85 | 84 | 109 | 25 | 22 | 17 | 36 |
| Young's modulus parameter Y | 0.96 | 0.97 | 0.96 | 0.96 | 0.96 | 0.98 | 0.98 | 0.98 | 0.98 |
| Liquid phase parameter L | 9.7 | 9.8 | 9.8 | 9.8 | 9.9 | 9.5 | 9.5 | 9.5 | 9.5 |
| Thermal expansion parameter C | 0.78 | 0.77 | 0.77 | 0.77 | 0.76 | 0.80 | 0.80 | 0.80 | 0.80 |
| Glass transition point (° C.) | 731 | 737 | 731 | 725 | 731 | 744 | 737 | 737 | 744 |
| Density (g/cm³) | 2.77 | 2.70 | 2.71 | 2.72 | 2.67 | 2.83 | 2.84 | 2.85 | 2.81 |
| Liquid phase viscosity log η_{L} (dPa · s) | 3.0 | 3.2 | 3.2 | 3.2 | 3.3 | 2.8 | 2.9 | 2.9 | 2.9 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | x | ◯ | x | x | x | x |
| Manufacturability determination | ⊚ | ⊚ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 486 | 487 | 488 | 489 | 490 | 491 | 492 | 493 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.5 | 0.5 | 0.5 | 0.5 | 0.5 | 0.5 | 0.5 | 0.5 |
| SrO | 0.2 | 0.2 | 0.2 | 0.2 | 0.2 | 0.2 | 0.2 | 0.2 |
| BaO | 0.2 | 0.2 | 0.2 | 0.2 | 0.2 | 0.2 | 0.2 | 0.2 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 0.5 | 0.5 | 0.5 | 0.5 | 0.5 | 0.5 | 0.5 | 0.5 |
| TiO₂ | 0.5 | 0.5 | 0.5 | 1 | 1 | 1 | 1 | 1 |
| Y₂O₃ | 1.5 | 2 | 2 | 1 | 1 | 1.5 | 1.5 | 2.5 |
| Gd₂O₃ | 1.5 | | 1 | | 1.5 | | 1 | |
| La₂O₃ | | 1 | | 1.5 | | 1 | | |
| WO₃ | | | | | | | | |
| Ta₂O₅ | | | | | | | | |
| Al₂O₃ + rare earth oxide | 17 | 17 | 17 | 16.5 | 16.5 | 16.5 | 16.5 | 16.5 |
| Y₂O₃ + Gd₂O₃ + La₂O₃ + Nd₂O₃ + Ta₂O₅ + Nb₂O₅ | 3 | 3 | 3 | 2.5 | 2.5 | 2.5 | 2.5 | 2.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 9 | 9 | 9 | 9 | 9 | 9 | 9 | 8 |
| Young's modulus E (GPa) | 98 | 98 | 98 | 98 | 98 | 98 | 98 | 98 |
| Thermal expansion coefficient α(ppm/° C.) | 4.03 | 3.94 | 3.98 | 3.94 | 3.99 | 3.90 | 3.93 | 3.82 |
| Liquid phase temperature T_{L} (° C.) | 1265 | 1254 | 1254 | 1260 | 1257 | 1254 | 1252 | 1237 |
| 13.1 · E+9 − T_{L} | 33 | 45 | 45 | 34 | 37 | 41 | 42 | 58 |
| 1923 − 156 · α − T_{L} | 28 | 55 | 49 | 49 | 43 | 61 | 57 | 90 |
| Young's modulus parameter Y | 0.98 | 0.98 | 0.98 | 0.97 | 0.97 | 0.97 | 0.97 | 0.97 |
| Liquid phase parameter L | 9.5 | 9.6 | 9.6 | 9.7 | 9.7 | 9.7 | 9.7 | 9.8 |
| Thermal expansion parameter C | 0.80 | 0.79 | 0.79 | 0.79 | 0.79 | 0.78 | 0.78 | 0.77 |
| Glass transition point (° C.) | 737 | 744 | 737 | 737 | 730 | 737 | 729 | 737 |
| Density (g/cm³) | 2.82 | 2.79 | 2.80 | 2.78 | 2.80 | 2.76 | 2.77 | 2.73 |
| Liquid phase viscosity log η_{L} (dPa · s) | 2.9 | 3.0 | 3.0 | 2.9 | 2.9 | 3.0 | 3.0 | 3.1 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | x | x | x | x | x | ◯ |
| Manufacturability determination | ⊚ | ⊚ | ⊚ | ⊚ | ⊚ | ⊚ | ⊚ | ⊚ |

TABLE 30

| | Example | Example | Example | Example | Example | Example | Example | Example | Example |
|---|---|---|---|---|---|---|---|---|---|
| (mol %) | 494 | 495 | 496 | 497 | 498 | 499 | 500 | 501 | 502 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.5 | 0.5 | 0.5 | 0.5 | 0.5 | 0.5 | 0.5 | 0.5 | 0.5 |
| SrO | 0.2 | 0.2 | 0.2 | 0.2 | 0.2 | 0.2 | 0.2 | 0.2 | 0.2 |
| BaO | 0.2 | 0.2 | 0.2 | 0.2 | 0.2 | 0.2 | 0.2 | 0.2 | 0.2 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 0.5 | 0.5 | 0.5 | 1 | 1 | 1 | 1 | 1 | 1 |
| TiO₂ | 1.5 | 1.5 | 1.5 | 0.5 | 0.5 | 0.5 | 0.5 | 0.5 | 0.5 |
| Y₂O₃ | 1 | 1 | 2 | | | | | 1 | 1 |
| Gd₂O₃ | | 1 | | | 1 | 1.5 | 2.5 | | 1.5 |
| La₂O₃ | 1 | | | 2.5 | 1.5 | 1 | | 1.5 | |
| WO₃ | | | | | | | | | |
| Ta₂O₅ | | | | | | | | | |
| Al₂O₃ + rare earth oxide | 16 | 16 | 16 | 16.5 | 16.5 | 16.5 | 16.5 | 16.5 | 16.5 |
| Y₂O₃ + Gd₂O₃ + La₂O₃ + Nd₂O₃ + Ta₂O₅ + Nb₂O₅ | 2 | 2 | 2 | 2.5 | 2.5 | 2.5 | 2.5 | 2.5 | 2.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 9 | 9 | 8 | 8 | 9 | 9 | 8 | 9 | 9 |
| Young's modulus E (GPa) | 98 | 98 | 98 | 99 | 99 | 99 | 98 | 99 | 99 |
| Thermal expansion coefficient α(ppm/° C.) | 3.86 | 3.89 | 3.78 | 4.04 | 4.08 | 4.09 | 4.13 | 3.96 | 4.02 |
| Liquid phase temperature T_{L} (° C.) | 1261 | 1258 | 1239 | 1257 | 1253 | 1253 | 1252 | 1237 | 1233 |
| 13.1 · E+9 − T_{L} | 29 | 32 | 52 | 44 | 46 | 47 | 47 | 64 | 67 |
| 1923 − 156 · α − T_{L} | 61 | 58 | 95 | 36 | 34 | 32 | 27 | 68 | 64 |
| Young's modulus parameter Y | 0.96 | 0.96 | 0.96 | 0.97 | 0.97 | 0.97 | 0.97 | 0.98 | 0.98 |
| Liquid phase parameter L | 9.8 | 9.8 | 9.9 | 9.5 | 9.5 | 9.5 | 9.5 | 9.6 | 9.6 |
| Thermal expansion parameter C | 0.77 | 0.77 | 0.76 | 0.80 | 0.80 | 0.80 | 0.80 | 0.79 | 0.79 |
| Glass transition point (° C.) | 734 | 728 | 734 | 744 | 737 | 737 | 737 | 744 | 737 |
| Density (g/cm³) | 2.74 | 2.74 | 2.70 | 2.83 | 2.84 | 2.84 | 2.85 | 2.79 | 2.81 |
| Liquid phase viscosity log η_{L} (dPa · s) | 2.9 | 2.9 | 3.1 | 3.0 | 3.0 | 3.0 | 3.0 | 3.1 | 3.1 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | ◯ | x | x | x | x | x | x |
| Manufacturability determination | ◯ | ⊚ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 503 | 504 | 505 | 506 | 507 | 508 | 509 | 510 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.5 | 0.5 | 0.5 | 0.5 | 0.5 | 0.5 | 0.5 | 0.5 |
| SrO | 0.2 | 0.2 | 0.2 | 0.2 | 0.2 | 0.2 | 0.2 | 0.2 |
| BaO | 0.2 | 0.2 | 0.2 | 0.2 | 0.2 | 0.2 | 0.2 | 0.2 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1 | 1 | 1 | 1 | 1 | 1 | 1 | 1 |
| TiO₂ | 0.5 | 0.5 | 0.5 | 1 | 1 | 1 | 1 | 1 |
| Y₂O₃ | 1.5 | 1.5 | 2.5 | | | | 1 | 1 |
| Gd₂O₃ | | 1 | | | 1 | 2 | | 1 |
| La₂O₃ | 1 | | | 2 | 1 | | 1 | |
| WO₃ | | | | | | | | |
| Ta₂O₅ | | | | | | | | |
| Al₂O₃ + rare earth oxide | 16.5 | 16.5 | 16.5 | 16 | 16 | 16 | 16 | 16 |
| Y₂O₃ + Gd₂O₃ + La₂O₃ + Nd₂O₃ + Ta₂O₅ + Nb₂O₅ | 2.5 | 2.5 | 2.5 | 2 | 2 | 2 | 2 | 2 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 |
| N | 9 | 9 | 8 | 8 | 9 | 8 | 9 | 9 |
| Young's modulus E (GPa) | 99 | 99 | 99 | 98 | 98 | 98 | 98 | 98 |
| Thermal expansion coefficient α(ppm/° C.) | 3.92 | 3.96 | 3.85 | 3.96 | 4.00 | 4.03 | 3.88 | 3.92 |
| Liquid phase temperature T_{L} (° C.) | 1237 | 1235 | 1222 | 1235 | 1231 | 1230 | 1225 | 1220 |
| 13.1 · E+9 − T_{L} | 64 | 66 | 79 | 61 | 65 | 65 | 71 | 76 |
| 1923 − 156 · α − T_{L} | 74 | 70 | 101 | 70 | 69 | 64 | 92 | 91 |
| Young's modulus parameter Y | 0.98 | 0.98 | 0.98 | 0.97 | 0.97 | 0.97 | 0.97 | 0.97 |
| Liquid phase parameter L | 9.7 | 9.7 | 9.8 | 9.7 | 9.7 | 9.7 | 9.8 | 9.8 |
| Thermal expansion parameter C | 0.79 | 0.79 | 0.78 | 0.78 | 0.78 | 0.78 | 0.77 | 0.77 |
| Glass transition point (° C.) | 744 | 737 | 744 | 736 | 729 | 729 | 736 | 729 |
| Density (g/cm³) | 2.77 | 2.78 | 2.73 | 2.78 | 2.79 | 2.80 | 2.75 | 2.75 |
| Liquid phase viscosity log η_{L} (dPa · s) | 3.1 | 3.1 | 3.2 | 3.1 | 3.2 | 3.2 | 3.2 | 3.2 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | x | x | x | x | x | x |
| Manufacturability determination | ⊚ | ⊚ | ⊚ | ⊚ | ⊚ | ⊚ | ⊚ | ⊚ |

TABLE 31

| | Example | Example | Example | Example | Example | Example | Example | Example | Example |
|---|---|---|---|---|---|---|---|---|---|
| (mol %) | 511 | 512 | 513 | 514 | 515 | 516 | 517 | 518 | 519 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.5 | 0.5 | 0.5 | 0.5 | 0.5 | 0.5 | 0.5 | 0.5 | 0.5 |
| SrO | 0.2 | 0.2 | 0.2 | 0.2 | 0.2 | 0.2 | 0.2 | 0.2 | 0.2 |
| BaO | 0.2 | 0.2 | 0.2 | 0.2 | 0.2 | 0.2 | 0.2 | 0.2 | 0.2 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1 | 1 | 1 | 1 | 1.5 | 1.5 | 1.5 | 1.5 | 1.5 |
| TiO₂ | 1 | 1.5 | 1.5 | 1.5 | 0.5 | 0.5 | 0.5 | 0.5 | 0.5 |
| Y₂O₃ | 2 | | | 1.5 | | | | 1 | 1 |
| Gd₂O₃ | | | 1.5 | | | 1 | 2 | | 1 |
| La₂O₃ | | 1.5 | | | 2 | 1 | | 1 | |
| WO₃ | | | | | | | | | |
| Ta₂O₅ | | | | | | | | | |
| Al₂O₃ + rare earth oxide | 16 | 15.5 | 15.5 | 15.5 | 16 | 16 | 16 | 16 | 16 |
| Y₂O₃ + Gd₂O₃ + La₂O₃ + Nd₂O₃ + Ta₂O₅ + Nb₂O₅ | 2 | 1.5 | 1.5 | 1.5 | 2 | 2 | 2 | 2 | 2 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.96 | 0.96 |
| N | 8 | 8 | 8 | 8 | 8 | 9 | 8 | 9 | 9 |
| Young's modulus E (GPa) | 98 | 98 | 98 | 98 | 99 | 99 | 99 | 99 | 99 |
| Thermal expansion coefficient α(ppm/° C.) | 3.80 | 3.88 | 3.93 | 3.76 | 3.99 | 4.02 | 4.06 | 3.91 | 3.94 |
| Liquid phase temperature T_{L} (° C.) | 1208 | 1230 | 1225 | 1225 | 1257 | 1253 | 1252 | 1237 | 1233 |
| 13.1 · E+9 − T_{L} | 89 | 62 | 67 | 68 | 46 | 49 | 50 | 66 | 70 |
| 1923 − 156 · α − T_{L} | 122 | 88 | 85 | 111 | 44 | 43 | 38 | 76 | 75 |
| Young's modulus parameter Y | 0.97 | 0.96 | 0.96 | 0.96 | 0.97 | 0.97 | 0.97 | 0.98 | 0.98 |
| Liquid phase parameter L | 9.9 | 9.8 | 9.8 | 10.0 | 9.6 | 9.6 | 9.6 | 9.7 | 9.7 |
| Thermal expansion parameter C | 0.77 | 0.77 | 0.77 | 0.76 | 0.79 | 0.79 | 0.79 | 0.78 | 0.78 |
| Glass transition point (° C.) | 736 | 733 | 728 | 733 | 744 | 737 | 737 | 744 | 737 |
| Density (g/cm³) | 2.71 | 2.74 | 2.75 | 2.68 | 2.79 | 2.80 | 2.81 | 2.75 | 2.76 |
| Liquid phase viscosity log η_{L} (dPa · s) | 3.3 | 3.2 | 3.2 | 3.2 | 2.9 | 3.0 | 3.0 | 3.1 | 3.1 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | ◯ | x | x | ◯ | x | x | x | x | x |
| Manufacturability determination | ⊚ | ⊚ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 520 | 521 | 522 | 523 | 524 | 525 | 526 | 527 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.5 | 0.5 | 0.5 | 0.5 | 0.5 | 0.5 | 0.5 | 0.5 |
| SrO | 0.2 | 0.2 | 0.2 | 0.2 | 0.2 | 0.2 | 0.2 | 0.4 |
| BaO | 0.2 | 0.2 | 0.2 | 0.2 | 0.2 | 0.2 | 0.2 | 0.5 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1.5 | 1.5 | 1.5 | 1.5 | 1.5 | 1.5 | 1.5 | 0.5 |
| TiO₂ | 0.5 | 1 | 1 | 1 | 1.5 | 1.5 | 1.5 | 0.5 |
| Y₂O₃ | 2 | | | 1.5 | | | 1 | 1 |
| Gd₂O₃ | | | 1.5 | | | 1 | | |
| La₂O₃ | | 1.5 | | | 1 | | | 1.5 |
| WO₃ | | | | | | | | |
| Ta₂O₅ | | | | | | | | |
| Al₂O₃ + rare earth oxide | 16 | 15.5 | 15.5 | 15.5 | 15 | 15 | 15 | 16.5 |
| Y₂O₃ + Gd₂O₃ + La₂O₃ + Nd₂O₃ + Ta₂O₅ + Nb₂O₅ | 2 | 1.5 | 1.5 | 1.5 | 1 | 1 | 1 | 2.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.96 | 0.96 | 0.96 | 0.96 | 0.96 | 0.96 | 0.96 | 0.93 |
| N | 8 | 8 | 8 | 8 | 8 | 8 | 8 | 10 |
| Young's modulus E (GPa) | 99 | 98 | 98 | 98 | 98 | 98 | 98 | 98 |
| Thermal expansion coefficient α(ppm/° C.) | 3.83 | 3.90 | 3.96 | 3.79 | 3.82 | 3.86 | 3.75 | 4.00 |
| Liquid phase temperature T_{L} (° C.) | 1224 | 1236 | 1231 | 1224 | 1230 | 1225 | 1225 | 1262 |
| 13.1 · E+9 − T_{L} | 80 | 62 | 67 | 74 | 64 | 68 | 69 | 26 |
| 1923 − 156 · α − T_{L} | 102 | 78 | 75 | 108 | 97 | 96 | 114 | 36 |
| Young's modulus parameter Y | 0.98 | 0.97 | 0.97 | 0.97 | 0.96 | 0.96 | 0.96 | 0.97 |
| Liquid phase parameter L | 9.8 | 9.8 | 9.8 | 9.9 | 9.9 | 9.9 | 10.0 | 9.6 |
| Thermal expansion parameter C | 0.77 | 0.77 | 0.77 | 0.76 | 0.76 | 0.76 | 0.75 | 0.80 |
| Glass transition point (° C.) | 744 | 737 | 729 | 737 | 734 | 728 | 734 | 737 |
| Density (g/cm³) | 2.72 | 2.75 | 2.76 | 2.69 | 2.70 | 2.71 | 2.66 | 2.80 |
| Liquid phase viscosity log η_{L} (dPa · s) | 3.2 | 3.1 | 3.2 | 3.2 | 3.2 | 3.2 | 3.2 | 2.9 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | ◯ | x | x | ◯ | ◯ | x | ◯ | x |
| Manufacturability determination | ⊚ | ⊚ | ⊚ | ⊚ | ⊚ | ⊚ | ⊚ | ◯ |

TABLE 32

| | Example | Example | Example | Example | Example | Example | Example | Example | Example |
|---|---|---|---|---|---|---|---|---|---|
| (mol %) | 528 | 529 | 530 | 531 | 532 | 533 | 534 | 535 | 536 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.5 | 0.5 | 0.5 | 0.5 | 0.5 | 0.5 | 0.5 | 0.5 | 0.5 |
| SrO | 0.4 | 0.4 | 0.4 | 0.4 | 0.4 | 0.4 | 0.4 | 0.4 | 0.4 |
| BaO | 0.5 | 0.5 | 0.5 | 0.5 | 0.5 | 0.5 | 0.5 | 0.5 | 0.5 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 0.5 | 0.5 | 0.5 | 0.5 | 0.5 | 0.5 | 0.5 | 0.5 | 0.5 |
| TiO₂ | 0.5 | 0.5 | 0.5 | 0.5 | 1 | 1 | 1 | 1 | 1 |
| Y₂O₃ | 1 | 1.5 | 1.5 | 2.5 | | | 1 | 1 | 2 |
| Gd₂O₃ | 1.5 | | 1 | | 1 | 2 | | 1 | |
| La₂O₃ | | 1 | | | 1 | | 1 | | |
| WO₃ | | | | | | | | | |
| Ta₂O₅ | | | | | | | | | |
| Al₂O₃ + rare earth oxide | 16.5 | 16.5 | 16.5 | 16.5 | 16 | 16 | 16 | 16 | 16 |
| Y₂O₃ + Gd₂O₃ + La₂O₃ + Nd₂O₃ + Ta₂O₅ + Nb₂O₅ | 2.5 | 2.5 | 2.5 | 2.5 | 2 | 2 | 2 | 2 | 2 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.93 | 0.93 | 0.93 | 0.93 | 0.93 | 0.93 | 0.93 | 0.93 | 0.93 |
| N | 10 | 10 | 10 | 9 | 1C | 9 | 10 | 10 | 9 |
| Young's modulus E (GPa) | 98 | 98 | 98 | 98 | 97 | 97 | 97 | 97 | 97 |
| Thermal expansion coefficient α(ppm/° C.) | 4.06 | 3.97 | 4.00 | 3.89 | 4.04 | 4.07 | 3.92 | 3.96 | 3.85 |
| Liquid phase temperature T_{L} (° C.) | 1260 | 1258 | 1257 | 1241 | 1279 | 1279 | 1252 | 1249 | 1227 |
| 13.1 · E+9 − T_{L} | 28 | 30 | 31 | 48 | 4 | 4 | 32 | 34 | 57 |
| 1923 − 156 · α − T_{L} | 30 | 46 | 42 | 75 | 15 | 9 | 59 | 56 | 96 |
| Young's modulus parameter Y | 0.97 | 0.97 | 0.97 | 0.97 | 0.96 | 0.96 | 0.96 | 0.96 | 0.96 |
| Liquid phase parameter L | 9.6 | 9.6 | 9.6 | 9.7 | 9.6 | 9.6 | 9.7 | 9.7 | 9.9 |
| Thermal expansion parameter C | 0.80 | 0.79 | 0.79 | 0.78 | 0.79 | 0.79 | 0.78 | 0.78 | 0.77 |
| Glass transition point (° C.) | 731 | 737 | 731 | 737 | 726 | 726 | 732 | 726 | 732 |
| Density (g/cm³) | 2.81 | 2.78 | 2.79 | 2.74 | 2.80 | 2.81 | 2.75 | 2.76 | 2.71 |
| Liquid phase viscosity log η_{L} (dPa · s) | 2.9 | 2.9 | 2.9 | 3.1 | 2.8 | 2.8 | 3.0 | 3.0 | 3.2 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | x | x | x | x | x | x |
| Manufacturability determination | ⊚ | ⊚ | ⊚ | ⊚ | ◯ | ◯ | ⊚ | ⊚ | ⊚ |

| | Example | Example | Example | Example | Example | Example | Example | Example |
|---|---|---|---|---|---|---|---|---|
| (mol %) | 537 | 538 | 539 | 540 | 541 | 542 | 543 | 544 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.5 | 0.5 | 0.5 | 0.5 | 0.5 | 0.5 | 0.5 | 0.5 |
| SrO | 0.4 | 0.4 | 0.4 | 0.4 | 0.4 | 0.4 | 0.4 | 0.4 |
| BaO | 0.5 | 0.5 | 0.5 | 0.5 | 0.5 | 0.5 | 0.5 | 0.5 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1 | 1 | 1 | 1 | 1 | 1 | 1 | 1 |
| TiO₂ | 0.5 | 0.5 | 0.5 | 0.5 | 0.5 | 0.5 | 1 | 1 |
| Y₂O₃ | | | | 1 | 1 | 2 | | |
| Gd₂O₃ | | 1 | 2 | | 1 | | | 1.5 |
| La₂O₃ | 2 | 1 | | 1 | | | 1.5 | |
| WO₃ | | | | | | | | |
| Ta₂O₅ | | | | | | | | |
| Al₂O₃ + rare earth oxide | 16 | 16 | 16 | 16 | 16 | 16 | 15.5 | 15.5 |
| Y₂O₃ + Gd₂O₃ + La₂O₃ + Nd₂O₃ + Ta₂O₅ + Nb₂O₅ | 2 | 2 | 2 | 2 | 2 | 2 | 1.5 | 1.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.93 | 0.93 | 0.93 | 0.93 | 0.93 | 0.93 | 0.93 | 0.93 |
| N | 9 | 10 | 9 | 10 | 10 | 9 | 9 | 9 |
| Young's modulus E (GPa) | 98 | 98 | 98 | 98 | 98 | 98 | 97 | 97 |
| Thermal expansion coefficient α(ppm/° C.) | 4.03 | 4.06 | 4.10 | 3.95 | 3.98 | 3.87 | 3.95 | 4.00 |
| Liquid phase temperature T_{L} (° C.) | 1250 | 1246 | 1246 | 1229 | 1225 | 1214 | 1229 | 1224 |
| 13.1 · E+9 − T_{L} | 40 | 43 | 44 | 61 | 65 | 77 | 57 | 61 |
| 1923 − 156 · α − T_{L} | 45 | 43 | 38 | 78 | 77 | 105 | 78 | 75 |
| Young's modulus parameter Y | 0.96 | 0.96 | 0.96 | 0.97 | 0.97 | 0.97 | 0.96 | 0.96 |
| Liquid phase parameter L | 9.6 | 9.6 | 9.6 | 9.7 | 9.7 | 9.8 | 9.7 | 9.7 |
| Thermal expansion parameter C | 0.79 | 0.79 | 0.79 | 0.79 | 0.79 | 0.78 | 0.78 | 0.78 |
| Glass transition point (° C.) | 737 | 731 | 731 | 737 | 731 | 737 | 731 | 725 |
| Density (g/cm³) | 2.80 | 2.81 | 2.81 | 2.76 | 2.77 | 2.72 | 2.75 | 2.76 |
| Liquid phase viscosity log η_{L} (dPa · s) | 3.0 | 3.0 | 3.0 | 3.2 | 3.2 | 3.3 | 3.2 | 3.2 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | x | x | x | x | x | x |
| Manufacturability determination | ⊚ | ⊚ | ⊚ | ⊚ | ⊚ | ⊚ | ⊚ | ⊚ |

TABLE 33

| | Example | Example | Example | Example | Example | Example | Example | Example | Example |
|---|---|---|---|---|---|---|---|---|---|
| (mol %) | 545 | 546 | 547 | 548 | 549 | 550 | 551 | 552 | 553 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.5 | 0.5 | 0.5 | 0.5 | 0.5 | 0.5 | 0.5 | 0.5 | 0.5 |
| SrO | 0.4 | 0.4 | 0.4 | 0.4 | 0.4 | 0.4 | 0.4 | 0.5 | 0.5 |
| BaO | 0.5 | 0.5 | 0.5 | 0.5 | 0.5 | 0.5 | 0.5 | 0.4 | 0.4 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1 | 1.5 | 1.5 | 1.5 | 1.5 | 1.5 | 1.5 | 0.5 | 0.5 |
| TiO₂ | 1 | 0.5 | 0.5 | 0.5 | 1 | 1 | 1 | 0.5 | 0.5 |
| Y₂O₃ | 1.5 | | | 1.5 | | | 1 | 1 | 1 |
| Gd₂O₃ | | | 1.5 | | | 1 | | | 1.5 |
| La₂O₃ | | 1.5 | | | 1 | | | 1.5 | |
| WO₃ | | | | | | | | | |
| Ta₂O₅ | | | | | | | | | |
| Al₂O₃ + rare earth oxide | 15.5 | 15.5 | 15.5 | 15.5 | 15 | 15 | 15 | 16.5 | 16.5 |
| Y₂O₃ + Gd₂O₃ + La₂O₃ + Nd₂O₃ + Ta₂O₅ + Nb₂O₅ | 1.5 | 1.5 | 1.5 | 1.5 | 1 | 1 | 1 | 2.5 | 2.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.93 | 0.93 | 0.93 | 0.93 | 0.93 | 0.93 | 0.93 | 0.93 | 0.93 |
| N | 9 | 9 | 9 | 9 | 9 | 9 | 9 | 10 | 10 |
| Young's modulus E (GPa) | 98 | 98 | 98 | 98 | 98 | 98 | 98 | 98 | 98 |
| Thermal expansion coefficient α(ppm/° C.) | 3.83 | 3.97 | 4.03 | 3.85 | 3.89 | 3.93 | 3.81 | 4.00 | 4.06 |
| Liquid phase temperature T_{L} (° C.) | 1217 | 1251 | 1247 | 1230 | 1230 | 1225 | 1217 | 1263 | 1261 |
| 13.1 · E+9 − T_{L} | 69 | 41 | 45 | 63 | 58 | 62 | 71 | 25 | 27 |
| 1923 − 156 · α − T_{L} | 109 | 52 | 49 | 92 | 86 | 85 | 111 | 35 | 29 |
| Young's modulus parameter Y | 0.96 | 0.96 | 0.96 | 0.97 | 0.96 | 0.96 | 0.96 | 0.97 | 0.97 |
| Liquid phase parameter L | 9.9 | 9.7 | 9.7 | 9.8 | 9.9 | 9.9 | 10.0 | 9.6 | 9.6 |
| Thermal expansion parameter C | 0.77 | 0.78 | 0.78 | 0.77 | 0.77 | 0.77 | 0.76 | 0.80 | 0.80 |
| Glass transition point (° C.) | 731 | 737 | 731 | 737 | 732 | 725 | 732 | 737 | 731 |
| Density (g/cm³) | 2.69 | 2.76 | 2.77 | 2.70 | 2.71 | 2.72 | 2.67 | 2.80 | 2.81 |
| Liquid phase viscosity log η_{L} (dPa · s) | 3.3 | 3.0 | 3.0 | 3.2 | 3.2 | 3.2 | 3.3 | 2.9 | 2.9 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | ◯ | x | x | x | x | x | ◯ | x | x |
| Manufacturability determination | ⊚ | ⊚ | ⊚ | ⊚ | ⊚ | ⊚ | ◯ | ◯ | ⊚ |

| | Example | Example | Example | Example | Example | Example | Example | Example |
|---|---|---|---|---|---|---|---|---|
| (mol %) | 554 | 555 | 556 | 557 | 558 | 559 | 560 | 561 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.5 | 0.5 | 0.5 | 0.5 | 0.5 | 0.5 | 0.5 | 0.5 |
| SrO | 0.5 | 0.5 | 0.5 | 0.5 | 0.5 | 0.5 | 0.5 | 0.5 |
| BaO | 0.4 | 0.4 | 0.4 | 0.4 | 0.4 | 0.4 | 0.4 | 0.4 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 0.5 | 0.5 | 0.5 | 0.5 | 0.5 | 0.5 | 0.5 | 0.5 |
| TiO₂ | 0.5 | 0.5 | 0.5 | 1 | 1 | 1 | 1 | 1 |
| Y₂O₃ | 1.5 | 1.5 | 2.5 | | | 1 | 1 | 2 |
| Gd₂O₃ | | 1 | | 1 | 2 | | 1 | |
| La₂O₃ | 1 | | | 1 | | 1 | | |
| WO₃ | | | | | | | | |
| Ta₂O₅ | | | | | | | | |
| Al₂O₃ + rare earth oxide | 16.5 | 16.5 | 16.5 | 16 | 16 | 16 | 16 | 16 |
| Y₂O₃ + Gd₂O₃ + La₂O₃ + Nd₂O₃ + Ta₂O₅ + Nb₂O₅ | 2.5 | 2.5 | 2.5 | 2 | 2 | 2 | 2 | 2 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.93 | 0.93 | 0.93 | 0.93 | 0.93 | 0.93 | 0.93 | 0.93 |
| N | 10 | 10 | 9 | 10 | 9 | 10 | 10 | 9 |
| Young's modulus E (GPa) | 98 | 98 | 98 | 97 | 97 | 97 | 97 | 97 |
| Thermal expansion coefficient α(ppm/° C.) | 3.97 | 4.00 | 3.89 | 4.04 | 4.07 | 3.92 | 3.96 | 3.85 |
| Liquid phase temperature T_{L} (° C.) | 1259 | 1258 | 1241 | 1279 | 1279 | 1253 | 1250 | 1228 |
| 13.1 · E+9 − T_{L} | 30 | 30 | 48 | 4 | 4 | 32 | 34 | 57 |
| 1923 − 156 · α − T_{L} | 45 | 41 | 75 | 14 | 9 | 58 | 56 | 96 |
| Young's modulus parameter Y | 0.97 | 0.97 | 0.97 | 0.96 | 0.96 | 0.96 | 0.96 | 0.96 |
| Liquid phase parameter L | 9.6 | 9.6 | 9.7 | 9.6 | 9.6 | 9.7 | 9.7 | 9.8 |
| Thermal expansion parameter C | 0.79 | 0.79 | 0.78 | 0.79 | 0.79 | 0.78 | 0.78 | 0.77 |
| Glass transition point (° C.) | 737 | 731 | 737 | 725 | 726 | 732 | 725 | 732 |
| Density (g/cm³) | 2.78 | 2.79 | 2.74 | 2.80 | 2.80 | 2.75 | 2.76 | 2.71 |
| Liquid phase viscosity log η_{L} (dPa · s) | 2.9 | 2.9 | 3.1 | 2.8 | 2.8 | 3.0 | 3.0 | 3.2 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | x | x | x | x | x | x |
| Manufacturability determination | ⊚ | ⊚ | ⊚ | ◯ | ◯ | ⊚ | ⊚ | ⊚ |

TABLE 34

| | Example | Example | Example | Example | Example | Example | Example | Example | Example |
|---|---|---|---|---|---|---|---|---|---|
| (mol %) | 562 | 563 | 564 | 565 | 566 | 567 | 568 | 569 | 570 |
| SiO₂ | 52.1 | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 | 14 |
| B₂O₃ | 9 | 9 | 9 | 9 | 9 | 9 | 9 | 9 | 9 |
| MgO | 20 | 20 | 20 | 20 | 20 | 20 | 20 | 20 | 20 |
| CaO | 0.5 | 0.5 | 0.5 | 0.5 | 0.5 | 0.5 | 0.5 | 0.5 | 0.5 |
| SrO | 0.5 | 0.5 | 0.5 | 0.5 | 0.5 | 0.5 | 0.5 | 0.5 | 0.5 |
| BaO | 0.4 | 0.4 | 0.4 | 0.4 | 0.4 | 0.4 | 0.4 | 0.4 | 0.4 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 0.5 | 0.5 | 0.5 | 1 | 1 | 1 | 1 | 1 | 1 |
| TiO₂ | 1.5 | 1.5 | 1.5 | 0.5 | 0.5 | 0.5 | 0.5 | 0.5 | 0.5 |
| Y₂O₃ | | | 1.5 | | | | 1 | 1 | 2 |
| Gd₂O₃ | | 1.5 | | | 1 | 2 | | 1 | |
| La₂O₃ | 1.5 | | | 2 | 1 | | 1 | | |
| WO₃ | | | | | | | | | |
| Ta₂O₅ | | | | | | | | | |
| Al₂O₃ + rare earth oxide | 15.5 | 15.5 | 15.5 | 16 | 16 | 16 | 16 | 16 | 16 |
| Y₂O₃ + Gd₂O₃ + La₂O₃ + Nd₂O₃ + Ta₂O₅ + Nb₂O₅ | 1.5 | 1.5 | 1.5 | 2 | 2 | 2 | 2 | 2 | 2 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 | 0.36 |
| MgO/ΣRO | 0.93 | 0.93 | 0.93 | 0.93 | 0.93 | 0.93 | 0.93 | 0.93 | 0.93 |
| N | 9 | 9 | 9 | 9 | 10 | 9 | 10 | 10 | 9 |
| Young's modulus E (GPa) | 97 | 97 | 97 | 98 | 98 | 98 | 98 | 98 | 98 |
| Thermal expansion coefficient α(ppm/° C.) | 3.92 | 3.97 | 3.80 | 4.03 | 4.06 | 4.10 | 3.95 | 3.98 | 3.87 |
| Liquid phase temperature T_{L} (° C.) | 1277 | 1274 | 1246 | 1251 | 1247 | 1246 | 1230 | 1226 | 1214 |
| 13.1 · E+9 − T_{L} | 3 | 5 | 35 | 40 | 43 | 44 | 61 | 65 | 77 |
| 1923 − 156 · α − T_{L} | 35 | 29 | 84 | 44 | 42 | 37 | 77 | 76 | 105 |
| Young's modulus parameter Y | 0.95 | 0.95 | 0.95 | 0.96 | 0.96 | 0.96 | 0.97 | 0.97 | 0.97 |
| Liquid phase parameter L | 9.8 | 9.8 | 9.9 | 9.6 | 9.6 | 9.6 | 9.7 | 9.7 | 9.8 |
| Thermal expansion parameter C | 0.78 | 0.78 | 0.76 | 0.79 | 0.79 | 0.79 | 0.79 | 0.79 | 0.78 |
| Glass transition point (° C.) | 730 | 725 | 730 | 737 | 731 | 731 | 737 | 731 | 737 |
| Density (g/cm³) | 2.74 | 2.75 | 2.68 | 2.80 | 2.80 | 2.81 | 2.76 | 2.77 | 2.72 |
| Liquid phase viscosity log η_{L} (dPa · s) | 2.8 | 2.8 | 3.0 | 3.0 | 3.0 | 3.0 | 3.2 | 3.2 | 3.3 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | ◯ | x | x | x | x | x | x |
| Manufacturability determination | ◯ | ◯ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 571 | 572 | 573 | 574 | 575 | 576 | 577 | 578 |
| SiO₂ | 52.1 | 52.1 | 52.1 | 52.1 | 52.1 | 52.1 | 52.1 | 52.1 |
| Al₂O₃ | 14 | 14 | 14 | 14 | 14 | 14 | 14 | 14 |
| B₂O₃ | 9 | 9 | 9 | 9 | 9 | 9 | 9 | 9 |
| MgO | 20 | 20 | 20 | 20 | 20 | 20 | 20 | 20 |
| CaO | 0.5 | 0.5 | 0.5 | 0.5 | 0.5 | 0.5 | 0.5 | 0.5 |
| SrO | 0.5 | 0.5 | 0.5 | 0.5 | 0.5 | 0.5 | 0.5 | 0.5 |
| BaO | 0.4 | 0.4 | 0.4 | 0.4 | 0.4 | 0.4 | 0.4 | 0.4 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1 | 1 | 1 | 1 | 1 | 1 | 1.5 | 1.5 |
| TiO₂ | 1 | 1 | 1 | 1.5 | 1.5 | 1.5 | 0.5 | 0.5 |
| Y₂O₃ | | | 1.5 | | | 1 | | |
| Gd₂O₃ | | 1.5 | | | 1 | | | 1.5 |
| La₂O₃ | 1.5 | | | 1 | | | 1.5 | |
| WO₃ | | | | | | | | |
| Ta₂O₅ | | | | | | | | |
| Al₂O₃ + rare earth oxide | 15.5 | 15.5 | 15.5 | 15 | 15 | 15 | 15.5 | 15.5 |
| Y₂O₃ + Gd₂O₃ + La₂O₃ + Nd₂O₃ + Ta₂O₅ + Nb₂O₅ | 1.5 | 1.5 | 1.5 | 1 | 1 | 1 | 1.5 | 1.5 |
| (Al₂O₃ + MgO)/(SiO₂ + Al₂O₃ + B₂O₃ + MgO) | 0.36 | 0.36 | 0.36 | 0.36 | 0.36 | 0.36 | 0.36 | 0.36 |
| MgO/ΣRO | 0.93 | 0.93 | 0.93 | 0.93 | 0.93 | 0.93 | 0.93 | 0.93 |
| N | 9 | 9 | 9 | 9 | 9 | 9 | 9 | 9 |
| Young's modulus E (GPa) | 97 | 97 | 98 | 97 | 97 | 97 | 98 | 98 |
| Thermal expansion coefficient α(ppm/° C.) | 3.95 | 4.00 | 3.83 | 3.87 | 3.90 | 3.79 | 3.97 | 4.02 |
| Liquid phase temperature T_{L} (° C.) | 1230 | 1225 | 1218 | 1222 | 1218 | 1217 | 1252 | 1247 |
| 13.1 · E+9 − T_{L} | 56 | 61 | 69 | 60 | 64 | 66 | 41 | 45 |
| 1923 − 156 · α − T_{L} | 78 | 74 | 108 | 98 | 97 | 115 | 52 | 48 |
| Young's modulus parameter Y | 0.96 | 0.96 | 0.96 | 0.95 | 0.95 | 0.95 | 0.97 | 0.96 |
| Liquid phase parameter L | 9.7 | 9.7 | 9.9 | 9.9 | 9.9 | 10.0 | 9.7 | 9.7 |
| Thermal expansion parameter C | 0.78 | 0.78 | 0.77 | 0.76 | 0.76 | 0.76 | 0.78 | 0.78 |
| Glass transition point (° C.) | 731 | 725 | 731 | 729 | 724 | 729 | 738 | 732 |
| Density (g/cm³) | 2.75 | 2.76 | 2.69 | 2.70 | 2.71 | 2.66 | 2.76 | 2.77 |
| Liquid phase viscosity log η_{L} (dPa · s) | 3.2 | 3.2 | 3.3 | 3.2 | 3.3 | 3.3 | 3.0 | 3.0 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | ◯ | x | x | ◯ | x | x |
| Manufacturability determination | ⊚ | ⊚ | ⊚ | ⊚ | ⊚ | ⊚ | ⊚ | ⊚ |

TABLE 35

| | Example | Example | Example | Example | Example | Example | Example | Example | Example |
|---|---|---|---|---|---|---|---|---|---|
| (mol %) | 579 | 580 | 581 | 582 | 583 | 584 | 585 | 586 | 587 |
| SiO₂ | 52.1 | 52.1 | 52.1 | 52.1 | 52.6 | 52.6 | 52.6 | 52.6 | 52.6 |
| Al₂O₃ | 14 | 14 | 14 | 14 | 11.5 | 11.5 | 11.5 | 11.5 | 12 |
| B₂O₃ | 9 | 9 | 9 | 9 | 7 | 7.5 | 8 | 8.5 | 7 |
| MgO | 20 | 20 | 20 | 20 | 24 | 23.5 | 23 | 22.5 | 23.5 |
| CaO | 0.5 | 0.5 | 0.5 | 0.5 | 0.3 | 0.3 | 0.3 | 0.3 | 0.3 |
| SrO | 0.5 | 0.5 | 0.5 | 0.5 | 0.3 | 0.3 | 0.3 | 0.3 | 0.3 |
| BaO | 0.4 | 0.4 | 0.4 | 0.4 | 0.3 | 0.3 | 0.3 | 0.3 | 0.3 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1.5 | 1.5 | 1.5 | 1.5 | 1 | 1 | 1 | 1 | 1 |
| TiO₂ | 0.5 | 1 | 1 | 1 | 1 | 1 | 1 | 1 | 1 |
| Y₂O₃ | 1.5 | | | 1 | 2 | 2 | 2 | 2 | 2 |
| Gd₂O₃ | | | 1 | | | | | | |
| La₂O₃ | | 1 | | | | | | | |
| WO₃ | | | | | | | | | |
| Ta₂O₅ | | | | | | | | | |
| Al₂O₃ + rare earth oxide | 15.5 | 15 | 15 | 15 | 13.5 | 13.5 | 13.5 | 13.5 | 14 |
| Y₂O₃ + Gd₂O₃ + La₂O₃ + Nd₂O₃ + Ta₂O₅ + Nb₂O₅ | 1.5 | 1 | 1 | 1 | 2 | 2 | 2 | 2 | 2 |
| (Al₂O₃ + MgO)/(SiO₂ + Al₂O₃ + B₂O₃ + MgO) | 0.36 | 0.36 | 0.36 | 0.36 | 0.37 | 0.37 | 0.36 | 0.36 | 0.37 |
| MgO/ΣRO | 0.93 | 0.93 | 0.93 | 0.93 | 0.96 | 0.96 | 0.96 | 0.96 | 0.96 |
| N | 9 | 9 | 9 | 9 | 7 | 7 | 7 | 7 | 7 |
| Young's modulus E (GPa) | 98 | 98 | 98 | 98 | 99 | 99 | 98 | 98 | 99 |
| Thermal expansion coefficient α(ppm/° C.) | 3.85 | 3.89 | 3.93 | 3.81 | 4.09 | 4.07 | 4.04 | 4.01 | 4.05 |
| Liquid phase temperature T_{L} (° C.) | 1230 | 1230 | 1226 | 1218 | 1200 | 1202 | 1200 | 1199 | 1200 |
| 13.1 · E+9 − T_{L} | 63 | 58 | 62 | 71 | 111 | 103 | 98 | 93 | 112 |
| 1923 − 156 · α − T_{L} | 91 | 86 | 84 | 110 | 85 | 87 | 93 | 98 | 91 |
| Young's modulus parameter Y | 0.97 | 0.96 | 0.96 | 0.96 | 0.99 | 0.99 | 0.98 | 0.97 | 0.99 |
| Liquid phase parameter L | 9.8 | 9.8 | 9.8 | 9.9 | 9.6 | 9.6 | 9.6 | 9.5 | 9.7 |
| Thermal expansion parameter C | 0.77 | 0.77 | 0.77 | 0.76 | 0.82 | 0.82 | 0.81 | 0.81 | 0.81 |
| Glass transition point (° C.) | 738 | 732 | 725 | 732 | 728 | 727 | 727 | 727 | 728 |
| Density (g/cm³) | 2.70 | 2.71 | 2.72 | 2.67 | 2.73 | 2.72 | 2.72 | 2.71 | 2.73 |
| Liquid phase viscosity log η_{L} (dPa · s) | 3.2 | 3.2 | 3.2 | 3.3 | 3.4 | 3.4 | 3.4 | 3.4 | 3.4 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | ◯ | X | x | x | x | x |
| Manufacturability determination | ⊚ | ⊚ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 588 | 589 | 590 | 591 | 592 | 593 | 594 | 595 |
| SiO₂ | 52.6 | 52.6 | 52.6 | 52.6 | 52.6 | 52.6 | 52.6 | 52.6 |
| Al₂O₃ | 12 | 12 | 12 | 12.5 | 12.5 | 12.5 | 12.5 | 13 |
| B₂O₃ | 7.5 | 8 | 8.5 | 7 | 7.5 | 8 | 8.5 | 7 |
| MgO | 23 | 22.5 | 22 | 23 | 22.5 | 22 | 21.5 | 22.5 |
| CaO | 0.3 | 0.3 | 0.3 | 0.3 | 0.3 | 0.3 | 0.3 | 0.3 |
| SrO | 0.3 | 0.3 | 0.3 | 0.3 | 0.3 | 0.3 | 0.3 | 0.3 |
| BaO | 0.3 | 0.3 | 0.3 | 0.3 | 0.3 | 0.3 | 0.3 | 0.3 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1 | 1 | 1 | 1 | 1 | 1 | 1 | 1 |
| TiO₂ | 1 | 1 | 1 | 1 | 1 | 1 | 1 | 1 |
| Y₂O₃ | 2 | 2 | 2 | 2 | 2 | 2 | 2 | 2 |
| Gd₂O₃ | | | | | | | | |
| La₂O₃ | | | | | | | | |
| WO₃ | | | | | | | | |
| Ta₂O₅ | | | | | | | | |
| Al₂O₃ + rare earth oxide | 14 | 14 | 14 | 14.5 | 14.5 | 14.5 | 14.5 | 15 |
| Y₂O₃ + Gd₂O₃ + La₂O₃ + Nd₂O₃ + Ta₂O₅ + Nb₂O₅ | 2 | 2 | 2 | 2 | 2 | 2 | 2 | 2 |
| (Al₂O₃ + MgO)/(SiO₂ + Al₂O₃ + B₂O₃ + MgO) | 0.37 | 0.36 | 0.36 | 0.37 | 0.37 | 0.36 | 0.36 | 0.37 |
| MgO/ΣRO | 0.96 | 0.96 | 0.96 | 0.96 | 0.96 | 0.96 | 0.96 | 0.96 |
| N | 7 | 7 | 7 | 7 | 7 | 7 | 7 | 7 |
| Young's modulus E (GPa) | 99 | 98 | 98 | 100 | 99 | 99 | 98 | 100 |
| Thermal expansion coefficient α(ppm/° C.) | 4.02 | 4.00 | 3.97 | 4.01 | 3.98 | 3.96 | 3.93 | 3.97 |
| Liquid phase temperature T_{L} (° C.) | 1202 | 1200 | 1199 | 1203 | 1205 | 1202 | 1204 | 1204 |
| 13.1 · E+9 − T_{L} | 104 | 100 | 94 | 110 | 101 | 98 | 90 | 110 |
| 1923 − 156 · α − T_{L} | 93 | 100 | 104 | 95 | 96 | 104 | 106 | 100 |
| Young's modulus parameter Y | 0.99 | 0.98 | 0.97 | 0.99 | 0.99 | 0.98 | 0.97 | 0.99 |
| Liquid phase parameter L | 9.7 | 9.6 | 9.6 | 9.8 | 9.8 | 9.7 | 9.7 | 9.9 |
| Thermal expansion parameter C | 0.81 | 0.80 | 0.80 | 0.80 | 0.80 | 0.79 | 0.79 | 0.80 |
| Glass transition point (° C.) | 727 | 727 | 727 | 729 | 729 | 729 | 729 | 730 |
| Density (g/cm³) | 2.72 | 2.72 | 2.71 | 2.73 | 2.72 | 2.72 | 2.71 | 2.73 |
| Liquid phase viscosity log η_{L} (dPa · s) | 3.4 | 3.4 | 3.4 | 3.4 | 3.4 | 3.4 | 3.4 | 3.4 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | x | x | x | x | x | x |
| Manufacturability determination | ⊚ | ⊚ | ⊚ | ⊚ | ⊚ | ⊚ | ⊚ | ⊚ |

TABLE 36

| | Example | Example | Example | Example | Example | Example | Example | Example | Example |
|---|---|---|---|---|---|---|---|---|---|
| (mol %) | 596 | 597 | 598 | 599 | 600 | 601 | 602 | 603 | 604 |
| SiO₂ | 52.6 | 52.6 | 52.6 | 52.6 | 52.6 | 52.6 | 52.6 | 53.1 | 53.1 |
| Al₂O₃ | 13 | 13 | 13 | 13.5 | 13.5 | 13.5 | 13.5 | 11.5 | 11.5 |
| B₂O₃ | 7.5 | 8 | 8.5 | 7 | 7.5 | 8 | 8.5 | 7 | 7.5 |
| MgO | 22 | 21.5 | 21 | 22 | 21.5 | 21 | 20.5 | 23.5 | 23 |
| CaO | 0.3 | 0.3 | 0.3 | 0.3 | 0.3 | 0.3 | 0.3 | 0.3 | 0.3 |
| SrO | 0.3 | 0.3 | 0.3 | 0.3 | 0.3 | 0.3 | 0.3 | 0.3 | 0.3 |
| BaO | 0.3 | 0.3 | 0.3 | 0.3 | 0.3 | 0.3 | 0.3 | 0.3 | 0.3 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1 | 1 | 1 | 1 | 1 | 1 | 1 | 1 | 1 |
| TiO₂ | 1 | 1 | 1 | 1 | 1 | 1 | 1 | 1 | 1 |
| Y₂O₃ | 2 | 2 | 2 | 2 | 2 | 2 | 2 | 2 | 2 |
| Gd₂O₃ | | | | | | | | | |
| La₂O₃ | | | | | | | | | |
| WO₃ | | | | | | | | | |
| Ta₂O₅ | | | | | | | | | |
| Al₂O₃ + rare earth oxide | 15 | 15 | 15 | 15.5 | 15.5 | 15.5 | 15.5 | 13.5 | 13.5 |
| Y₂O₃ + Gd₂O₃ + La₂O₃ + Nd₂O₃ + Ta₂O₅ + Nb₂O₅ | 2 | 2 | 2 | 2 | 2 | 2 | 2 | 2 | 2 |
| (Al₂O₃ + MgO)/(SiO₂ + Al₂O₃ + B₂O₃ + MgO) | 0.37 | 0.36 | 0.36 | 0.37 | 0.37 | 0.36 | 0.36 | 0.37 | 0.36 |
| MgO/ΣRO | 0.96 | 0.96 | 0.96 | 0.96 | 0.96 | 0.96 | 0.96 | 0.96 | 0.96 |
| N | 7 | 7 | 7 | 7 | 7 | 7 | 7 | 7 | 7 |
| Young's modulus E (GPa) | 99 | 99 | 98 | 100 | 99 | 99 | 98 | 99 | 99 |
| Thermal expansion coefficient α(ppm/° C.) | 3.94 | 3.91 | 3.89 | 3.92 | 3.90 | 3.87 | 3.85 | 4.06 | 4.03 |
| Liquid phase temperature T_{L} (° C.) | 1206 | 1204 | 1203 | 1205 | 1207 | 1203 | 1201 | 1201 | 1203 |
| 13.1 · E+9 − T_{L} | 102 | 97 | 92 | 110 | 102 | 100 | 96 | 105 | 97 |
| 1923 − 156 · α − T_{L} | 103 | 108 | 113 | 106 | 108 | 116 | 122 | 89 | 91 |
| Young's modulus parameter Y | 0.99 | 0.98 | 0.97 | 0.99 | 0.99 | 0.98 | 0.97 | 0.99 | 0.98 |
| Liquid phase parameter L | 9.8 | 9.8 | 9.8 | 10.0 | 9.9 | 9.9 | 9.9 | 9.7 | 9.6 |
| Thermal expansion parameter C | 0.79 | 0.79 | 0.78 | 0.79 | 0.78 | 0.78 | 0.77 | 0.81 | 0.81 |
| Glass transition point (° C.) | 730 | 730 | 730 | 732 | 732 | 732 | 732 | 729 | 728 |
| Density (g/cm³) | 2.72 | 2.72 | 2.71 | 2.73 | 2.72 | 2.72 | 2.71 | 2.72 | 2.72 |
| Liquid phase viscosity log η_{L} (dPa · s) | 3.4 | 3.4 | 3.4 | 3.4 | 3.4 | 3.4 | 3.4 | 3.4 | 3.4 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | x | x | x | x | x | x |
| Manufacturability determination | ⊚ | ⊚ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 605 | 606 | 607 | 608 | 609 | 610 | 611 | 612 |
| SiO₂ | 53.1 | 53.1 | 53.1 | 53.1 | 53.1 | 53.1 | 53.1 | 53.1 |
| Al₂O₃ | 11.5 | 11.5 | 12 | 12 | 12 | 12 | 12.5 | 12.5 |
| B₂O₃ | 8 | 8.5 | 7 | 7.5 | 8 | 8.5 | 7 | 7.5 |
| MgO | 22.5 | 22 | 23 | 22.5 | 22 | 21.5 | 22.5 | 22 |
| CaO | 0.3 | 0.3 | 0.3 | 0.3 | 0.3 | 0.3 | 0.3 | 0.3 |
| SrO | 0.3 | 0.3 | 0.3 | 0.3 | 0.3 | 0.3 | 0.3 | 0.3 |
| BaO | 0.3 | 0.3 | 0.3 | 0.3 | 0.3 | 0.3 | 0.3 | 0.3 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1 | 1 | 1 | 1 | 1 | 1 | 1 | 1 |
| TiO₂ | 1 | 1 | 1 | 1 | 1 | 1 | 1 | 1 |
| Y₂O₃ | 2 | 2 | 2 | 2 | 2 | 2 | 2 | 2 |
| Gd₂O₃ | | | | | | | | |
| La₂O₃ | | | | | | | | |
| WO₃ | | | | | | | | |
| Ta₂O₅ | | | | | | | | |
| Al₂O₃ + rare earth oxide | 13.5 | 13.5 | 14 | 14 | 14 | 14 | 14.5 | 14.5 |
| Y₂O₃ + Gd₂O₃ + La₂O₃ + Nd₂O₃ + Ta₂O₅ + Nb₂O₅ | 2 | 2 | 2 | 2 | 2 | 2 | 2 | 2 |
| (Al₂O₃ + MgO)/(SiO₂ + Al₂O₃ + B₂O₃ + MgO) | 0.36 | 0.35 | 0.37 | 0.36 | 0.36 | 0.35 | 0.37 | 0.36 |
| MgO/ΣRO | 0.96 | 0.96 | 0.96 | 0.96 | 0.96 | 0.96 | 0.96 | 0.96 |
| N | 7 | 7 | 7 | 7 | 7 | 7 | 7 | 7 |
| Young's modulus E (GPa) | 98 | 98 | 99 | 99 | 98 | 98 | 99 | 99 |
| Thermal expansion coefficient α(ppm/° C.) | 4.01 | 3.98 | 4.02 | 3.99 | 3.96 | 3.94 | 3.97 | 3.95 |
| Liquid phase temperature T_{L} (° C.) | 1201 | 1200 | 1201 | 1203 | 1200 | 1201 | 1203 | 1205 |
| 13.1 · E+9 − T_{L} | 93 | 87 | 106 | 98 | 94 | 88 | 105 | 97 |
| 1923 − 156 · α − T_{L} | 97 | 102 | 96 | 98 | 104 | 108 | 100 | 102 |
| Young's modulus parameter Y | 0.97 | 0.97 | 0.99 | 0.98 | 0.98 | 0.97 | 0.99 | 0.98 |
| Liquid phase parameter L | 9.6 | 9.6 | 9.8 | 9.7 | 9.7 | 9.7 | 9.8 | 9.8 |
| Thermal expansion parameter C | 0.80 | 0.80 | 0.81 | 0.80 | 0.80 | 0.79 | 0.80 | 0.79 |
| Glass transition point (° C.) | 728 | 728 | 729 | 728 | 728 | 728 | 730 | 730 |
| Density (g/cm³) | 2.71 | 2.71 | 2.72 | 2.72 | 2.71 | 2.71 | 2.72 | 2.72 |
| Liquid phase viscosity log η_{L} (dPa · s) | 3.4 | 3.4 | 3.4 | 3.4 | 3.4 | 3.4 | 3.4 | 3.4 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | x | x | x | x | x | x | x | x |
| Manufacturability determination | ⊚ | ⊚ | ⊚ | ⊚ | ⊚ | ⊚ | ⊚ | ⊚ |

TABLE 37

| | Example | Example | Example | Example | Example | Example | Example | Example | Example |
|---|---|---|---|---|---|---|---|---|---|
| (mol %) | 613 | 614 | 615 | 616 | 617 | 618 | 619 | 620 | 621 |
| SiO₂ | 53.1 | 53.1 | 53.1 | 53.1 | 53.1 | 53.1 | 53.1 | 53.1 | 53.1 |
| Al₂O₃ | 12.5 | 12.5 | 13 | 13 | 13 | 13 | 13.5 | 13.5 | 13.5 |
| B₂O₃ | 8 | 8.5 | 7 | 7.5 | 8 | 8.5 | 7 | 7.5 | 8 |
| MgO | 21.5 | 21 | 22 | 21.5 | 21 | 20.5 | 21.5 | 21 | 20.5 |
| CaO | 0.3 | 0.3 | 0.3 | 0.3 | 0.3 | 0.3 | 0.3 | 0.3 | 0.3 |
| SrO | 0.3 | 0.3 | 0.3 | 0.3 | 0.3 | 0.3 | 0.3 | 0.3 | 0.3 |
| BaO | 0.3 | 0.3 | 0.3 | 0.3 | 0.3 | 0.3 | 0.3 | 0.3 | 0.3 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1 | 1 | 1 | 1 | 1 | 1 | 1 | 1 | 1 |
| TiO₂ | 1 | 1 | 1 | 1 | 1 | 1 | 1 | 1 | 1 |
| Y₂O₃ | 2 | 2 | 2 | 2 | 2 | 2 | 2 | 2 | 2 |
| Gd₂O₃ | | | | | | | | | |
| La₂O₃ | | | | | | | | | |
| WO₃ | | | | | | | | | |
| Ta₂O₅ | | | | | | | | | |
| Al₂O₃ + rare earth oxide | 14.5 | 14.5 | 15 | 15 | 15 | 15 | 15.5 | 15.5 | 15.5 |
| Y₂O₃ + Gd₂O₃ + La₂O₃ + Nd₂O₃ + Ta₂O₅ + Nb₂O₅ | 2 | 2 | 2 | 2 | 2 | 2 | 2 | 2 | 2 |
| (Al₂O₃ + MgO)/(SiO₂ + Al₂O₃ + B₂O₃ + MgO) | 0.36 | 0.35 | 0.37 | 0.36 | 0.36 | 0.35 | 0.37 | 0.36 | 0.36 |
| MgO/ΣRO | 0.96 | 0.96 | 0.96 | 0.96 | 0.96 | 0.96 | 0.96 | 0.96 | 0.96 |
| N | 7 | 7 | 7 | 7 | 7 | 7 | 7 | 7 | 7 |
| Young's modulus E (GPa) | 98 | 98 | 99 | 99 | 98 | 98 | 99 | 99 | 98 |
| Thermal expansion coefficient α(ppm/° C.) | 3.92 | 3.90 | 3.93 | 3.91 | 3.88 | 3.86 | 3.89 | 3.87 | 3.84 |
| Liquid phase temperature T_{L} (° C.) | 1204 | 1202 | 1204 | 1206 | 1202 | 1200 | 1205 | 1205 | 1200 |
| 13.1 · E+9 − T_{L} | 92 | 87 | 106 | 97 | 94 | 90 | 106 | 99 | 98 |
| 1923 − 156 · α − T_{L} | 107 | 113 | 106 | 107 | 115 | 122 | 111 | 115 | 124 |
| Young's modulus parameter Y | 0.98 | 0.97 | 0.99 | 0.98 | 0.98 | 0.97 | 0.99 | 0.98 | 0.98 |
| Liquid phase parameter L | 9.8 | 9.7 | 9.9 | 9.9 | 9.9 | 9.8 | 10.0 | 10.0 | 9.9 |
| Thermal expansion parameter C | 0.79 | 0.78 | 0.79 | 0.78 | 0.78 | 0.77 | 0.78 | 0.78 | 0.77 |
| Glass transition point (° C.) | 730 | 730 | 731 | 731 | 731 | 731 | 733 | 733 | 733 |
| Density (g/cm³) | 2.71 | 2.71 | 2.72 | 2.72 | 2.71 | 2.71 | 2.72 | 2.72 | 2.71 |
| Liquid phase viscosity log η_{L} (dPa · s) | 3.4 | 3.4 | 3.4 | 3.4 | 3.4 | 3.4 | 3.4 | 3.4 | 3.4 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | x | x | x | x | x | x |
| Manufacturability determination | ⊚ | ⊚ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 622 | 623 | 624 | 625 | 626 | 627 | 628 | 629 |
| SiO₂ | 53.1 | 53.6 | 53.6 | 53.6 | 53.6 | 53.6 | 53.6 | 53.6 |
| Al₂O₃ | 13.5 | 11.5 | 11.5 | 11.5 | 11.5 | 12 | 12 | 12 |
| B₂O₃ | 8.5 | 7 | 7.5 | 8 | 8.5 | 7 | 7.5 | 8 |
| MgO | 20 | 23 | 22.5 | 22 | 21.5 | 22.5 | 22 | 21.5 |
| CaO | 0.3 | 0.3 | 0.3 | 0.3 | 0.3 | 0.3 | 0.3 | 0.3 |
| SrO | 0.3 | 0.3 | 0.3 | 0.3 | 0.3 | 0.3 | 0.3 | 0.3 |
| BaO | 0.3 | 0.3 | 0.3 | 0.3 | 0.3 | 0.3 | 0.3 | 0.3 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1 | 1 | 1 | 1 | 1 | 1 | 1 | 1 |
| TiO₂ | 1 | 1 | 1 | 1 | 1 | 1 | 1 | 1 |
| Y₂O₃ | 2 | 2 | 2 | 2 | 2 | 2 | 2 | 2 |
| Gd₂O₃ | | | | | | | | |
| La₂O₃ | | | | | | | | |
| WO₃ | | | | | | | | |
| Ta₂O₅ | | | | | | | | |
| Al₂O₃ + rare earth oxide | 15.5 | 13.5 | 13.5 | 13.5 | 13.5 | 14 | 14 | 14 |
| Y₂O₃ + Gd₂O₃ + La₂O₃ + Nd₂O₃ + Ta₂O₅ + Nb₂O₅ | 2 | 2 | 2 | 2 | 2 | 2 | 2 | 2 |
| (Al₂O₃ + MgO)/(SiO₂ + Al₂O₃ + B₂O₃ + MgO) | 0.35 | 0.36 | 0.36 | 0.35 | 0.35 | 0.36 | 0.36 | 0.35 |
| MgO/ΣRO | 0.96 | 0.96 | 0.96 | 0.96 | 0.96 | 0.96 | 0.96 | 0.96 |
| N | 7 | 7 | 7 | 7 | 7 | 7 | 7 | 7 |
| Young's modulus E (GPa) | 98 | 99 | 98 | 98 | 97 | 99 | 98 | 98 |
| Thermal expansion coefficient α(ppm/° C.) | 3.81 | 4.02 | 4.00 | 3.97 | 3.95 | 3.98 | 3.96 | 3.93 |
| Liquid phase temperature T_{L} (° C.) | 1200 | 1201 | 1203 | 1200 | 1200 | 1201 | 1202 | 1200 |
| 13.1 · E+9 − T_{L} | 92 | 101 | 92 | 88 | 82 | 102 | 94 | 90 |
| 1923 − 156 · α − T_{L} | 128 | 95 | 97 | 103 | 107 | 101 | 103 | 110 |
| Young's modulus parameter Y | 0.97 | 0.98 | 0.98 | 0.97 | 0.96 | 0.98 | 0.98 | 0.97 |
| Liquid phase parameter L | 9.9 | 9.7 | 9.7 | 9.6 | 9.6 | 9.8 | 9.8 | 9.7 |
| Thermal expansion parameter C | 0.77 | 0.81 | 0.80 | 0.80 | 0.79 | 0.80 | 0.79 | 0.79 |
| Glass transition point (° C.) | 733 | 729 | 728 | 728 | 728 | 729 | 729 | 729 |
| Density (g/cm³) | 2.71 | 2.72 | 2.71 | 2.71 | 2.70 | 2.72 | 2.71 | 2.71 |
| Liquid phase viscosity log η_{L} (dPa · s) | 3.4 | 3.4 | 3.4 | 3.4 | 3.4 | 3.4 | 3.4 | 3.4 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | ◯ | x | x | x | x | x | x | x |
| Manufacturability determination | ⊚ | ⊚ | ⊚ | ⊚ | ⊚ | ⊚ | ⊚ | ⊚ |

TABLE 38

| | Example | Example | Example | Example | Example | Example | Example | Example | Example |
|---|---|---|---|---|---|---|---|---|---|
| (mol %) | 630 | 631 | 632 | 633 | 634 | 635 | 636 | 637 | 638 |
| SiO₂ | 53.6 | 53.6 | 53.6 | 53.6 | 53.6 | 53.6 | 53.6 | 53.6 | 53.6 |
| Al₂O₃ | 12 | 12.5 | 12.5 | 12.5 | 13 | 13 | 13 | 13 | 13.5 |
| B₂O₃ | 8.5 | 7 | 7.5 | 8.5 | 7 | 7.5 | 8 | 8.5 | 7 |
| MgO | 21 | 22 | 21.5 | 20.5 | 21.5 | 21 | 20.5 | 20 | 21 |
| CaO | 0.3 | 0.3 | 0.3 | 0.3 | 0.3 | 0.3 | 0.3 | 0.3 | 0.3 |
| SrO | 0.3 | 0.3 | 0.3 | 0.3 | 0.3 | 0.3 | 0.3 | 0.3 | 0.3 |
| BaO | 0.3 | 0.3 | 0.3 | 0.3 | 0.3 | 0.3 | 0.3 | 0.3 | 0.3 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1 | 1 | 1 | 1 | 1 | 1 | 1 | 1 | 1 |
| TiO₂ | 1 | 1 | 1 | 1 | 1 | 1 | 1 | 1 | 1 |
| Y₂O₃ | 2 | 2 | 2 | 2 | 2 | 2 | 2 | 2 | 2 |
| Gd₂O₃ | | | | | | | | | |
| La₂O₃ | | | | | | | | | |
| WO₃ | | | | | | | | | |
| Ta₂O₅ | | | | | | | | | |
| Al₂O₃ + rare earth oxide | 14 | 14.5 | 14.5 | 14.5 | 15 | 15 | 15 | 15 | 15.5 |
| Y₂O₃ + Gd₂O₃ + La₂O₃ + Nd₂O₃ + Ta₂O₅ + Nb₂O₅ | 2 | 2 | 2 | 2 | 2 | 2 | 2 | 2 | 2 |
| (Al₂O₃ + MgO)/(SiO₂ + Al₂O₃ + B₂O₃ + MgO) | 0.35 | 0.36 | 0.36 | 0.35 | 0.36 | 0.36 | 0.35 | 0.35 | 0.36 |
| MgO/ΣRO | 0.96 | 0.96 | 0.96 | 0.96 | 0.96 | 0.96 | 0.96 | 0.96 | 0.96 |
| N | 7 | 7 | 7 | 7 | 7 | 7 | 7 | 7 | 7 |
| Young's modulus E (GPa) | 97 | 99 | 98 | 97 | 99 | 98 | 98 | 97 | 99 |
| Thermal expansion coefficient α(ppm/° C.) | 3.91 | 3.94 | 3.91 | 3.86 | 3.90 | 3.87 | 3.85 | 3.82 | 3.86 |
| Liquid phase temperature T_{L} (° C.) | 1198 | 1203 | 1207 | 1199 | 1204 | 1205 | 1200 | 1200 | 1203 |
| 13.1 · E+9 − T_{L} | 85 | 101 | 91 | 85 | 100 | 94 | 92 | 86 | 103 |
| 1923 − 156 · α − T_{L} | 116 | 105 | 106 | 121 | 110 | 114 | 123 | 127 | 118 |
| Young's modulus parameter Y | 0.96 | 0.99 | 0.98 | 0.96 | 0.99 | 0.98 | 0.97 | 0.97 | 0.99 |
| Liquid phase parameter L | 9.7 | 9.9 | 9.8 | 9.8 | 10.0 | 9.9 | 9.9 | 9.9 | 10.0 |
| Thermal expansion parameter C | 0.78 | 0.79 | 0.78 | 0.77 | 0.78 | 0.78 | 0.77 | 0.77 | 0.77 |
| Glass transition point (° C.) | 729 | 731 | 730 | 730 | 732 | 732 | 732 | 732 | 734 |
| Density (g/cm³) | 2.70 | 2.72 | 2.71 | 2.70 | 2.72 | 2.71 | 2.71 | 2.70 | 2.72 |
| Liquid phase viscosity log η_{L} (dPa · s) | 3.4 | 3.4 | 3.4 | 3.4 | 3.4 | 3.4 | 3.4 | 3.4 | 3.4 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | x | x | x | x | ◯ | x |
| Manufacturability determination | ⊚ | ⊚ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 639 | 640 | 641 | 642 | 643 | 644 | 645 | 646 |
| SiO₂ | 53.6 | 53.6 | 54.1 | 54.1 | 54.1 | 54.1 | 54.1 | 54.1 |
| Al₂O₃ | 13.5 | 13.5 | 11.5 | 11.5 | 11.5 | 11.5 | 12 | 12 |
| B₂O₃ | 7.5 | 8 | 7 | 7.5 | 8 | 8.5 | 7 | 7.5 |
| MgO | 20.5 | 20 | 22.5 | 22 | 21.5 | 21 | 22 | 21.5 |
| CaO | 0.3 | 0.3 | 0.3 | 0.3 | 0.3 | 0.3 | 0.3 | 0.3 |
| SrO | 0.3 | 0.3 | 0.3 | 0.3 | 0.3 | 0.3 | 0.3 | 0.3 |
| BaO | 0.3 | 0.3 | 0.3 | 0.3 | 0.3 | 0.3 | 0.3 | 0.3 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1 | 1 | 1 | 1 | 1 | 1 | 1 | 1 |
| TiO₂ | 1 | 1 | 1 | 1 | 1 | 1 | 1 | 1 |
| Y₂O₃ | 2 | 2 | 2 | 2 | 2 | 2 | 2 | 2 |
| Gd₂O₃ | | | | | | | | |
| La₂O₃ | | | | | | | | |
| WO₃ | | | | | | | | |
| Ta₂O₅ | | | | | | | | |
| Al₂O₃ + rare earth oxide | 15.5 | 15.5 | 13.5 | 13.5 | 13.5 | 13.5 | 14 | 14 |
| Y₂O₃ + Gd₂O₃ + La₂O₃ + Nd₂O₃ + Ta₂O₅ + Nb₂O₅ | 2 | 2 | 2 | 2 | 2 | 2 | 2 | 2 |
| (Al₂O₃ + MgO)/(SiO₂ + Al₂O₃ + B₂O₃ + MgO) | 0.36 | 0.35 | 0.36 | 0.35 | 0.35 | 0.34 | 0.36 | 0.35 |
| MgO/ΣRO | 0.96 | 0.96 | 0.96 | 0.96 | 0.96 | 0.96 | 0.96 | 0.96 |
| N | 7 | 7 | 7 | 7 | 7 | 7 | 7 | 7 |
| Young's modulus E (GPa) | 99 | 98 | 98 | 98 | 97 | 97 | 98 | 98 |
| Thermal expansion coefficient α(ppm/° C.) | 3.83 | 3.81 | 3.99 | 3.96 | 3.94 | 3.91 | 3.95 | 3.92 |
| Liquid phase temperature T_{L} (° C.) | 1202 | 1199 | 1201 | 1202 | 1200 | 1198 | 1201 | 1203 |
| 13.1 · E+9 − T_{L} | 98 | 94 | 96 | 88 | 84 | 79 | 97 | 89 |
| 1923 − 156 · α − T_{L} | 123 | 130 | 100 | 102 | 108 | 114 | 107 | 109 |
| Young's modulus parameter Y | 0.98 | 0.97 | 0.98 | 0.97 | 0.97 | 0.96 | 0.98 | 0.97 |
| Liquid phase parameter L | 10.0 | 10.0 | 9.7 | 9.7 | 9.7 | 9.6 | 9.8 | 9.8 |
| Thermal expansion parameter C | 0.77 | 0.76 | 0.80 | 0.79 | 0.79 | 0.78 | 0.79 | 0.79 |
| Glass transition point (° C.) | 733 | 733 | 729 | 729 | 729 | 728 | 729 | 729 |
| Density (g/cm³) | 2.71 | 2.71 | 2.71 | 2.71 | 2.70 | 2.70 | 2.71 | 2.71 |
| Liquid phase viscosity log η_{L} (dPa · s) | 3.4 | 3.4 | 3.4 | 3.4 | 3.4 | 3.4 | 3.4 | 3.4 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | ◯ | ◯ | x | x | x | x | x | x |
| Manufacturability determination | ⊚ | ⊚ | ⊚ | ⊚ | ⊚ | ⊚ | ⊚ | ⊚ |

TABLE 39

| | Example | Example | Example | Example | Example | Example | Example | Example | Example |
|---|---|---|---|---|---|---|---|---|---|
| (mol %) | 647 | 648 | 649 | 650 | 651 | 652 | 653 | 654 | 655 |
| SiO₂ | 54.1 | 54.1 | 54.1 | 54.1 | 54.1 | 54.1 | 54.1 | 54.1 | 54.1 |
| Al₂O₃ | 12 | 12 | 12.5 | 12.5 | 12.5 | 12.5 | 13 | 13 | 13 |
| B₂O₃ | 8 | 8.5 | 7 | 7.5 | 8 | 8.5 | 7 | 7.5 | 8 |
| MgO | 21 | 20.5 | 21.5 | 21 | 20.5 | 20 | 21 | 20.5 | 20 |
| CaO | 0.3 | 0.3 | 0.3 | 0.3 | 0.3 | 0.3 | 0.3 | 0.3 | 0.3 |
| SrO | 0.3 | 0.3 | 0.3 | 0.3 | 0.3 | 0.3 | 0.3 | 0.3 | 0.3 |
| BaO | 0.3 | 0.3 | 0.3 | 0.3 | 0.3 | 0.3 | 0.3 | 0.3 | 0.3 |
| Li₂O | | | | | | | | | |
| Na₂O | | | | | | | | | |
| K₂O | | | | | | | | | |
| ZnO | | | | | | | | | |
| P₂O₅ | | | | | | | | | |
| ZrO₂ | 1 | 1 | 1 | 1 | 1 | 1 | 1 | 1 | 1 |
| TiO₂ | 1 | 1 | 1 | 1 | 1 | 1 | 1 | 1 | 1 |
| Y₂O₃ | 2 | 2 | 2 | 2 | 2 | 2 | 2 | 2 | 2 |
| Gd₂O₃ | | | | | | | | | |
| La₂O₃ | | | | | | | | | |
| WO₃ | | | | | | | | | |
| Ta₂O₅ | | | | | | | | | |
| Al₂O₃ + rare earth oxide | 14 | 14 | 14.5 | 14.5 | 14.5 | 14.5 | 15 | 15 | 15 |
| Y₂O₃ + Gd₂O₃ + La₂O₃ + Nd₂O₃ + Ta₂O₅ + Nb₂O₅ | 2 | 2 | 2 | 2 | 2 | 2 | 2 | 2 | 2 |
| (Al₂O₃ + MgO)/(SiO₂ + Al₂O₃ + B₂O₃ + MgO) | 0.35 | 0.34 | 0.36 | 0.35 | 0.35 | 0.34 | 0.36 | 0.35 | 0.35 |
| MgO/ΣRO | 0.96 | 0.96 | 0.96 | 0.96 | 0.96 | 0.96 | 0.96 | 0.96 | 0.96 |
| N | 7 | 7 | 7 | 7 | 7 | 7 | 7 | 7 | 7 |
| Young's modulus E (GPa) | 97 | 97 | 98 | 98 | 97 | 97 | 99 | 98 | 98 |
| Thermal expansion coefficient α(ppm/° C.) | 3.90 | 3.87 | 3.91 | 3.88 | 3.86 | 3.83 | 3.86 | 3.84 | 3.81 |
| Liquid phase temperature T_{L} (° C.) | 1198 | 1196 | 1204 | 1205 | 1199 | 1198 | 1203 | 1202 | 1200 |
| 13.1 · E+9 − T_{L} | 87 | 83 | 95 | 88 | 87 | 81 | 97 | 91 | 88 |
| 1923 − 156 · α − T_{L} | 117 | 124 | 109 | 113 | 122 | 127 | 117 | 122 | 128 |
| Young's modulus parameter Y | 0.97 | 0.96 | 0.98 | 0.97 | 0.97 | 0.96 | 0.98 | 0.98 | 0.97 |
| Liquid phase parameter L | 9.8 | 9.7 | 9.9 | 9.9 | 9.8 | 9.8 | 10.0 | 10.0 | 9.9 |
| Thermal expansion parameter C | 0.78 | 0.78 | 0.78 | 0.78 | 0.77 | 0.77 | 0.77 | 0.77 | 0.76 |
| Glass transition point (° C.) | 729 | 729 | 731 | 731 | 731 | 730 | 732 | 732 | 732 |
| Density (g/cm³) | 2.70 | 2.70 | 2.71 | 2.71 | 2.70 | 2.70 | 2.71 | 2.71 | 2.70 |
| Liquid phase viscosity log η_{L} (dPa · s) | 3.4 | 3.5 | 3.4 | 3.4 | 3.4 | 3.4 | 3.4 | 3.4 | 3.4 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | x | x | ◯ | x | x | ◯ |
| Manufacturability determination | ⊚ | ⊚ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 656 | 657 | 658 | 659 | 660 | 661 | 662 | 663 |
| SiO₂ | 54.1 | 54.1 | 54.6 | 54.6 | 54.6 | 54.6 | 54.6 | 54.6 |
| Al₂O₃ | 13.5 | 13.5 | 11.5 | 11.5 | 11.5 | 11.5 | 12 | 12 |
| B₂O₃ | 7 | 7.5 | 7 | 7.5 | 8 | 8.5 | 7 | 7.5 |
| MgO | 20.5 | 20 | 22 | 21.5 | 21 | 20.5 | 21.5 | 21 |
| CaO | 0.3 | 0.3 | 0.3 | 0.3 | 0.3 | 0.3 | 0.3 | 0.3 |
| SrO | 0.3 | 0.3 | 0.3 | 0.3 | 0.3 | 0.3 | 0.3 | 0.3 |
| BaO | 0.3 | 0.3 | 0.3 | 0.3 | 0.3 | 0.3 | 0.3 | 0.3 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1 | 1 | 1 | 1 | 1 | 1 | 1 | 1 |
| TiO₂ | 1 | 1 | 1 | 1 | 1 | 1 | 1 | 1 |
| Y₂O₃ | 2 | 2 | 2 | 2 | 2 | 2 | 2 | 2 |
| Gd₂O₃ | | | | | | | | |
| La₂O₃ | | | | | | | | |
| WO₃ | | | | | | | | |
| Ta₂O₅ | | | | | | | | |
| Al₂O₃ + rare earth oxide | 15.5 | 15.5 | 13.5 | 13.5 | 13.5 | 13.5 | 14 | 14 |
| Y₂O₃ + Gd₂O₃ + La₂O₃ + Nd₂O₃ + Ta₂O₅ + Nb₂O₅ | 2 | 2 | 2 | 2 | 2 | 2 | 2 | 2 |
| (Al₂O₃ + MgO)/(SiO₂ + Al₂O₃ + B₂O₃ + MgO) | 0.36 | 0.35 | 0.35 | 0.35 | 0.34 | 0.34 | 0.35 | 0.35 |
| MgO/ΣRO | 0.96 | 0.96 | 0.96 | 0.96 | 0.96 | 0.96 | 0.96 | 0.96 |
| N | 7 | 7 | 7 | 7 | 7 | 7 | 7 | 7 |
| Young's modulus E (GPa) | 99 | 98 | 98 | 97 | 97 | 96 | 98 | 98 |
| Thermal expansion coefficient α(ppm/° C.) | 3.82 | 3.80 | 3.96 | 3.93 | 3.91 | 3.88 | 3.91 | 3.89 |
| Liquid phase temperature T_{L} (° C.) | 1201 | 1202 | 1201 | 1203 | 1199 | 1196 | 1201 | 1201 |
| 13.1 · E+9 − T_{L} | 100 | 93 | 91 | 83 | 81 | 77 | 92 | 86 |
| 1923 − 156 · α − T_{L} | 126 | 129 | 105 | 107 | 115 | 122 | 111 | 115 |
| Young's modulus parameter Y | 0.98 | 0.98 | 0.98 | 0.97 | 0.96 | 0.96 | 0.98 | 0.97 |
| Liquid phase parameter L | 10.1 | 10.0 | 9.8 | 9.7 | 9.7 | 9.7 | 9.9 | 9.8 |
| Thermal expansion parameter C | 0.77 | 0.76 | 0.79 | 0.79 | 0.78 | 0.78 | 0.78 | 0.78 |
| Glass transition point (° C.) | 734 | 733 | 729 | 729 | 729 | 729 | 729 | 729 |
| Density (g/cm³) | 2.71 | 2.71 | 2.71 | 2.70 | 2.70 | 2.69 | 2.71 | 2.70 |
| Liquid phase viscosity log η_{L} (dPa · s) | 3.4 | 3.4 | 3.4 | 3.4 | 3.4 | 3.5 | 3.4 | 3.4 |
| K_{Ic} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 |
| Deflection determination | ◯ | ◯ | ◯ | ◯ | ◯ | ◯ | ◯ | ◯ |
| Deflection determination in high density process | ◯ | ◯ | x | x | x | x | x | x |
| Manufacturability determination | ⊚ | ⊚ | ⊚ | ⊚ | ⊚ | ⊚ | ⊚ | ⊚ |

TABLE 40

| | Example | Example | Example | Example | Example | Example | Example | Example | Example |
|---|---|---|---|---|---|---|---|---|---|
| (mol %) | 664 | 665 | 666 | 667 | 668 | 669 | 670 | 671 | 672 |
| SiO₂ | 54.6 | 54.6 | 54.6 | 54.6 | 54.6 | 54.6 | 54.6 | 54.6 | 53 |
| Al₂O₃ | 12 | 12 | 12.5 | 12.5 | 12.5 | 13 | 13 | 13.5 | 14 |
| B₂O₃ | 8 | 8.5 | 7 | 7.5 | 8 | 7 | 7.5 | 7 | 9.1 |
| MgO | 20.5 | 20 | 21 | 20.5 | 20 | 20.5 | 20 | 20 | 19 |
| CaO | 0.3 | 0.3 | 0.3 | 0.3 | 0.3 | 0.3 | 0.3 | 0.3 | 0.3 |
| SrO | 0.3 | 0.3 | 0.3 | 0.3 | 0.3 | 0.3 | 0.3 | 0.3 | 0.3 |
| BaO | 0.3 | 0.3 | 0.3 | 0.3 | 0.3 | 0.3 | 0.3 | 0.3 | 0.3 |
| Li₂O | | | | | | | | | |
| Na₂O | | | | | | | | | |
| K₂O | | | | | | | | | |
| ZnO | | | | | | | | | |
| P₂O₅ | | | | | | | | | 1 |
| ZrO₂ | 1 | 1 | 1 | 1 | 1 | 1 | 1 | 1 | 1 |
| TiO₂ | 1 | 1 | 1 | 1 | 1 | 1 | 1 | 1 | 1 |
| Y₂O₃ | 2 | 2 | 2 | 2 | 2 | 2 | 2 | 2 | 1 |
| Gd₂O₃ | | | | | | | | | |
| La₂O₃ | | | | | | | | | |
| WO₃ | | | | | | | | | |
| Ta₂O₅ | | | | | | | | | |
| Al₂O₃ + rare earth oxide | 14 | 14 | 14.5 | 14.5 | 14.5 | 15 | 15 | 15.5 | 15 |
| Y₂O₃ + Gd₂O₃ + La₂O₃ + Nd₂O₃ + Ta₂O₅ + Nb₂O₅ | 2 | 2 | 2 | 2 | 2 | 2 | 2 | 2 | 1 |
| (Al₂O₃ + MgO)/(SiO₂ + Al₂O₃ + B₂O₃ + MgO) | 0.34 | 0.34 | 0.35 | 0.35 | 0.34 | 0.35 | 0.35 | 0.35 | 0.35 |
| MgO/ΣRO | 0.96 | 0.96 | 0.96 | 0.96 | 0.96 | 0.96 | 0.96 | 0.96 | 0.95 |
| N | 7 | 7 | 7 | 7 | 7 | 7 | 7 | 7 | 8 |
| Young's modulus E (GPa) | 97 | 97 | 98 | 98 | 97 | 98 | 98 | 98 | 96 |
| Thermal expansion coefficient α(ppm/° C.) | 3.86 | 3.84 | 3.87 | 3.85 | 3.82 | 3.83 | 3.81 | 3.79 | 3.72 |
| Liquid phase temperature T_{L} (° C.) | 1196 | 1195 | 1203 | 1202 | 1198 | 1201 | 1202 | 1200 | 1212 |
| 13.1 · E+9 − T_{L} | 84 | 78 | 92 | 86 | 83 | 94 | 87 | 96 | 52 |
| 1923 − 156 · α − T_{L} | 124 | 129 | 116 | 121 | 129 | 124 | 128 | 132 | 132 |
| Young's modulus parameter Y | 0.96 | 0.96 | 0.98 | 0.97 | 0.96 | 0.98 | 0.97 | 0.98 | 0.95 |
| Liquid phase parameter L | 9.8 | 9.8 | 9.9 | 9.9 | 9.9 | 10.0 | 10.0 | 10.1 | 9.8 |
| Thermal expansion parameter C | 0.77 | 0.77 | 0.78 | 0.77 | 0.77 | 0.77 | 0.76 | 0.76 | 0.75 |
| Glass transition point (° C.) | 729 | 729 | 731 | 731 | 731 | 732 | 732 | 734 | 733 |
| Density (g/cm³) | 2.70 | 2.69 | 2.71 | 2.70 | 2.70 | 2.71 | 2.70 | 2.71 | 2.69 |
| Liquid phase viscosity log η_{L} (dPa · s) | 3.4 | 3.5 | 3.4 | 3.4 | 3.4 | 3.4 | 3.4 | 3.4 | 3.3 |
| K_{Ic} (MPa · m^{0.5}) | 0.8< | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ | 80≤ |
| T₂ (° C.) | <1450 | <1450 | <1450 | <1450 | <1450 | <1450 | <1450 | <1450 | <1450 |
| T₃ (° C.) | <1300 | <1300 | <1300 | <1300 | <1300 | <1300 | <1300 | <1300 | <1300 |
| T₄ (° C.) | <1200 | <1200 | <1200 | <1200 | <1200 | <1200 | <1200 | <1200 | <1200 |
| Deflection determination | ◯ | ◯ | ◯ | ◯ | ◯ | ◯ | ◯ | ◯ | ◯ |
| Deflection determination in high density process | x | x | x | x | ◯ | ◯ | ◯ | ◯ | ◯ |
| Manufacturability determination | ⊚ | ⊚ | ⊚ | ⊚ | ⊚ | ⊚ | ⊚ | ⊚ | ⊚ |

| | Example | Example | Example | Example | Example | Example | Example | Example |
|---|---|---|---|---|---|---|---|---|
| (mol %) | 673 | 674 | 675 | 676 | 677 | 678 | 679 | 680 |
| SiO₂ | 53 | 53 | 53 | 66.5 | 68 | 52.4 | 50.3 | 48 |
| Al₂O₃ | 14 | 14 | 14 | 13.2 | 13 | 13.4 | 17.1 | 12 |
| B₂O₃ | 9.1 | 9.1 | 9.1 | | 3.8 | 5 | 2.2 | 7 |
| MgO | 19 | 19 | 19 | 12.2 | 6.8 | 28.7 | 17.1 | 22 |
| CaO | 0.3 | 0.3 | 0.3 | 5.5 | 3.8 | | 1 | 1 |
| SrO | 0.3 | 0.3 | 0.3 | 2.6 | 4.4 | | 1 | 1 |
| BaO | 0.3 | 0.3 | 0.3 | | | | 1 | 1 |
| Li₂O | | | 1 | | | | 1 | 1 |
| Na₂O | | 1 | | | | | 0.1 | 1 |
| K₂O | | | | | 0.2 | | 0.1 | 1 |
| ZnO | 1 | | | | | | 1 | 1 |
| P₂O₅ | | | | | | | | |
| ZrO₂ | 1 | 1 | 1 | | | 0.3 | 1 | 1 |
| TiO₂ | 1 | 1 | 1 | | | 0.3 | 1 | 1 |
| Y₂O₃ | 1 | 1 | 1 | | | | 1 | 1 |
| Gd₂O₃ | | | | | | | 0.9 | 1 |
| La₂O₃ | | | | | | | | |
| WO₃ | | | | | | | | |
| Ta₂O₅ | | | | | | | 4.2 | |
| Al₂O₃ + rare earth oxide | 15 | 15 | 15 | 13.2 | 13 | 13.4 | 19 | 14 |
| Y₂O₃ + Gd₂O₃ + La₂O₃ + Nd₂O₃ + Ta₂O₅ + Nb₂O₅ | 1 | 1 | 1 | 0 | 0 | 0 | 6.1 | 2 |
| (Al₂O₃ + MgO)/(SiO₂ + Al₂O₃ + B₂O₃ + MgO) | 0.35 | 0.35 | 0.35 | 0.28 | 0.22 | 0.42 | 0.39 | 0.38 |
| MgO/ΣRO | 0.95 | 0.95 | 0.95 | 0.60 | 0.45 | 1.00 | 0.85 | 0.88 |
| N | 8 | 8 | 8 | 5 | 6 | 4 | 14 | 15 |
| Young's modulus E (GPa) | 96 | 96 | 98 | 91 | 86 | 100 | 111 | 99 |
| Thermal expansion coefficient α(ppm/° C.) | 3.67 | 3.78 | 3.81 | 3.91 | 3.49 | 3.80 | 4.06 | 5.20 |
| Liquid phase temperature T_{L} (° C.) | 1207 | 1205 | 1207 | 1312 | 1192 | 1325 | 1295 | 1175 |
| 13.1 · E+9 − T_{L} | 66 | 58 | 91 | −106 | −56 | −13 | 168 | 132 |
| 1923 − 156 · α − T_{L} | 143 | 129 | 122 | 1 | 187 | 5 | −5 | −63 |
| Young's modulus parameter Y | 0.95 | 0.95 | 0.96 | 0.92 | 0.85 | 0.99 | 1.10 | 0.98 |
| Liquid phase parameter L | 9.9 | 9.8 | 9.8 | 11.1 | 10.7 | 9.7 | 11.0 | 9.3 |
| Thermal expansion parameter C | 0.73 | 0.83 | 0.75 | 0.74 | 0.70 | 0.76 | 0.84 | 1.04 |
| Glass transition point (° C.) | 734 | 733 | 731 | 791 | 748 | 755 | 747 | 678 |
| Density (g/cm³) | 2.67 | 2.63 | 2.64 | 2.58 | | | | 2.85 |
| Liquid phase viscosity log η_{L} (dPa · s) | 3.4 | 3.4 | 3.4 | | | | | 2.8 |
| K_{Ic} (MPa · m^{0.5}) | 0.8< | 0.8< | 0.8< | | | | | 0.9 |
| Transmittance (%) @308 nm, 0.7 mmt | 30≤ | 30≤ | 30≤ | 30≤ | 30≤ | 30≤ | 30≤ | 30≤ |
| Transmittance (%) @1064 nm, 0.7 mmt | 80≤ | 80≤ | 80≤ | 80≤ | 80≤ | 80≤ | 80≤ | 80≤ |
| T₂ (° C.) | <1450 | <1450 | <1450 | | 1400< | 1376 | 1349 | 1320 |
| T₃ (° C.) | <1300 | <1300 | <1300 | 1341 | | 1229 | 1212 | 1178 |
| T₄ (° C.) | <1200 | <1200 | <1200 | | | 1129 | 1115 | 1077 |
| Deflection determination | ◯ | ◯ | ◯ | ◯ | x | ◯ | ◯ | x |
| Deflection determination in high density process | ◯ | ◯ | ◯ | x | ◯ | ◯ | x | x |
| Manufacturability determination | ⊚ | ⊚ | ⊚ | x | ⊚ | x | x | ⊚ |

TABLE 41

| (mol %) | Example 681 | Example 682 |
|---|---|---|
| SiO₂ | 64.1 | 55 |
| Al₂O₃ | 9.6 | 15 |
| B₂O₃ | | 5 |
| MgO | 14.9 | 20 |
| CaO | 9.9 | |
| SrO | | |
| BaO | | |
| Li₂O | | |
| Na₂O | | |
| K₂O | | |
| ZnO | | |
| P₂O₅ | | |
| ZrO₂ | | |
| TiO₂ | | |
| Y₂O₃ | 1.4 | 5 |
| Gd₂O₃ | | |
| La₂O₃ | | |
| WO₃ | | |
| Ta₂O₅ | | |
| Al₂O₃ + rare earth oxide | 11 | 20 |
| Y₂O₃ + Gd₂O₃ + La₂O₃ + | 1.4 | 5 |
| Nd₂O₃ + Ta₂O₅ + Nb₂O₅ | | |
| (Al₂O₃ + MgO)/(SiO₂ + | 0.28 | 0.37 |
| Al₂O₃ + B₂O₃ + MgO) | | |
| MgO/ΣRO | 0.60 | 1.00 |
| N | 5 | 5 |
| Young's modulus E (GPa) | 93 | 105 |
| Thermal expansion | 4.57 | 4.00 |
| coefficient α (ppm/° C.) | | |
| Liquid phase temperature T_{L} (° C.) | 1227 | 1400< |
| 13.1 · E + 9-T_{L} | 0 | |
| 1923-156 · α-T_{L} | −17 | |
| Young's modulus parameter Y | 0.95 | 1.04 |
| Liquid phase parameter L | 10.7 | 10.2 |
| Thermal expansion parameter C | 0.86 | 0.79 |
| Glass transition point (° C.) | 678 | 678 |
| Density (g/cm³) | | |
| Liquid phase viscosity log η_{L} (dPa · s) | | |
| K_{lc} (MPa · m^{0.5}) | | |
| Transmittance (%) @308 nm, 0.7 mmt | 30≤ | 30≤ |
| Transmittance (%) @1064 nm, 0.7 mmt | 80≤ | 80≤ |
| T₂ (° C.) | | |
| T₃ (° C.) | 1324 | |
| T₄ (° C.) | 1413 | |
| Deflection determination | X | ◯ |
| Deflection determination | X | X |
| in high density process | | |
| Manufacturability determination | ⊚ | X |

### Example 1

In Example 1, a glass having the composition shown in Table 1 was produced. In Example 1, a base plate having a diameter of 320 mm and a thickness of 6 mm was manufactured using a melt casting method. Next, a plurality of plates was cut out from the center of the base plate, each plate having a diameter of 300 mm and a thickness of 3 mm. Both surfaces of each plate were polished using cerium oxide as a polishing material to obtain glass having a thickness of 0.7 mm.

Young's modulus E (GPa) was measured for the glass of Example 1. The Young's modulus was measured by an ultrasonic pulse method defined in JIS R 1602:1995 “Testing methods for elastic modulus of fine ceramics”. The bulk density of a sample was measured by the Archimedes method, and the longitudinal wave velocity and the transverse wave velocity are measured using an ultrasonic thickness meter 38DL PLUS manufactured by Olympus Corporation to determine a value of the Young's modulus.

The linear thermal expansion coefficient α (ppm/° C.) of the glass of Example 1 was measured. The measurement was performed within a range of 30° C. to 300° C. using a thermal expansion meter (DIL 402 Expedis Supreme) manufactured by NETZSCH Group as a measuring apparatus, and an average thermal expansion coefficient within a range of 50° C. to 200° C. in that measurement range was used as the linear thermal expansion coefficient α.

A liquid phase temperature T_{L} (° C.) was measured for the glass of Example 1. The liquid phase temperature T_{L} was measured by placing glass particles that pass through a sieve with a mesh width of 4.0 mm and do not pass through a sieve with a mesh width of 2.3 mm on a platinum dish, and then holding the glass particles in an electric furnace set at a predetermined temperature for one hour to measure the temperature at which crystals are precipitated.

For the glass of Example 1, the value on the left side of Formulae (1) and (2) described above was calculated.

For the glass of Example 1, the Young's modulus parameter Y was calculated using Formula (3) described above.

For the glass of Example 1, the thermal expansion parameter C was calculated using Formula (5) described above.

For the glass of Example 1, the liquid phase parameter L was calculated using Formula (4) described above.

The glass transition temperature (° C.) of the glass of Example 1 was measured. The glass transition temperature was measured by obtaining an expansion curve of the glass up to a softening point thereof, as measured by a thermal expansion measuring apparatus.

For the glass of Example 1, the density (g/cm³) was measured. The density was measured by the Archimedes method.

The liquid phase viscosity of the glass of Example 1 was measured. The liquid phase viscosity was measured by measuring a temperature-viscosity curve by an inner cylinder rotation method and calculating the viscosity at the liquid phase temperature.

The fracture toughness value K_{IC} (MPa·m^{0.5}) of the glass of Example 1 was measured. The fracture toughness value K_{IC} was measured using a pre-crack introduction fracture test method (Single-Edge-Precracked-Beam (SEPB) method) as defined in JIS R1607:2015 “Testing methods for fracture toughness of fine ceramics at room temperature”.

For the glass of Example 1, the transmittance for light at a wavelength of 308 nm and the transmittance for light at a wavelength of 1064 nm were measured. The transmittance was measured by measuring a spectral transmittance curve using an ultraviolet-visible spectrophotometer (UH4150 type, manufactured by Hitachi High-Tech Corporation).

For the glass of Example 1, the melting temperature T₂, the working temperature T₃, and the molding temperature T₄ were measured. The melting temperature T₂, the working temperature T₃, and the molding temperature T₄ were measured by an inner cylinder rotation method.

The measurement results and the calculation results are shown in Table 1.

### Examples 2 to 682

In Examples 2 to 682, glasses were manufactured in the same manner as in Example 1 except that compositions of the glasses were as shown in Tables 1 to 41. The measurement results and calculation results of the examples are shown in Tables 1 to 41.

### Evaluation

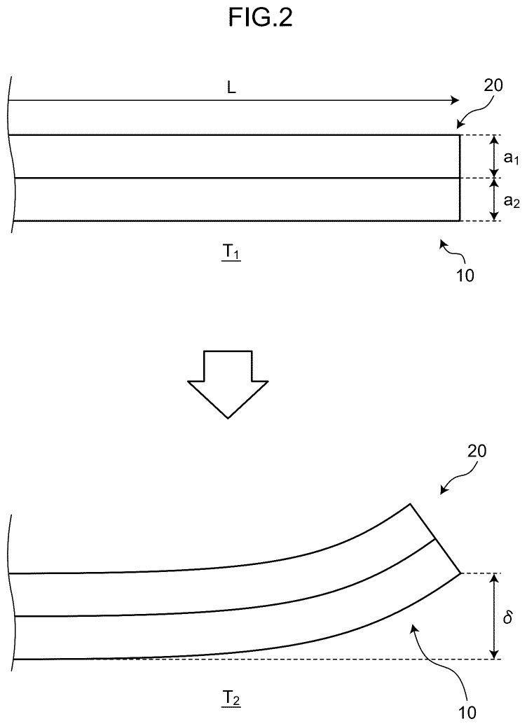

For the glass of each example, the deflection and manufacturability were determined. A deflection evaluation was carried out on the basis of the Bi-Metal warpage calculation defined in the literature S. Timoshenko, “Analysis of Bi-Metal Thermostats” J. Opt. Soc. Am. 11 (1925) 233. FIG. 2 is a schematic diagram for explaining the deflection evaluation. Here, as illustrated in FIG. 2, when a semiconductor substrate is cooled from a high temperature state of 200° C. to a low temperature of 20° C. in a process of molding a semiconductor substrate with a resin and bonding the semiconductor substrate to a first surface 12 of the glass 10 processed into the shape illustrated in FIG. 1, a warpage amount δ is defined as a displacement amount in any one of the upward or downward vertical direction at an edge of the glass 10, with the center of a second surface 14 used as the height reference. Specifically, the warpage amount δ is calculated by Formula (6).

$$δ = \frac{6 {L}^{2} ( {α}_{2} - {α}_{1} ) ( {T}_{2} - {T}_{1} ) {( 1 + m )}^{2}}{8 h [ 3 {( 1 + m )}^{2} + ( 1 + mn ) \{ {m}^{2} + {( mn )}^{- 1} \} ]} \qquad ( 6 )$$

Here, as illustrated in FIG. 2, L is a length in a warpage direction (lateral direction in FIG. 2) of the glass 10, α₁ is a linear thermal expansion coefficient of a resin substrate 20, α₂ is a linear thermal expansion coefficient of the glass 10, T₂ is a temperature after cooling (here, 20° C.), and T₁ is a temperature before cooling (here, 200° C.). In addition, m is a₁/a₂, h is a₁+a₂, and n is E₁/E₂. Here, a₁ is the thickness of the resin substrate 20, a₂ is the thickness of the glass 10, E₁ is the Young's modulus of the resin substrate 20, and E₂ is the Young's modulus of the glass 10. In the deflection evaluation, the thickness of the resin substrate 20 to be bonded to the glass 10 was assumed to be 0.3 mm and the Young's modulus was assumed to be 31.5 GPa in consideration of mounting a semiconductor. Assuming that the linear thermal expansion coefficient was 4.0 ppm/° C., the warpage amount δ was calculated when the thickness of the glass 10 was 0.7 mm and the length L was 300 mm. In the determination of deflection, a case where the absolute value of the calculated warpage amount value δ was less than 0.8 mm was defined as ∘, and a case where the absolute value was 0.8 mm or more was defined as ×. In addition, the term “manufacturability” refers to facilitation of manufacturing, and a liquid phase temperature of less than 1280° C. was defined as “∘”, a liquid phase temperature of less than 1260° C. was defined as “⊚”, and a liquid phase temperature of 1280° C. or more was defined as “×”.

As an optional evaluation, a deflection evaluation in a high density process was also carried out. In the deflection evaluation in the high density process, the resin substrate 20 to be bonded to the glass 10 was assumed to have a thickness of 0.3 mm and a Young's modulus of 31.5 GPa in consideration of mounting silicon at high density. The linear thermal expansion coefficient was assumed to be 3.2 ppm/° C. In the determination of deflection in this high density process, a case where the absolute value of the calculated warpage amount value δ was less than 1.08 mm was defined as ∘, and a case where the absolute value was 1.08 mm or more was defined as ×.

As shown in Tables 1 to 41, in Examples 1 to 675 in which the liquid phase temperature T_{L} satisfies Formulae (1) and (2) described above, the deflection determination and the manufacturability determination are ∘ to ⊚, and it can be seen that it is possible to facilitate manufacturing while minimizing deflection. On the other hand, in Examples 676 to 682 which are Comparative Examples, since the liquid phase temperature T_{L} does not satisfy at least one of Formula (1) or (2) described above, at least one of the manufacturability determination or the deflection determination was ×, and it can be seen that the manufacturing could not be facilitated.

Although the embodiments of the present invention have been described above, the embodiments are not limited by the contents of these embodiments. In addition, the above-described constituent elements include those that can be easily assumed by those skilled in the art, those that are substantially the same, and those in a so-called equivalent range. Furthermore, the above-described components can be appropriately combined. Furthermore, various omissions, substitutions, or modifications in the constituent elements can be made without departing from the gist of the above-described embodiments.

According to the present invention, it is possible to facilitate the manufacturing.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

1. A glass, having a liquid phase temperature is denoted by T_{L} (C), a Young's modulus is denoted by E (GPa), and a linear thermal expansion coefficient is denoted by α (ppm/° C.), that satisfies formulas (1) and (2):
$$13.1 \times E + 9 - {T}_{L} \geq 0 \qquad ( 1 )$$
$$1923 - 156 \times α - {T}_{L} \geq 0. \qquad ( 2 )$$

2. The glass according to claim 1, wherein
the glass comprises, in terms of mol % on an oxide basis,
SiO₂: 40% to 65%,
B₂O3: 0.01% to 15%,
Al₂O₃+a rare earth oxide: 0% to 20%, and
Y₂O₃+Gd₂O₃+Ta₂O₅+La₂O₃+Nd₂O₃+Nb₂O₅: 0.5% or more.

3. The glass according to claim 2, wherein
the glass comprises, in terms of mol % on an oxide basis,
SiO₂: 44% to 64%,
B₂O₃: 1% to 13%,
Al₂O3: 5% to 20%, and
Y₂O₃+Gd₂O₃+Ta₂O₅+La₂O₃+Nd₂O₃+Nb₂O₅: 1to 10%.

4. The glass according to claim 1, having a composition in terms of mol % on an oxide basis that satisfies:
$$0.1 \leq \{ ( {Al}_{2} {O}_{3} + MgO ) / ( {SiO}_{2} + {Al}_{2} {O}_{3} + {B}_{2} {O}_{3} + MgO ) \} \leq 1 ,$$
$$0.5 \leq ( MgO ) / ( \sum R O ) \leq 1 , and$$
$$0 \% \leq {Al}_{2} {O}_{3} + rare earth oxides \leq 20 \% ,$$
where, ΣRO refers to a total content of an alkaline earth metal oxide contained in the glass.

5. The glass according to claim 1, having
a Young's modulus parameter Y calculated by Formula (3) of 0.8 or more,
$$Y = ( 123 - 0.54 [ {SiO}_{2} ] + 0.3 [ {Al}_{2} {O}_{3} ] - 1.15 [ {B}_{2} {O}_{3} ] + 0.21 [ MgO ] - 0.2 [ CaO ] - 0.1 [ SrO ] - 1.2 [ BaO ] + [ {Li}_{2} O ] - 2.8 [ {K}_{2} O ] + 0.05 [ ZnO ] + 1.46 [ {ZrO}_{2} ] - 0.05 [ {TiO}_{2} ] + 1.6 [ {Y}_{2} {O}_{3} ] + 1.35 [ {Gd}_{2} {O}_{3} ] + 1.37 [ {La}_{2} {O}_{3} ] + [ {Ta}_{2} {O}_{5} ] ) / 100 ; \qquad ( 3 )$$
a liquid phase parameter L calculated by Formula (4) of 10.5 or less,
$$L = ( - 642.5 + 20.6 [ {SiO}_{2} ] + 31.9 [ {Al}_{2} {O}_{3} ] + 2.85 [ {B}_{2} {O}_{3} ] + 11.24 [ MgO ] + 17.3 [ CaO ] + 1.7 [ SrO ] + 31.4 [ BaO ] - 6.86 [ {Li}_{2} O ] + 38 [ {K}_{2} O ] + 11.5 [ ZnO ] + 25.8 [ {ZrO}_{2} ] + 41 [ {TiO}_{2} ] + 12.3 [ {Y}_{2} {O}_{3} ] - 1.2 [ {Gd}_{2} {O}_{3} ] - 1.2 [ {La}_{2} {O}_{3} ] + 24.5 [ {Ta}_{2} {O}_{5} ] ) / 125 ; and \qquad ( 4 )$$
a thermal expansion parameter C calculated by Formula (5) of 0.9 or less,
$$C = ( 14.098 - 0.1245 [ {SiO}_{2} ] - 0.131 [ {Al}_{2} {O}_{3} ] - 0.101 [ {B}_{2} {O}_{3} ] - 0.051 [ MgO ] + 0.013 [ CaO ] + 0.053 [ SrO ] + 0.018 [ BaO ] + 0.041 [ {Li}_{2} O ] + 0.395 [ {Na}_{2} O ] - 0.066 [ ZnO ] - 0.033 [ {ZrO}_{2} ] - 0.072 [ {TiO}_{2} ] + 0.035 [ {Y}_{2} {O}_{3} ] + 0.074 [ {Gd}_{2} {O}_{3} ] + 0.074 [ {La}_{2} {O}_{3} ] - 0.091 [ {Ta}_{2} {O}_{5} ] ) / 5 \underline{,} \qquad ( 5 )$$
where in formulas (3)-(5), [RₓO_{y}] represents a content of an oxide RₓO_{y} contained in the glass measured in mol % on an oxide basis.

6. The glass according to claim 1, wherein the glass is a substrate.

7. The glass according to claim 6, wherein the glass is used for manufacturing at least one of a fan out wafer level package or a fan out panel level package.

8. A semiconductor support device, comprising
a substrate comprising the glass of claim 1; and
a semiconductor chip disposed on a surface of the glass.

9. A method of forming a semiconductor package, the method comprising
attaching a semiconductor chip to a surface of a first glass to form a first supported chip;
covering the semiconductor chip and the surface of the first glass with an encapsulating material to form an element substrate;
separating the encapsulating material and semiconductor chip from the first glass to form a second supported chip;
bonding a second glass to a surface of the second supported chip opposite to a surface in contact with the semiconductor chip to form a third supported chip;
forming on a surface of the semiconductor chip at least one selected from the group consisting of wiring and soldering bumps; and
separating the encapsulating material and semiconductor chip from the second glass to form a second supported chip to form the semiconductor package,
wherein at least one selected from the group consisting of the first glass and the second glass is the glass of claim 1.

10. The method of claim 9, wherein the semiconductor package is at least one selected from the group consisting of a fan out wafer level package and a fan out panel level package.
